(19) United States
(12) Patent Application Publication
(10) Pub. No.: US 2011/0141448 A1
(43) Pub. Date: Jun. 16, 2011

(54) SUBSTRATE CARRIER DEVICE, SUBSTRATE CARRYING METHOD, SUBSTRATE SUPPORTING MEMBER, SUBSTRATE HOLDING DEVICE, EXPOSURE APPARATUS, EXPOSURE METHOD AND DEVICE MANUFACTURING METHOD

(75) Inventors: Yasuo AOKI, Zushi-shi (JP); Tadashi SEKI, Fujisawa-shi (JP); Takuya YANAGAWA, Kawasaki-shi (JP)

(73) Assignee: NIKON CORPORATION, TOKYO (JP)

(21) Appl. No.: 12/954,760

(22) Filed: Nov. 26, 2010

Related U.S. Application Data
(60) Provisional application No. 61/272,979, filed on Nov. 27, 2009.
(60) Provisional application No. 61/272,978, filed on Nov. 27, 2009.

(51) Int. Cl. G03B 27/58; H01L 21/677; B65D 8/04

(52) U.S. Cl. 355/72; 355/77; 414/222.01; 414/806; 220/600

(57) ABSTRACT

A substrate carry-out device carries out an exposed substrate mounted on a substrate stage from a substrate holder by moving the substrate in one axis direction (X-axis direction) parallel to a horizontal plane in a state where the substrate is mounted on a substrate tray housed in the substrate holder. Meanwhile, a substrate carry-in device makes an unexposed substrate to be carried into the substrate stage wait at a substrate exchange position in a state where the unexposed substrate is mounted on another substrate tray, and after the exposed substrate is carried out from the substrate stage, lowers the another substrate tray, thereby mounting the unexposed substrate onto the substrate holder.

### CROSS-REFERENCE TO RELATED APPLICATIONS

This non-provisional application claims the benefit of Provisional Application No. 61/272,978 filed Nov. 27, 2009 and Provisional Application No. 61/272,979 filed Nov. 27, 2009, the disclosures of which are hereby incorporated herein by reference in their entirety.

### BACKGROUND OF THE INVENTION

1. Field of the Invention

The present invention relates to substrate carrier devices, substrate carrying methods, substrate supporting members, substrate holding devices, exposure apparatuses, exposure methods and device manufacturing methods, and more particularly to a substrate carrier device and a substrate carrying method to perform carry-in and carry-out of a substrate to/from a substrate holding device, a substrate supporting member that supports a substrate during carry of the substrate, the substrate holding device having a holding member that holds the carried substrate, an exposure apparatus including the substrate carrier device or the substrate holding device, an exposure method in which a substrate is carried using the substrate supporting member, and a device manufacturing method that uses the exposure method or the exposure apparatus.

2. Description of the Background Art

Conventionally, in a lithography process for manufacturing electron devices (microdevices) such as liquid crystal display elements or semiconductor devices (integrated circuits or the like), an exposure apparatus such as a projection exposure apparatus by a step-and-repeat method (a so-called stepper), or a projection exposure apparatus by a step-and-scan method (a so-called scanning stepper (which is also called a scanner)) is mainly used.

In this type of the exposure apparatus, a substrate such as a glass plate or a wafer whose surface is coated with a photosensitive agent (hereinafter, generically referred to as a substrate), which serves as an exposure subject, is mounted on a substrate holder of a substrate stage device, and is held by the substrate holder by, for example, vacuum adsorption or the like. And, onto the substrate, a circuit pattern that is formed on a mask (or a reticle) is transferred, by irradiating the substrate with an energy beam via an optical system that includes a projection lens and the like. When exposure processing on one substrate is completed, the substrate that has been exposed is carried out from the substrate holder by a substrate carrier device, and on the substrate holder, another substrate is mounted. In the exposure apparatus, the exchange of the substrate on the substrate holder is repeated, and thereby the exposure processing is consecutively performed to a plurality of substrates (refer to, for example, U.S. Pat. No. 6,559,928).

In this case, in order to improve the processing speed (throughput) as a whole when the exposure processing of a plurality of substrates is consecutively performed, it is effective to decrease the exchange time of substrates (cycle time) (to perform the exchange of substrates in a short time) as well as improving processing capability of exposure processing and alignment processing (reduction in the processing time). Therefore, a system (or an apparatus) that is capable of promptly performing exchange of substrates on the substrate stage device has been desired to be developed.

### SUMMARY OF TEE INVENTION

According to a first aspect of the present invention, there is provided a substrate carrier device, comprising; a carry-in device that carries in a substrate to a predetermined substrate holding device by carrying the substrate in a first path; and a carry-out device that carries out the substrate held by the substrate holding device, from the substrate holding device, by carrying the substrate in a second path that is different from the first path.

With this device, the carry-in of a substrate to the substrate holding device is performed in a first path by the carry-in device and the carry-out of the substrate from the substrate holding device is performed in a second path different from the first path by the carry-out device. Consequently, it becomes possible to perform the carry-in and the carry-out of the substrates in parallel (e.g. at the time of carry-out a substrate, to make another substrate subject to carry-in wait in the first path, and the like), thereby the cycle time needed when a substrate on the substrate holding device is exchanged can be reduced.

According to a second aspect of the present invention, there is provided a first exposure apparatus, comprising: the substrate carrier device of the present invention; and a pattern forming device that forms a predetermined pattern on the substrate mounted on the substrate holding device by exposing the substrate using an energy beam.

According to a third aspect of the present invention, there is provided a second exposure apparatus, comprising: a substrate holding device that includes a holding member having a holding surface parallel to a horizontal plane, on the holding surface a substrate being mounted; a carry-in device that carries in the substrate to the substrate holding device by carrying the substrate in a first path; a carry-out device that carries out the substrate held by the substrate holding device, from the substrate holding device, by carrying the substrate in a second path that is different from the first path; and an exposure system that exposes the substrate held on the substrate holding device with an energy beam.

With the first and second exposure apparatuses described above, because the cycle time needed when a substrate on the substrate holding device is exchanged can be reduced, the throughput can be improved as a consequence.

According to a fourth aspect of the present invention, there is provided a substrate carrying method, comprising: carrying in a substrate to a predetermined substrate holding device by carrying the substrate in a first path; and carrying out the substrate from the substrate holding device by carrying the substrate in a second path that is different from the first path.

With this method, the carry-in of a substrate to the substrate holding device is performed in a first path and the carry-out of the substrate from the substrate holding device is performed in a second path that is different from the first path. Consequently, it becomes possible to perform the carry-in and the carry-out of the substrates in parallel (e.g. at the time of carry-out a substrate, to make another substrate subject to carry-in wait in the first path, and the like), thereby the cycle time needed when a substrate on the substrate holding device is exchanged can be reduced.

According to a fifth aspect of the present invention, there is provided a substrate supporting member, comprising: a support section that is made up of a plurality of bar-shaped members extending in a first direction parallel to a horizontal plane and arranged at a predetermined distance in a second direction orthogonal to the first direction within the horizontal plane, and supports a substrate from below; and an engagement section that is connected to the support section and is capable of engaging with a predetermined carrier device, wherein the substrate supporting member is carried, together with the substrate, by the carrier device to a substrate holding device that has a substrate mounting surface parallel to the horizontal plane, at least a part of the support section is housed in a groove section formed at the substrate mounting surface, and the substrate supporting member removes from the inside of the groove section, together with the substrate, by relatively moving to one side in the first direction with respect to the substrate holding device.

With this member, the substrate supporting member that supports a substrate from below with a support section made up of a plurality of bar-shaped members extending in a first direction is carried to the substrate holding device by the carrier device. Of the substrate supporting member, at least a part of the support section is housed in the groove section of the substrate holding device, and at the time of carry-out of the substrate, the substrate supporting member relatively moves in a direction parallel to a first axis to direction in which the plurality of bar-shaped members configuring the support section extend) with respect to the substrate holding device in a state where the at least a part is housed in the groove section. Consequently, the carry-out of the substrate can be speedily performed.

According to a sixth aspect of the present invention, there is provided a substrate holding device, comprising: a holding member that has a holding surface parallel to a horizontal plane, on the holding surface a substrate being mounted, wherein at the holding member, a plurality of groove sections are formed that are capable of housing a part of a substrate supporting member that supports the substrate from below and allow removal of the part of the substrate supporting member by relative movement of the substrate supporting member to one side in a first direction parallel to the horizontal plane.

With this apparatus, a part of the substrate supporting member that supports a substrate from below is housed in a plurality of groove sections formed at the holding member. Consequently, the substrate can be delivered onto the holding surface in conjunction with an operation of housing the substrate supporting member in the groove sections. Further, the substrate supporting member is capable of removing the part housed in the groove sections from the groove sections by relative movement to one side in a first direction with respect to the holding member. Consequently, the substrate can be carried out from the holding member.

According to a seventh aspect of the present invention, there is provided a third exposure apparatus, comprising: the substrate holding device of the present invention; and a pattern forming device that forms a predetermined pattern on the substrate mounted on the substrate holding device by exposing the substrate using an energy beam.

According to an eighth aspect of the present invention, there is provided a fourth exposure apparatus, comprising: a substrate holding device that includes a holding member having a holding surface parallel to a horizontal plane, on the holding surface a substrate being mounted and at the holding member a plurality of groove sections being formed; and an exposure system that exposes the substrate held on the substrate holding device with an energy beam, wherein the groove sections are capable of housing a part of a substrate supporting member that supports the substrate from below and allow removal of the part of the substrate supporting member by relative movement of the substrate supporting member to one side in a first direction parallel to the horizontal plane.

With the third and fourth exposure apparatuses described above, the substrate can be delivered onto the holding surface in conjunction with an operation of housing the substrate supporting member in the groove sections. Further, the substrate supporting member is capable of speedily carrying out the substrate from the holding member by relative movement to one side in a first direction with respect to the holding member. Consequently, the cycle time needed when a substrate on the substrate holding device is exchanged can be reduced, and the throughput can be improved as a consequence.

According to a ninth aspect of the present invention, there is provided an exposure method of exposing a substrate held on a substrate holding device with an energy beam, the method comprising: carrying in the substrate to the substrate holding device by carrying the substrate in a state mounted on a substrate supporting member; and carrying out the substrate held on the substrate holding device, from the substrate holding device, by carrying the substrate in a state mounted on a substrate supporting member, wherein at least during one of the carry-in of the substrate to the substrate holding device and the carry-out of the substrate from the substrate holding device, a shift of a position of the substrate with respect to the substrate supporting member used in the carry of the substrate is restrained or prevented.

According to a tenth aspect of the present invention, there is provided an exposure apparatus, comprising: a substrate holding device on which a substrate is mounted; a carry-in device that carries in the substrate to the substrate holding device by carrying the substrate in a state mounted on a substrate supporting member; a carry-out device that carries out the substrate held by the substrate holding device, from the substrate holding device, by carrying the substrate in a state mounted on a substrate supporting member; and an exposure system that exposes the substrate held on the substrate holding device with an energy beam, wherein at least during one of the carry-in of the substrate to the substrate holding device and the carry-out of the substrate from the substrate holding device, a shift of a position of the substrate with respect to the substrate supporting member used in the carry of the substrate is restrained or prevented.

According to another aspect of the present invention, there is provided a device manufacturing method, comprising: exposing the substrate using any one of the first to fifth exposure apparatuses described above or the exposure method described above; and developing the substrate that has been exposed.

### BRIEF DESCRIPTION OF DRAWINGS

In the accompanying drawings;

FIG. 1 is a view showing a schematic configuration of a liquid crystal exposure apparatus related to a first embodiment;

FIG. 2 is a view of a configuration of a substrate stage device and a configuration of a substrate exchanging device that the liquid crystal exposure apparatus shown in FIG. 1 has;

FIG. 3A is a plan view of a substrate holder that the substrate stage device has, and FIG. 3B is a cross-sectional view sectioned along a line A-A of FIG. 3A;

FIG. 4A is a plan view of a substrate tray that supports a substrate, FIG. 4B is a side view of the substrate tray viewed from the −Y side, and FIG. 4C is a side view of the substrate tray viewed from the +X side;

FIG. 5A is a plan view showing a state where a substrate is mounted on the substrate holder, and FIGS. 5B and 5C are views used to explain an operation of tray guide devices that the substrate holder has;

FIG. 6 is a side view of a substrate carry-out device viewed from the +X side;

FIG. 7 is a plan view showing the substrate holder and a substrate carry-in device;

FIGS. 8A to 8C are views (No. 1 to No. 3) used to explain an operation of when exchange of a substrate on the substrate stage is performed;

FIGS. 9A to 9C are views (No. 4 to No. 6) used to explain the operation of when the exchange of the substrate on the substrate stage is performed;

FIGS. 10A to 10C are views (No. 7 to No. 9) used to explain the operation of when exchange of the substrate on the substrate stage is performed;

FIGS. 11A to 11C are views (No. 10 to No. 12) used to explain the operation of when the exchange of the substrate on the substrate stage is performed;

FIGS. 12A to 12C are views (No. 13 to No. 15) used to explain the operation of when the exchange of the substrate on the substrate stage is performed;

FIGS. 13A to 13C are views (No. 16 to No. 18) used to explain the operation of when the exchange of the substrate on the substrate stage is performed;

FIG. 14A is a plan view of a substrate tray used in a liquid crystal exposure apparatus related to a second embodiment, and FIG. 14B is a side view of the substrate tray shown in FIG. 14A;

FIG. 15A is a plan view of a substrate holder of a substrate stage related to the second embodiment, and FIGS. 15B and 15C are cross-sectional views of the substrate holder in a state combined with the substrate tray;

FIG. 16A is a plan view of a substrate tray used in a liquid crystal exposure apparatus related to a third embodiment, and FIG. 16B is, a view showing an operation of the substrate tray;

FIG. 17 is a plan view of a substrate tray used in a liquid crystal exposure apparatus related to a fourth embodiment;

FIG. 18 is a cross-sectional view of a substrate stage that a liquid crystal exposure apparatus related to a fifth embodiment is equipped with;

FIG. 19 is a plan view of a substrate holder and a substrate carry-in device related to a sixth embodiment;

FIG. 20 is a view (No. 1) used to explain an operation of when performing exchange of a substrate on a substrate stage related to the sixth embodiment;

FIG. 21 is a view (No. 2) used to explain the operation of when performing the exchange of the substrate on the substrate stage related to the sixth embodiment;

FIG. 22 is a view (No. 3) used to explain the operation of when performing the exchange of the substrate on the substrate stage related to the sixth embodiment;

FIG. 23 is a view (No. 4) used to explain the operation of when performing the exchange of the substrate on the substrate stage related to the sixth embodiment;

FIG. 24 is a view (No. 5) used to explain the operation of when performing the exchange of the substrate on the substrate stage related to the sixth embodiment;

FIG. 25 is a view showing a modified example (No. 1) of a substrate tray and a modified example of a substrate carry-out device;

FIG. 26 is a side view showing a modified example (No, 2) of a substrate tray;

FIGS. 27A to 27C are views showing modified examples (No. 3 to No. 5) of a substrate tray;

FIG. 28 is a view showing a modified example (No. 6) of a substrate tray and a substrate holder;

FIG. 29 is a view showing a modified example of a lift device;

FIGS. 30A and 30B are views showing a modified example of a substrate carry-in device;

FIGS. 31A and 31B are views showing a modified example (No. 7) of a substrate tray; and

FIG. 32A is a view showing a modified example (No. 8) of a substrate tray, and FIG. 32B is a view showing a substrate carry-out device that carries out the substrate tray shown in FIG. 32A.

### DESCRIPTION OF EMBODIMENTS

### First Embodiment

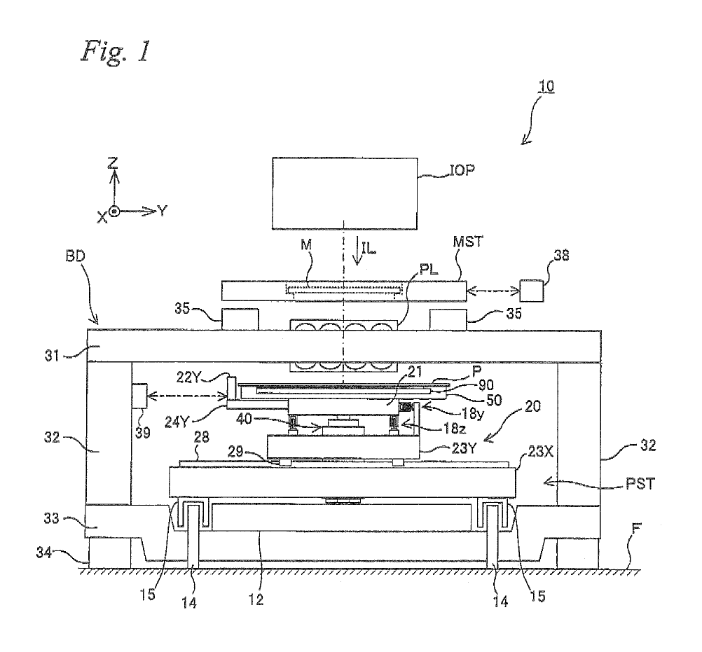

A first embodiment of the present invention is described below, with reference to FIGS. 1 to 13C.

FIG. 1 schematically shows a configuration of a liquid crystal exposure apparatus 10 related to the first embodiment, which is used in manufacturing of flat-panel displays, e.g. liquid crystal display devices (liquid crystal panels) and the like. Liquid crystal exposure apparatus 10 is a projection exposure apparatus by a step-and-scan method, in which a rectangular glass substrate P (hereinafter, simply referred to as a substrate 2) that is used for, for example, a display panel of a liquid crystal display device or the like serves as an exposure subject, which is a so-called scanner.

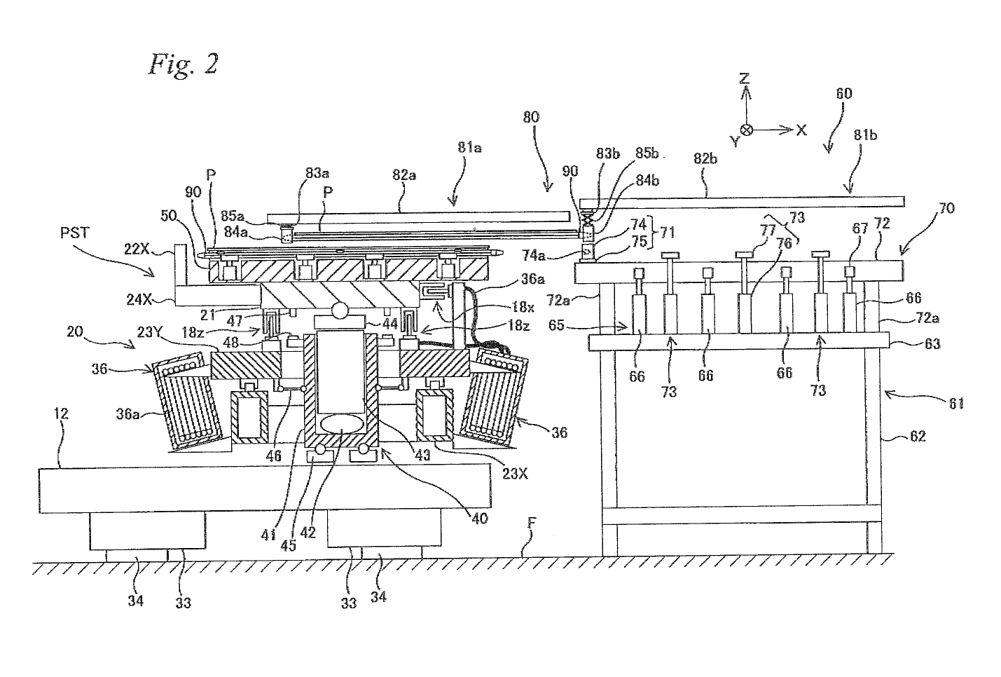

Liquid crystal exposure apparatus 10 is equipped with an illumination system 10P, a mask stage MST that holds a mask M, a projection optical system PL, a body SD on which mask stage MST and projection optical system PL described above and the like are mounted, a substrate stage device PST including a substrate holder 50 that holds substrate P, substrate exchanging device 60 (not illustrated in FIG. 1, see FIG. 2) that performs exchange of substrate P on substrate holder 50, and their control system, and the like. In this case, in FIG. 2, substrate P is mounted on substrate stage device PST and another substrate P is carried by substrate exchanging device 60 above substrate stage device PST. In the description below, the explanation is given assuming that a direction in which mask M and substrate P are relatively scanned with respect to projection optical system PL, respectively, during exposure is an X-axis direction (X direction), a direction orthogonal to the X-axis direction within a horizontal plane is a Y-axis direction (Y direction), and a direction orthogonal to the X-axis and the Y-axis is a Z-axis direction (Z direction), and rotational (tilt) directions around the X-axis, Y-axis and Z-axis are θx, θy and θz directions, respectively.

Illumination system IOP is configured similar to the illumination system that is disclosed in, for example, U.S. Pat. No. 5,729,331 and the like. More specifically, illumination system IOP irradiates mask M with a light emitted from a light source that is not illustrated (e.g. a mercury lamp), as an illumination light for exposure (illumination light) IL, via a reflection mirror, a dichroic mirror, a shutter, a wavelength selecting filter, various types of lenses and the like, which are not illustrated. As illumination light IL, for example, a light such as an i-line (with a wavelength of 365 nm), a g-line (with a wavelength of 436 nm) or an h-line (with a wavelength of 405 nm) (or a synthetic light of the i-line, the g-line and the h-line described above) is used. Further, the wavelength of illumination light IL can be appropriately switched by the wavelength selecting filter, for example, according to the required resolution.

On mask stage MST, mask M having a pattern surface (the lower surface in FIG. 2) on which a circuit pattern and the like are formed is fixed by, for example, vacuum adsorption (or electrostatic adsorption). Mask stage MST is supported by levitation in a noncontact state, for example, via air bearings that are not illustrated, above a pair of mask stage guides 35 that are fixed to the upper surface of a barrel surface plate 31 that is a part of body BD to be described later on. Mask stage MST is driven in a scanning direction (the X-axis direction) with predetermined strokes and also is finely driven in each of the Y-axis direction and the θz direction as needed, above the pair of mask stage guides 35, by a mask stage driving system (not illustrated) that includes, for example, a linear motor. Positional information of mask stage MST within the XY plane (which includes rotational information in the θz direction) is measured by a mask interferometer system 38 that includes a laser interferometer that irradiates a reflection surface arranged (or formed) on mask stage MST with a measurement beam.

Projection optical system PL is supported below mask stage MST in FIG. 1, by barrel surface plate 31. Projection optical system PL is configured similar to the projection optical system disclosed in, for example, U.S. Pat. No. 5,729,331. More specifically, projection optical system PL includes a plurality of projection optical systems whose projection areas of a pattern image of mask M are placed in, for example, a zigzag shape (a multi-lens projection optical system), and functions equivalent to a projection optical system that has a single rectangular image field with the Y-axis direction serving as its longitudinal direction. In the present embodiment, as each of the plurality of projection optical systems, for example, a both-side telecentric equal-magnification system that forms an erected normal image is used. Further, in the description below, the plurality of projection areas placed in the zigzag shape of projection optical system P1 are collectively referred to as an exposure area IA (see FIG. 2).

Therefore, when an illumination area on mask M is illuminated with illumination light IL from illumination system IOP, by illumination light IL that has passed through mask M, a projected image (partial erected image) of a circuit pattern of mask M within the illumination area is formed, via projection optical system PL, on an irradiation area (the exposure area) of illumination light IL, which is conjugate to the illumination area, on substrate P which is placed on the image plane side of projection optical system PL and whose surface is coated with a resist (sensitive agent). Then, by relatively moving mask M with respect to the illumination area (illumination light IL) in the scanning direction (X-axis direction) and also relatively moving substrate P with respect to the exposure area (illumination light IL) in the scanning direction (X-axis direction) by synchronous drive of mask stage MST and substrate stage device PST, scanning exposure of one shot area (divided area) on substrate P is performed, and a pattern of mask M is transferred onto the shot area. More specifically, in the present embodiment, a pattern of mask II is generated on substrate P by illumination system IOP and projection optical system PL, and the pattern is formed on substrate P by exposure of a sensitive layer (resist layer) on substrate P with illumination light IL.

Body BD has a substrate stage mount 33, and barrel surface plate 31 that is horizontally supported via a pair of support members 32 on substrate stage mount 33, as disclosed in, for example, U.S. Patent Application Publication No. 2008/0030702 and the like. Substrate stage mount 33 is made up of a member whose longitudinal direction is in the Y-axis direction, and as shown in FIG. 2, two (a pair of) substrate stage mounts 33 are arranged at a predetermined distance in the X-axis direction. Both ends of each of substrate stage mounts 33 in the longitudinal direction are each supported by a vibration isolation device 34 installed on a floor surface F, and are separated from floor surface F in terms of vibration. Accordingly, body BD, projection optical system PL supported by body BD and the like are separated from floor surface F in terms of vibration.

Substrate stage device PST is equipped with a surface plate 12 fixed on substrate stage mounts 33, a pair of base frames 14 placed at a predetermined distance in the Y-axis direction, and a substrate stage 20 mounted on the pair of base frames 14.

Surface plate 12 is made up of a plate-shaped member formed by, for example, a stone material and having a rectangular shape in a planar view (when viewed from the +Z side), and its upper surface is finished so as to have a very high flatness degree.

One of the pair of base frames 14 is placed on the +Y side of surface plate 12 and the other is placed on the −Y side of surface plate 12. Each of the pair of base frames 14 is made up of a member extending in the X-axis direction, and is fixed to floor surface F in a state bridging over substrate stage mounts 33. Incidentally, although not illustrated in FIG. 1, the pair of base frames 14 have X linear guide members used to linearly guide an X coarse movement stage 23X to be described later on, which is a part of substrate stage 20, in the X-axis direction, X stators (e.g. coil units) that configure X linear motors used to drive X coarse movement stage 23x, and the like.

Substrate stage 20 includes X coarse movement stage 23X mounted on the pair of base frames 14, a Y coarse movement stage 23Y mounted on X coarse movement stage 23X and configuring, together with X coarse movement stage 23X, an XY two-axial stage, a fine movement stage 21 placed on the +Z side of (above) Y coarse movement stage 23Y, a weight cancelling device 42 that supports fine movement stage 21 on surface plate 12, and a substrate holder 50 that is mounted on fine movement stage 21 and holds substrate P.

X coarse movement stage 23X is made up of a frame-like (frame-shaped) member having an rectangular outer shape in a planar view, and has an opening section (see FIG. 2) having a long hole shape whose longitudinal direction is in the Y-axis direction, in its center portion. On the lower surface of X coarse movement stage 23X, as shown in FIG. 1, a pair of stage guides 15 each formed so as to have an inversed U-like YZ cross sectional shape are fixed corresponding to the pair of base frames 14. Although not illustrated in FIG. 1, stage guides 15 have slide members that engage with the X linear guide members (not illustrated), which base frames 14 have, so as to be slidable with respect to the X linear guide members, X movers (e.g. magnet units) that configure, together with the X stators described above, X linear motors, and the like. X coarse movement stage 23X is linearly driven with predetermined strokes in the X-axis direction on the pair of base frames 14, by an X coarse movement stage driving system that includes the X linear motors. Further, on the upper surface of X coarse movement stage 23x, Y linear guide members 28 extending in the Y-axis direction are fixed. A plurality of Y linear guide members 28 are arranged spaced apart in the X-axis direction. Further, although not illustrated in the drawings, on the upper surface of X coarse movement stage 23x, a Y stator (e.g. a coil unit) that configures a Y linear motor used to drive Y coarse movement stage 23Y is fixed.

Y coarse movement stage 23Y is made up of a frame-like member having a rectangular outer shape in a planar view whose size in the Y-axis direction is shorter than that of X coarse movement stage 23X, and has an opening section (see FIG. 2) in its center portion. On the lower surface of Y coarse movement stage 23Y, a plurality of slide members 29, which engage with X linear guide members 28 slidable with respect to Y linear guide members 28, are fixed. Further, although not illustrated in FIG. 1, on the lower surface of Y coarse movement stage 23X, a Y mover (e.g. a magnet unit) that configures, together with the Y stator described above, the Y linear motor is fixed. Y coarse movement stage 23Y is driven with predetermined strokes in the Y-axis direction on X coarse movement stage 23X, by a Y coarse movement stage driving system that includes the Y linear motor. Positional information of each of X coarse movement stage 23X and Y coarse movement stage 23Y is measured with, for example, a linear encoder system that is not illustrated. Incidentally, the drive method to drive X coarse movement stage 23X and Y coarse movement stage 23Y in the X-axis direction and the Y-axis direction, respectively, can be another method such as a drive method by feed screws or a belt drive method. Further, the positional information of each of X coarse movement stage 23X and Y coarse movement stage 23Y can be obtained in another measurement method, e.g., an optical interferometer system or the like.

Between X coarse movement stage 23X and Y coarse movement stage 23Y, as shown in FIG. 2, cables 36a for supplying the electric power to, for example, a voice coil motor used to drive fine movement stage 21 that is described later and the like are installed via a pair of cable guide devices 36. Cable guide devices 36 appropriately guide cables 36a, in accordance with the position of Y coarse movement stage 23Y on X coarse movement stage 23X. Incidentally, in FIG. 1, from the viewpoint of avoiding intricacy of the drawing, the illustration of the cable guide devices is omitted.

Fine movement stage 21 is made up of a rectangular parallelepiped-shaped member of a low height with a roughly square shape in a planar view. On the side surface the −Y side of fine movement stage 21, as shown in FIG. 1, a Y movable mirror (bar mirror) 22Y having a reflection surface orthogonal to the Y-axis is fixed via a mirror base 241. Further, on the side surface the −X side of fine movement stage 21, as shown in FIG. 2, an X movable mirror (bar mirror) 22x having a reflection surface orthogonal to the X-axis is fixed via a mirror base 24X. Positional information of fine movement stage 21 within the XY plane is constantly detected at a resolution of, for example, around 0.5 to 1 nm with a substrate interferometer system 39 (see FIG. 1) that includes at least two laser interferometers that irradiate movable mirror 22Y and X movable mirror 22X, respectively, with measurement beams and receive reflection lights of the measurement beams. Incidentally, while substrate interferometer system 39 actually has an X laser interferometer and a Y laser interferometer that correspond to Y movable mirror 22Y and X movable mirror 22X, substrate interferometer system 39 is illustrated in FIG. 1, representing these laser interferometers.

As shown in FIG. 2, fine movement stage 21 is finely driven in directions of six degrees of freedom (X-axis, Y-axis, Z-axis, θx, θy and θz directions) on Y coarse movement stage 23Y, for example, by a fine movement stage driving system that has a plurality of voice coil motors by the electromagnetic force (Lorentz force) drive method (X voice coil motors 18x (see FIG. 2), Y voice coil motors 18y (see FIG. 1), and Z voice coil motors 18z (see FIGS. 1 and 2)) each including a stator (e.g. a coil unit) fixed to Y coarse movement stage 23Y and a mover (e.g. a magnet unit) fixed to fine movement stage 21. Incidentally, the illustration of the X voice coil motors is omitted in FIG. 1 from the viewpoint of avoiding intricacy of the drawing. Accordingly, fine movement stage 21 is capable of moving (coarsely moving) with long strokes in the XY two-axial directions together with Y coarse movement stage 23Y, and is also capable of finely moving (performing fine movement) in the directions of six degrees of freedom on coarse movement stage 23Y, with respect to projection optical system PL. Note that a plurality of X voice coil motors 18X are arranged along the Y-axis direction and a plurality of Y voice coil motors 18y are arranged along the X-axis direction (in FIGS. 1 and 2, the plurality of X voice coil motors 18x overlap and the plurality of Y voice coil motors overlap in depth directions, respectively). Further, Z voice coil motor 18z is arranged at three or more noncollinear positions (e.g. at least three positions of the positions corresponding to four corners of fine movement stage 21).

As shown in FIG. 2, weight canceling device 40 is made up of a columnar member arranged extending in the Z-axis direction, and is also referred to as a center pillar. Weight canceling device 40 has a housing 41, an air spring 42 and a slide section 43.

Housing 41 is made up of a cylinder-like member having a bottom whose +Z side is opened, and is inserted in the opening section of X coarse movement stage 23X and the opening section of Y coarse movement stage 23Y. Housing 41 is supported in a noncontact manner above surface plate 12 by a plurality of static gas bearings, e.g. air bearings 45, attached to the lower surface of housing 41. Housing 41 is connected to Y coarse movement stage 23Y at the height position (Z-position) that includes a position of center of gravity of weight canceling device 40 by a plurality of interlinking devices 46 (which are also referred to as flexure devices) that include plate springs, and moves integrally with Y coarse movement stage 23Y in the X-axis direction and/or the Y-axis direction.

Slide section 43 is made up of a cylinder-like member housed inside housing 41, and is placed above air spring 42. Air spring 42 is housed in the lowermost section within housing 41. A gas (e.g. air) is supplied from a gas supplying device that is not illustrated to air spring 42, and the inside of air spring 42 is set to be a positive pressure space whose atmospheric pressure is higher compared with the outside. Weight cancelling device 40 makes slide section 43 vertically move by appropriately changing the inner pressure of air spring 42 in accordance with the position in the Z-axis direction (Z-position) of fine movement stage 21 that is driven by Z voice coil motors 18z.

Weight canceling device 40 supports the center portion of fine movement stage 21 from below via a device that is referred to as a leveling device 44 including a ball. Leveling device 44 is supported in a noncontact manner (by levitation) by slide section 43 with a plurality of noncontact bearings (e.g. air bearings) that are not illustrated attached to the upper surface of slide section 43. Accordingly, fine movement stage 21 moves integrally with slide section 43 in the Z-axis direction, whereas fine movement stage 21 freely tilts (freely slides) with respect slide section 43 in the θx direction and the θy direction.

Weight cancelling device 40 reduces the load on the plurality of Z voice coil motors 18z by cancelling out the weight (a downward force in the −Z direction) owing to the gravitational acceleration) of a system including fine movement stage 21 (to be specific, a system composed of fine movement stage 21, substrate holder 50, substrate P and the like) with an upward force (in the +Z direction) generated by air spring 42.

Positional information of fine movements stage 21 in the Z-axis direction and the θx and θy directions with respect to weight cancelling device 40 (a movement distance in the Z-axis direction, and a tilt amount with respect to a horizontal plane) is obtained by a plurality of laser displacement sensors 47 (which are also referred to z sensors) that measure the positions in the Z-axis direction of targets 48 fixed to housing 41 of weight canceller 40 via arm members. The plurality of laser displacement sensors 47 are fixed to the lower surface of fine movement stage 21. The configuration of weight cancelling device 40 that includes interlinking devices 46 (flexure devices) described above is disclosed in, for example, U.S. Patent Application Publication No 2010/0018950 and the like.

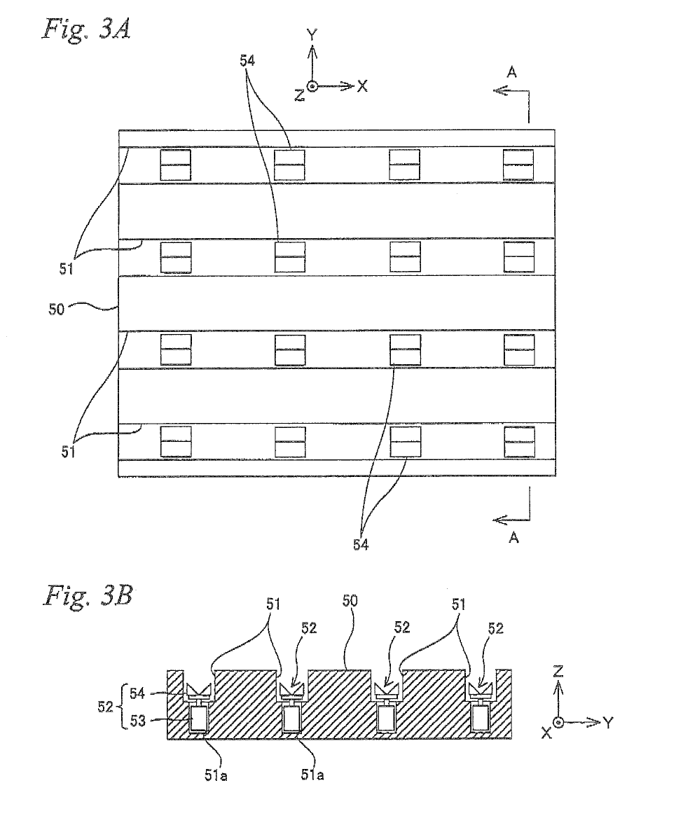

As can be seen from FIGS. 2 and 3A, substrate holder 50 is made up of a rectangular parallelepiped member having a size in the Z-axis direction (thickness) is smaller than a size in the X-axis direction and the Y-axis direction (length and width), and is fixed to the upper surface of fine movement stage 21. The upper surface of substrate holder 50 is rectangular with the X-axis direction serving as its longitudinal direction in a planar view (when viewed from the +Z direction), and the size in the X-axis direction and the size in the Y-axis direction are set slightly shorter than those of substrate P. Substrate holder 50 has an adsorption device that is not illustrated to hold by adsorption substrate P by vacuum adsorption (or electrostatic adsorption), on its upper surface (+Z side surface).

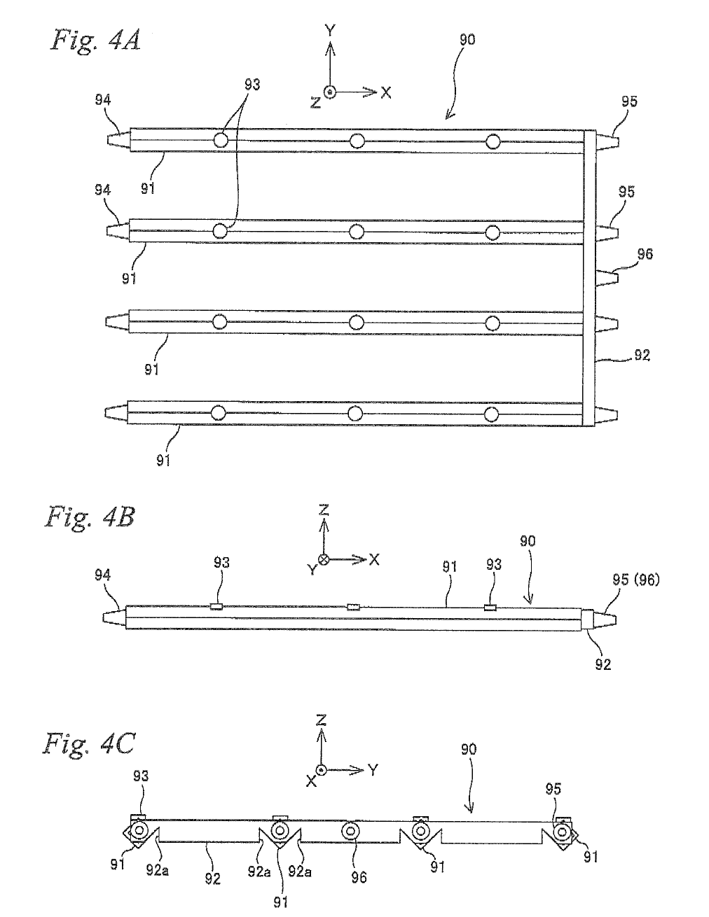

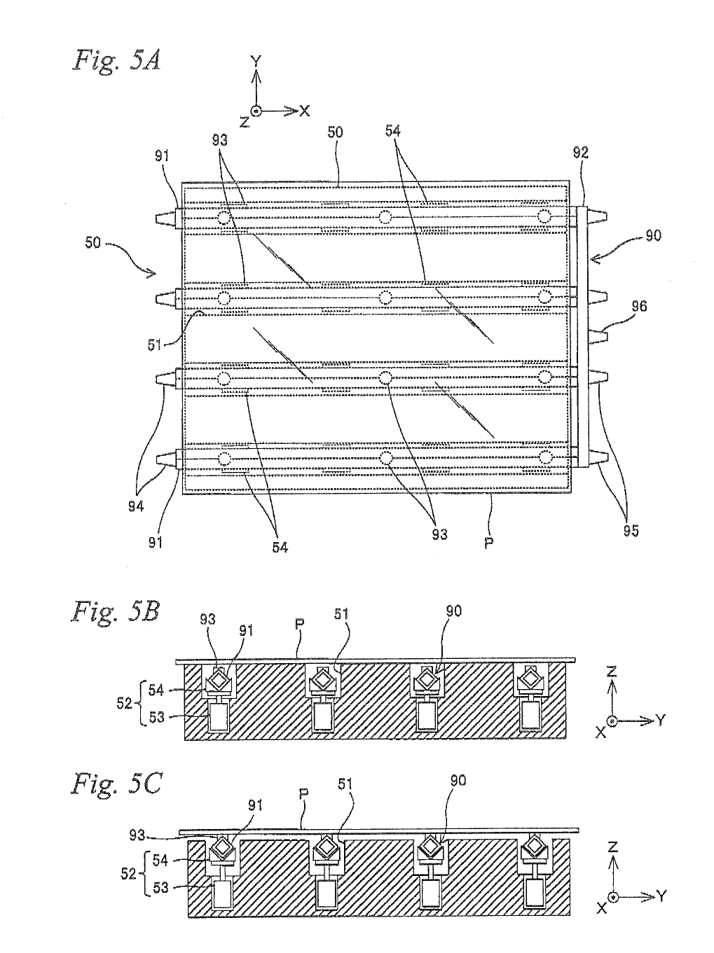

In this case, in liquid crystal exposure apparatus 10, the carry-in (loading) of substrate P to substrate stage 20 and the carry-out (unloading) of substrate P from substrate stage 20 are performed in a state where substrate P is mounted on a member that is referred to as a substrate tray 90 shown in FIG. 4A. As shown in FIG. 4A, substrate tray 90 has a plurality (e.g. four at a predetermined distance in the Y-axis direction) of support sections 91 that are each made up of a bar-shaped member extending in the X-axis direction, and the +X side end of each of four support sections 91 is connected to a connecting section 92 made up of a plate-shaped member parallel to the YZ plane, and substrate tray 90 has a comb-like outer shape in a planar view. Substrate P is mounted, on, for example, four support sections 91. Substrate tray 90 is capable of restraining deformation (such as bending) of substrate P owing to, for example, the empty weight of the substrate, and can also be referred to as a substrate mounting member, a carry auxiliary member, a deformation restraining member, a substrate supporting member, or the like. Incidentally, the configuration of substrate tray 90 is described later in detail. On the upper surface of substrate holder 50, as shown in FIG. 3A, a plurality (e.g. four) of groove sections 51 parallel to the X-axis are formed at a predetermined distance in the Y-axis direction. The depth of each of four grove sections 51 is, for example, around a half the thickness of substrate holder 50 (see FIG. 3B). The length of groove section 51 is the same as the length of substrate holder 50 in the present embodiment, and on the side surface (end surface) on each of the +X side and the −X side of substrate holder 50, an opening section is formed. In groove sections 51, as shown in FIG. 5B, support sections 91 of substrate tray 90 are housed. In this case, the depth of groove section 51 should be set such that the upper surface of substrate tray 90 is located flush with the surface of substrate holder 50 or at a position lower than the surface of substrate holder 50 when substrate tray 90 is mounted on substrate holder 50, and the length of groove section 51 can be shorter than that of the substrate holder, for example, in the case where the substrate tray supports substrate P in a cantilever state.

As shown in FIG. 3B, substrate holder 50 has a plurality of tray guide devices 52 inside thereof. Tray guide devices 52 are devices that support, from below, support sections 91 (see FIG. 5B) of substrate tray 90 housed in groove sections 51. As shown in FIG. 3B, tray guide device 52 includes an air cylinder 53 housed in a recessed section 51a formed on the inner bottom surface of groove section 51, and a guide member 54 fixed to the tip (the +Z side end) of a cylinder rod (hereinafter, referred to as a rod) of air cylinder 53. In one groove section 51, four recessed sections 51a that house air cylinders 53 are formed at a predetermined distance in the X-axis direction. Consequently, a total of 16 tray guide devices 52 are provided (see FIG. 3A).

As can be seen from FIGS. 3A and 35, guide member 54 has a rectangular plate-shaped member, and a pair of triangular prism members mounted on the upper surface of the plated-shaped member such that the slopes of the respective triangular prism members form a V-shaped groove section when viewed from the X-axis direction, and guide member 54 has en outer shape like a jig that is referred to as a so-called V-block. Hereinafter, the description is made referring to the groove section formed by the pair of triangular prism members as a V groove section. As shown in FIGS. 55 and 5C, guide member 54 moves (vertically moves) with predetermined strokes in the Z-axis direction within groove section 51, in accordance with the air supply pressure to air cylinder 53. In this case, although, in air cylinder 53, the rod performs reciprocating movement along the Z-axis and the air cylinder itself does not expand or contract, the overall length of the air cylinder including the driven member of the tip of the rod changes according to the reciprocating movement of the rod, and therefore, in the description below, the case where the rod moves such that the overall length of the air cylinder is elongated is expressed as air cylinder 53 expanding or being expanded or the case where the rod reversely moves is expressed as air cylinder 53 contracting or being contracted. Note that the same can be said for the other air cylinders to be described later besides air cylinders 53. Incidentally, the actuator to make guide member 54 vertically move is not limited to the air cylinder but can be an actuator using, for example, a screw mechanism, a link mechanism or the like. Further, on the V groove surface of guide member 54, a plurality of fine holes that are not illustrated are formed. Guide member 54 has a function that levitates substrate tray 90 via a minute space (gap/clearance) by jetting a high-pressure gas (e.g. air) from the plurality of holes. Further, guide member 54 can also hold substrate tray 90 by adsorption by vacuum suctioning via the plurality of holes. Incidentally, tray guide device 52 is not limited to a levitation type (noncontact type) device that supports substrate tray 90 in a noncontact manner, but can be a contact type device that supports substrate tray 90, for example, using bearings or the like.

Next, substrate tray 90 is described with reference to FIGS. 4A to 4C. As described earlier, substrate tray 90 is a member having a comb-like outer shape in a planar view that includes, for example, four support sections 91 and connecting section 92 that connects four support sections 91. Each of four support sections 91 is made up of a bar-shaped hollow member extending in the X-axis direction and having a rhombic YZ sectional shape. Four support sections 91 are disposed in the Y-axis direction at a distance corresponding to a distance between groove sections 51 formed at substrate holder 50 described earlier. The size of support section 91 in the X-axis direction is set to be longer than the size of substrate P in the X-axis direction (see FIG. 5A). Four support sections 91 and connecting section 92 are formed by, for example, MMC (Metal Matrix Composites) CFRP (Carbon Fiber Reinforced Plastics), C/C composites (Carbon Fiber Reinforced composites), or the like, and are lightweight and have high stiffness. Consequently, distortion of substrate P mounted on four support sections 91 can be restrained.

Further, on the upper end (top) of each of four support sections 91, a plurality (e.g. three) of pads 93 are attached at a predetermined distance in the X-axis direction each of which has a support surface parallel to a horizontal plane. Substrate tray 90 supports substrate P from below with the plurality of pads 93 (see FIG. 5C).

On each of the surfaces of four support sections 91 and connecting section 92 of substrate tray 90, for example, a black anodic oxide film is formed. When the exposure processing is performed to substrate P, substrate tray 90 is housed in groove sections 51 of substrate holder 50, as shown in FIG. 5B, and therefore, there is a possibility that illumination light IL (see FIG. 1) is irradiated on the surface of substrate tray 90, but because the black anodic oxide film described above is formed, reflection of illumination light IL is restrained. Further, the black anodic oxide film formed on substrate tray 90 described above restrains degradation of materials that configure substrate tray 90 due to irradiation of illumination light IL or generation of outgassing that causes loss of transparency of the projection lens that projection optical system PL has. Incidentally, the materials that form the substrate tray are not limited those described above. Also, the number of the bar-shaped members that support the substrate from below is not limited in particular, and can be appropriately changed according to the size, the thickness and the like of the substrate. Further, if it is possible to make the surface of substrate tray 90 have a low reflectance and to restrain the degradation of the materials due to the illumination light, the generation of outgassing and the like, surface treatment is not limited to the one with the anodic oxide film described above, but also another surface treatment can be applied to substrate tray 90.

To a −X side end (hereinafter, referred to as a tip as needed) of each of four support sections 91, a taper member 94 (a member having a circular truncated cone shape) having a taper surface (in this case, a surface like an outer peripheral surface of a circular truncated cone) that becomes thinner toward the −X side is fixed. Further, on the side surface on the +X side of connecting section 92, four taper members 95 each having a taper surface that becomes thinner toward the +X side are fixed at a distance corresponding to distance between four support sections 91. Furthermore, to the center of the side surface on the +X side of connecting section 92, another taper member 96 having a taper surface that becomes thinner toward the +X side is fixed.

A plurality of piping members, which are not illustrated, are built in support sections 91 and connecting section 92, and taper member 96 communicate with each of pads 93 by the piping members. In each of the upper surfaces of pads 93 and taper member 96, a hole section that is not illustrated is formed, and when a gas is suctioned from the hole section on the taper member 96 side, substrate P (see FIG. 5A) mounted on pads 93 is held by adsorption by pads 93.

Further, as shown in FIG. 4C, at the lower end of connecting section 92, a plurality of notches 92a each having a right triangular shape in a side view when viewed from the +X side are formed. Notches 92a are formed on the +Y side and the −Y side of each of taper members 95 (in this case, except for the −Y side of taper member 95 on the most −Y side and the +Y side of taper member 94 on the most +Y side). A pair of notches 92a respectively formed on the +Y side and the −Y side of taper member 95 are formed bilaterally symmetric in a side view when viewed from the X-axis direction (so as to be an M shape in a side view when viewed from the X-axis direction). The functions of the plurality of notches 92a are described later on.

Further, groove sections 51 (see FIG. 3B) of substrate holder 50 described earlier are formed with a width and a depth capable of housing support sections 91, and support sections 91 are, as shown in FIG. 5B, housed in groove sections 51 of substrate holder 50 and supported by guide members 54 from below (mounted on guide members 54). In a state where support sections 91 are supported by guide members 54, the lower portions of support sections 91 are inserted into the V groove sections of guide members 54, and therefore, relative movement of substrate tray 90 with respect to substrate holder 50 in the Y-axis direction is restricted. Further, as shown in FIG. 5B, the movement lower limit position of guide members 54 is set such that when guide members 54 that support substrate tray 90 are moved to the −Z side, the lower surface of substrate P and the upper surfaces of pads 93 can be separated and substrate P can be mounted on the upper surface of substrate holder 50.

Further, the movement upper limit position of the guide members 54 is set such that when substrate tray 90 is supported from below by guide members 54, guide members 54 are moved in the +Z direction, and as shown in FIG. 5C, thereby pads 93 of substrate tray 90 and substrate P can be made to come in contact and the lower surface of substrate P can be separated from the upper surface of substrate holder 50. However, in a state where guide members 54 are located on the most +Z side in its movable range, the lower half or more (e.g. around three quarters) of support sections 91 remain housed in groove sections 51.

Next, substrate exchanging device 60 shown in FIG. 2 is described. Substrate exchanging device 60 has a frame 61 placed on the +X side of substrate stage device PST, a substrate carry-out device 70 mounted on frame 61, and a substrate carry-in device 80 placed above frame 61 and substrate stage device PST. Frame 61, substrate carry-out device 70 and substrate carry-in device 80 are all housed together with substrate stage device PST in a chamber that is not illustrated.

Frame 61 has a base 63 made up of a rectangular plate-shaped member in a planar view that is supported substantially parallel to a horizontal plane on floor surface F via a plurality of leg sections 62.

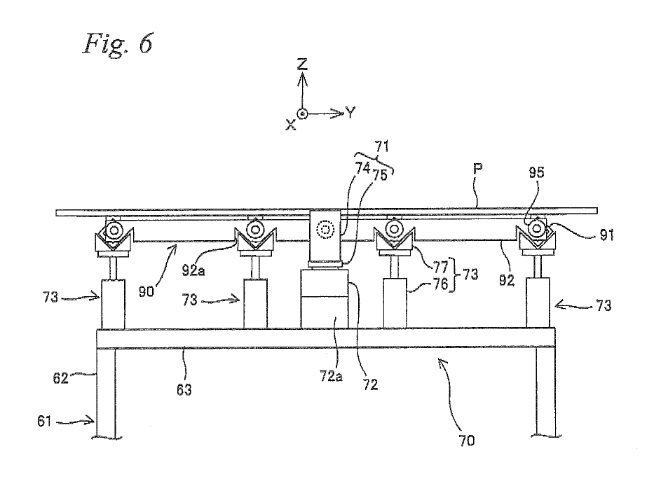

Substrate carry-out device 70 includes a grip device 71 that grips substrate tray 90, a drive device (actuator) that drives grip device 71 in the X-axis direction, e.g. a stator section 72 that includes a stator of a linear motor, a plurality of tray guide devices 73 that support substrate tray 90 on base 63, and a lift device 65 that moves substrate P apart from substrate tray 90. As can be seen from FIGS. 2 and 6, grip device 71 has a grip section 74 made up of a rectangular parallelepiped member and a mover section 75 connected to the lower end of grip section 74. On the −X side surface of grip section 74, a recessed section 74a having a taper surface that becomes narrower toward the +X side is formed. Recessed section 74a is formed so as to correspond to the outer shape of taper member 96 of substrate tray 90 described previously, and grip section 74 grips substrate tray 90 by, for example, vacuum adsorption, in a state where taper member 96 is inserted in recessed section 74a. Incidentally, as the method of grip section 74 gripping substrate tray 90, for example, magnetic adsorption or the like can also be employed. Further, a configuration of physically gripping taper member 96 with a mechanical chuck mechanism, e.g. a hook or the like, can also be employed. Mover section 75 has, for example, a magnet unit (the illustration is omitted) that includes a plurality of magnets, and configures an X linear motor by the electromagnetic force (Lorentz force) drive method that drives grip section 74 in the X-axis direction, together with a coil unit that stator section 72 has to be described below.

Stator section 72 is made up of a member extending in the X-axis direction whose both ends are supported from below by a pair of support columns 72a on base 63, and stator section 72 is equipped with a guide member that guides grip device 71 described above in the X-axis direction, a stator that has a coil unit including a plurality of coils (the illustration of the guide member and the coil unit is omitted), and the like.

In this case, the Z-position of recessed section 74a formed at grip section 74 is roughly the same as the z-position of taper member 96 (see FIG. 4A) of substrate tray 90 supported by the plurality of guide members 54 in a state where the plurality of guide members 54 that substrate holder 50 has are located at the movement upper limit position shown in FIG. 50. Consequently, the alignment of the position in the Y-axis direction (Y-position) of taper member 96 of substrate tray 90 and the Y-position of grip section 74 is performed in a state where grip section 74 is located in the vicinity of the −X side end of stator section 72 shown in FIG. 2, and substrate stage 20 is moved in the +X direction in such a state, and thereby taper member 96 is inserted into recessed section 74a of grasp section 74. At this point, even if the position of taper member 96 and the position of grip section 74 slightly deviate, taper member 96 is guided by the taper surface of the inner surface of recessed section 74a, and therefore, grip section 74 can reliably grip substrate tray 90. Then, when grip section 74 in a state gripping taper member 96 is driven in the +X direction by the X linear motor, substrate tray 90 moves integrally with grip section 74 in the +X direction and substrate tray 90 is pulled out of substrate holder 50. At this point, because the lower surface of substrate P is spaced apart from the upper surface of substrate holder 50 (see FIG. 5C), substrate P can be carried out from substrate holder 50. Incidentally, the one-axial drive device used to drive grip section 74 in the X-axis direction is not limited to the linear motor, but for example, a device by another method such as a feed screw device, a rack-and-pinion device, a belt method (or a chain method, a wire method and the like) drive device can also be used.

Further, one end of a piping member the other end of which is connected to a vacuum device is connected to grip section 74 (the illustration of the vacuum, device and the piping member is omitted). When substrate tray 90 and substrate P are carried out of substrate holder 50 using substrate carry-out device 70, a gas in the piping member, which is not illustrated, within substrate tray 90 is suctioned by the vacuum device in a state where grip section 74 grips taper member 96, and thereby substrate P is held by adsorption by pads 93. Accordingly, when substrate P is accelerated and decelerated, the shift of substrate P on substrate tray 90 is restrained.

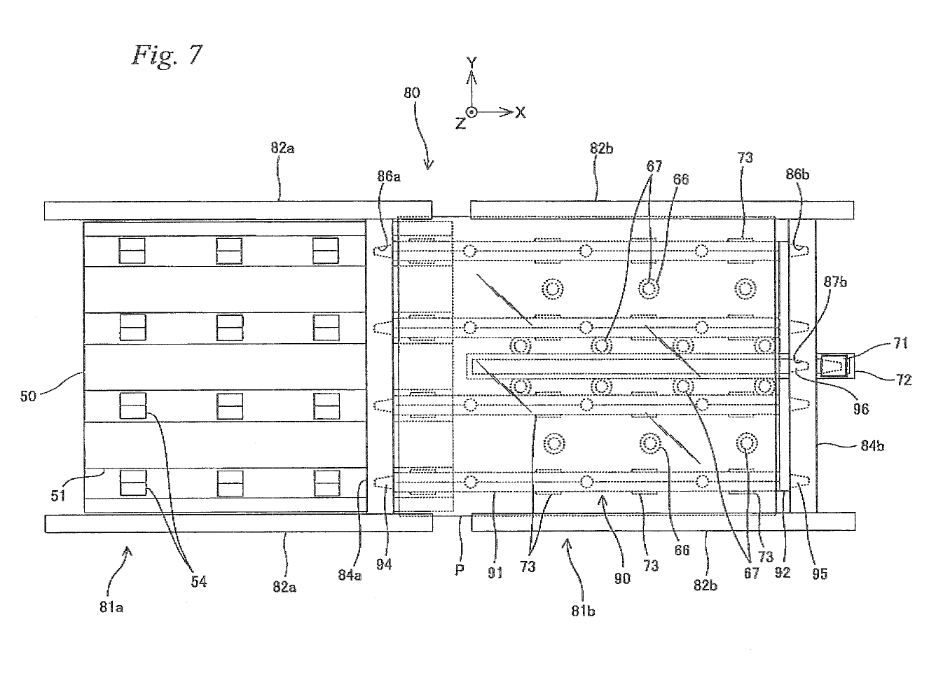

Substrate carry-out device 70 has, for example a total of twelve tray guide devices 73, and on base 63, for example, four rows of tray guide device rows, each of which is composed of, for example, three tray guide devices 73 disposed at a predetermined distance in the X-axis direction, are placed at a predetermined distance in the Y-axis direction (see FIG. 7). Each of twelve tray guide devices 73 has an air cylinder 76 fixed to base 63 and a guide member 77 connected to the tip of a rod of air cylinder 76. Respective air cylinders of twelve tray guide devices 73 are synchronously driven (controlled) by a main controller that is not illustrated. In this case, air cylinder 76 of each of twelve tray guide devices 73 does not necessarily have to be synchronously driven but can be driven in a temporally-shifted manner. Guide members 77 are substantially the same as guide members 54 of tray guide devices 52 that substrate holder 50 has. Note that similarly to guide members 54 of substrate holder 50, guide members 77 of substrate carry-out device 70 are capable of supporting by levitation substrate tray 90 by jetting a gas from the surfaces of the V groove sections. Further, guide members 77 are connected to air cylinders 76 so as to be rotatable in the θz direction. Incidentally, in the case where substrate tray 90 is formed by, for example, CFRP, generation of dust can be restrained by forming guide members 54 and 77, for example, with stone materials, even if substrate tray 90 and guide members 54 or 77 slide with each other (in this case, substrate tray 90 needs not be levitated).

In this case, for example, the distance in the Y-axis direction between the four rows of the tray guide device rows roughly coincides with the distance in the Y-axis direction of the four rows of the tray guide device rows (see FIG. 3A) that substrate holder 50 has. Further, the position of each of the plurality of tray guide devices 73 is set such that the position in the Y-axis direction of the four rows of the tray guide device rows that substrate carry-out device 70 has and that of the four rows of the tray guide device rows that substrate holder 50 has roughly coincide when alignment of substrate stage 20 in the Y-axis direction is performed to pull out substrate tray 90 from substrate holder 50. Further, the Z-positions of guide members 77 can be made to coincide with the Z-positions of guide members 54 of substrate holder 50, by air cylinders 76. Consequently, by making grip device 71 grip taper member 96 of substrate tray 90 and pulling substrate tray 90 out of substrate holder 50 in the +X direction, substrate tray 90 can be carried from the plurality of guide members 54 within substrate holder 50 and mounted on guide members 77. In this case, notches 92a (see FIG. 4C) formed at connecting section 92 of substrate tray 90 described previously are formed to prevent contact between connecting section 92 and guide members 77 when substrate tray 90 is pulled out of substrate holder 50 by substrate carry-out device 70. More specifically, as shown in FIG. 6, when substrate tray 90 moves in the +X direction on guide members 77, guide members 77 pass inside notches 92a. Incidentally, the one-axial drive device to vertically move guide members 77 is not limited to air cylinders 76, but for example, a screw (feed screw) drive device using a rotary motor, a linear motor drive device or the like can also be employed.

Lift device 65 is used to lift, for example, substrate P, to which the exposure processing has been completed, in the +Z direction in order to carry substrate P out from substrate tray 90 to a coater/developer device that is not illustrated, and has a plurality of air cylinders 66. As shown in FIG. 7, between the first row and the second row of the tray guide device rows when viewed from the −Y side, and between the third row and the fourth row of the tray guide device rows, for example, three air cylinders 66, of the plurality of air cylinders 66, are placed at a predetermined distance in the X-axis direction (six air cylinders 66 in total). Further, between the second row of the tray guide device rows, when viewed from the −Y side, and stator section 72, and between the third row of the tray guide device rows and stator section 72, for example, four air cylinders 66 are placed at a predetermined distance in the X-axis direction (eight air cylinders 66 in total). The plurality (fourteen in total) of air cylinders 66 are each fixed to base 63 and are synchronously driven by the main controller that is not illustrated. In this case, the plurality (fourteen in total) of air cylinders 66 do not necessarily have to be synchronously driven but can be driven in a temporally-shifted manner. Each of fourteen air cylinders 66 has a circular plate-shaped pad member 67 at the tip (the +Z side end) of a rod. Lift device 65 makes pad members 67 come in contact with the lower surface of substrate P in a state where substrate tray 90 is supported from below by the plurality of tray guide devices 73, and in this state, extend the plurality of air cylinders 66 in synchronization (or in a slightly temporally-shifted manner), thereby lifting substrate P in the +Z direction to move it apart from substrate tray 90.

As shown in FIG. 2, substrate carry-in device 80 has a first carrier unit 81a and a second carrier unit 81b. First carrier unit 81a is placed above substrate stage device PST, on the +X side of projection optical system PL (see FIG. 1). When substrate stage 20 moves to a position adjacent to frame 61 (the position shown in FIG. 2, hereinafter, referred to as a substrate exchange position) to perform exchange of substrate P, substrate stage 20 is located below first carrier unit 81a. As shown in FIG. 7, first carrier unit 81a includes a pair of stator sections 82a, a pair of mover sections 83a (not illustrated in FIG. 7, see FIG. 2) arranged so as to correspond to the pair of stator sections 82a, a grip section 84a that grips the −X side end of substrate tray 90, a pair of expansion/contraction devices 85a (not illustrated in FIG. 7, see FIG. 2) that are respectively connected to the pair of mover sections 83a and vertically move grip section 84a, and the like. Incidentally, in FIG. 2, one of the pair of stator sections 82a, one of the pair of mover sections 83a and one of the pair of expansion/contraction devices 65a are hidden behind the other of the pair of stator sections 82a, the other of the pair of mover sections 83a and the other of the pair of expansion/contraction devices 85a, respectively, in the depth of the page surface.

The pair of stator sections 82a are each made up of a member extending in the X-axis direction and are fixed to, for example, body BD (see FIG. 1). As shown in FIG. 7, the pair of stator sections 82a are placed parallel at a predetermined distance in the Y-axis direction. Each of the pair of stator sections 82a has a coil unit including a plurality of coils that is not illustrated. Further, each of the pair of stator sections 82a has a guide member, which is not illustrated, extending in the X-axis direction used to guide mover sections 83a, to be described below, in the x-axis direction.

In a state where each of the pair of mover sections 83e is slidable in the X-axis direction with respect to corresponding stator section 82a and relative movement in the Z-axis direction is restricted (fall from stator section 82a is prevented), each of the pair of mover sections 83a is mechanically engaged with the lower surface side of the stator section 82a in a suspended sate (see FIG. 2). Mover section 83a has a magnet unit including a plurality of magnets that is not illustrated. The magnet unit configures an X linear motor by the electromagnetic force (Lorentz force) drive method, together with the coil unit that stator section 82a has. The pair of mover sections 83a are synchronously driven by the X linear motor with predetermined strokes in the X-axis direction with respect to the pair of stator sections 82a, respectively. Incidentally, the drive device to uniaxially drive grip section 84a and expansion/contraction device 85a in the X-axis direction is not limited to the linear motor, but, for example, a ball screw drive device using a rotary motor, a belt drive device, a wire drive device or the like can also be used.

As shown in FIG. 7, grip section 84a is made up of a member extending in the Y-axis direction and having a rectangular XZ sectional shape. On the +X side surface of grip section 84a, a plurality (e.g. four) of recessed sections 86a each having a taper surface that becomes narrower toward the −X side are formed at a predetermined distance in the Y-axis direction. The distance between the plurality of recessed sections 86a roughly coincides with the distance between four support sections 91 (i.e. four taper members 94) of substrate tray 90. Grip section 84a holds the −X side of substrate tray 90 by taper members 94, which is connected to the −X side ends of support sections 91 of substrate tray 90, being inserted into recessed sections 86a.

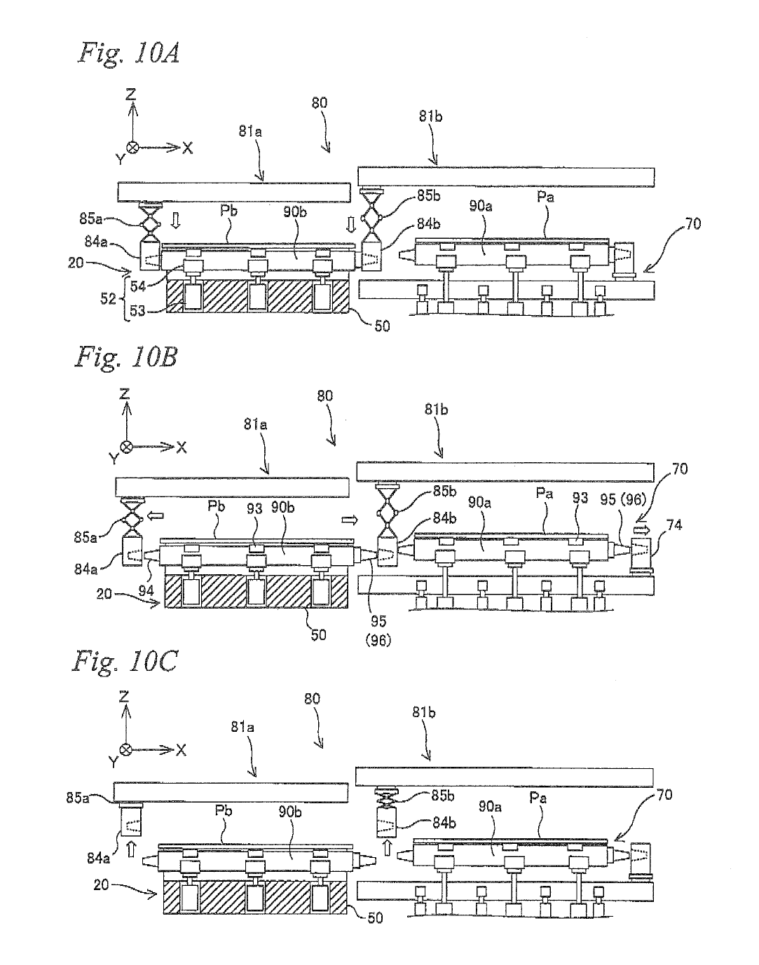

As shown in FIG. 2, expansion/contraction device 85a includes a pantograph mechanism that is configured of a plurality of link members and is capable of expanding and contracting in the Z-axis direction, and an actuator, not illustrated, that makes the pantograph mechanism expand and contract in the Z-axis direction. Note that, in FIG. 2, the expansion/contraction device is in a state where the pantograph mechanism contracts (in a state where the size in the Z-axis direction is the minimum, see FIG. 10A, for a state where the pantograph mechanism expands). The pantograph mechanism of expansion/contraction device 85a has the +Z side end connected to mover section 83a and the −Z side end connected to grip section 84a. The actuators of the pair of expansion/contraction devices 85a are synchronously driven by the main controller that is not illustrated, and accordingly, grip section 84a vertically moves parallel to the Z-axis. Incidentally, the device (uniaxial drive device) to vertically move grip section 84a is not limited to the one including the pantograph mechanism described above, but can be, for example, an air cylinder, and it is preferable to use a link mechanism because the link mechanism has the size in the Z-axis direction, in a state where grip section 84a is located on the most +Z side, is short and the link mechanism is capable of vertically moving grip section 84a with long strokes to some extent.

Second carrier unit 81b is located on the +X side of the first carrier unit, above frame 61. Note that, a configuration of second carrier unit 81b is the same as that of first carrier unit 81a except that the positions of stator sections 82b are slightly on the +Z side than the positions of stator sections 82a of first carrier unit 81a, that four recessed sections 86b (see FIG. 7) are formed on the −X side surface of grip section 84b, and that a recessed section 87b (see FIG. 7) in which taper member 96 is inserted is formed at grip section 84b. More specifically, second carrier unit 81b has a pair of stator sections 82b fixed to a column, a beam or the like of a chamber, not illustrated, that houses, for example, substrate stage device PST and the like, a pair of mover sections 83b arranged so as to correspond to the pair of stator sections 82b, grip section 84b to hold the +X side and of substrate tray 90, and a pair of expansion/contraction devices 85b (having strokes slightly longer than those of expansion/contraction devices 85a of first carrier unit 81a) that vertically move grip section 84b. Incidentally, in FIG. 2, one of the pair of stator sections 82b, one of the pair of mover sections 83b and one of the pair of expansion/contraction devices 85a are hidden behind the other of the pair of stator sections 82b, the other of the pair of mover sections 83b and the other of the pair of expansion/contraction devices 85b, respectively, in the depth of the page surface.

Further, one end of a piping member, the other end of which is connected to a vacuum device, is connected to grip section 84b (the illustration of the vacuum device and the piping member is omitted). When substrate P mounted on substrate tray 90 is carried into substrate holder 50 using substrate carry-in device 80, a gas in the piping member, which is not illustrated, within substrate tray 90 is suctioned by the vacuum device in a state where taper member 96 is inserted in recessed section 87b of grip section 84b, and thereby substrate P is held by adsorption by pads 93 of substrate tray 90. Accordingly, when substrate tray 90 is accelerated and decelerated, the shift of substrate P on substrate tray P is restrained. While, in the present embodiment, stator sections 82b of second carrier unit 81b are placed slightly on the +Z side than stator sections 82a of first carrier unit 81a, the Z-positions of stator section 82a of first carrier unit 81a and stator section 82b of second carrier unit 81b can be the same. Further, it is also possible that stator sections 82a of first carrier unit 81a and stator sections 82b of second carrier unit 81b are integrated and an actuator (e.g. a linear motor) is configured such that mover sections 83a and 83b are independently driven by the integrated (common) stator section.

In liquid crystal exposure apparatus 10 (see FIG. 1) configured as described above, under control of the main controller that is not illustrated, loading of mask M onto mask stage MST is performed by a mask carrier device (mask loader) that is not illustrated and carry-in (loading) of substrate P onto substrate stage 20 is performed by substrate carry-in device 80 shown in FIG. 2. After that, the main controller executes alignment measurement using an alignment (detection) system that is not illustrated, and after the alignment measurement has been completed, an exposure operation by a step-and-scan method is performed. Because this exposure operation is similar to the one by a step-and-scan method conventionally performed, detailed description thereof is omitted. Then, substrate P that has been exposed is carried out (unloaded) from substrate stage 20 by substrate carry-out device 70 shown in FIG. 2, and a new substrate P is carried into (loaded onto) substrate stage 20 by substrate carry-in device 80. In other words, in liquid crystal exposure apparatus 10, the exposure processing is consecutively performed to a plurality of substrates P by performing exchange of substrate P on substrate stage 20.

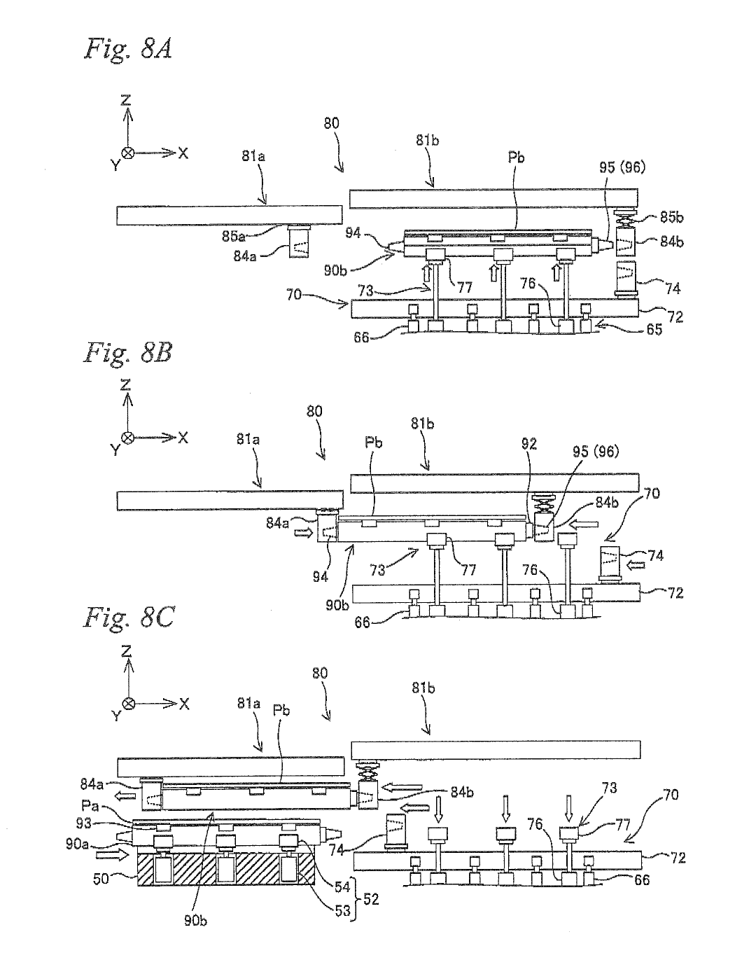

In this case, the exchange procedure of substrate P on substrate stage device PST using substrate carry-out device 70 and substrate carry-in device 80 is described based on FIGS. 8A to 13C and appropriately referring to the other drawings. Note that FIGS. 8A to 13C are views used to explain the exchange procedure of substrate P, and the configurations of substrate stage 20, substrate exchanging device 60 and the like are partially simplified and shown (e.g. the number of the tray guide devices that substrate holder 50 has is less than the actual number). Further, the illustration of fine movement stage 21, X coarse movement stage 23Y and X coarse movement stage 23X (see FIG. 1 for the respective stages) of substrate stage 20 and the like is omitted.

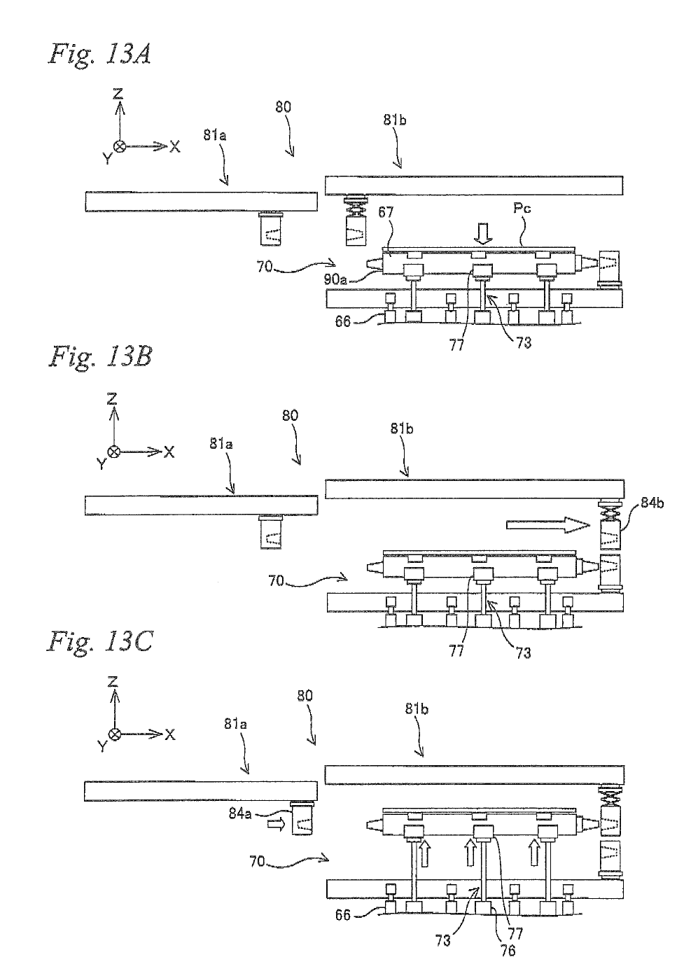

In liquid crystal exposure apparatus 10 related to the present embodiment, as shown in FIG. 2, the exposure processing is consecutively performed to a plurality of substrates P using two substrate trays 90. Hereinafter, in order to facilitate understanding, in FIGS. 8A to 13C, a substrate after the exposure processing to which the exposure processing has been completed and is carried out from substrate stage 20 is referred to as a substrate Pa and a substrate before exposure that is newly mounted on substrate stage 20 is referred as a substrate Pb. And, the description is made assuming that a substrate tray that supports substrate Pa is referred to as a substrate tray 90a and a substrate tray that supports substrate Pb is referred to as a substrate tray 90b. Further, in FIGS. 8A and 13C, a plurality of taper members 95 and taper member 96 of each of substrate trays 90a and 90b overlap in the depth direction of the page surface.

In FIG. 8A, substrate tray 90b that supports substrate Pb is mounted on the plurality of tray guide devices 73 of substrate carry-out device 70. Air cylinders 76 of tray guide devices 73 are in an expanding state. On the other hand, in substrate carry-in device 80, expansion/contraction devices 85a of first carrier unit 81a are in a contracting state. In second carrier unit 81b, expansion/contraction devices 85b are controlled such that the Z position of grip section 84b coincides with the Z-position of grip section 84a of first carrier unit 81a. At this point, the Z-positions of taper members 94, 95 and 96 that substrate tray 90b has and the Z-positions of recessed sections 86a of grip section 84a and recessed sections 86b of grip section 84b roughly coincide. Further, grip section 74 of substrate carry-out device 70 is located in the vicinity of the +X side end on stator section 72. And, the plurality of air cylinders 66 that configure lift device 65 are in a contracting state, and their tips are located further on the −Z side than the upper surface of stator section 72. Further, although not illustrated in FIGS. 5A and 8B, on substrate holder 50 of substrate stage 20, substrate Pa is mounted, and the exposure processing is performed to substrate Pa under projection optical system PL (see FIG. 1). In groove sections 51 of substrate holder 50, substrate tray 90a is housed.

Next, as shown in FIG. 8B, grip section 84b of second carrier unit 81b is driven in the −X direction, and accordingly, the plurality of taper members 95 and taper member 96 on the +X side of substrate tray 90b are inserted into recessed sections 86b and 87b (see FIG. 7) of grip section 84b. And, in second carrier unit 81b, in a state where taper members 95 and 96 are inserted in the recessed sections of grip section 84b, grip section 84b is driven further in the −X direction. Substrate tray 90b moves in the −X direction on the plurality of guide members 77 of tray guide devices 73 by being pressed by grip section 84b. When substrate tray 90b moves on the plurality of guide members 77, the plurality of guide members 77 levitate substrate tray 90b by jetting the gas from the surfaces of the V groove sections, thereby preventing dust generation and generation of vibration caused by the slide with substrate tray 90b. Since the mid portion of substrate tray 90b in the X-axis direction is supported from below by guide members 77 of tray guide devices 73, the bending due to the self weight is restrained. Further, in parallel with the operations described above, grip section 84a of first carrier unit 81a is driven in the +X direction. Accordingly, the plurality of taper members 94 on the −X side of substrate tray 90b are inserted into recessed sections 86a (see FIG. 7) of grip section 84a. With this operation, the +X side end and the −X side end of substrate tray 90b are held by grip sections 84a and 84b, respectively. Incidentally, because taper member 96 is exclusively used during the carry-out of substrate tray 90, grip section 84b can be configured so as to engage only with the plurality of taper members 95. Further, when holding substrate tray 90, substrate carry-in device 80 can mechanically hold (clamp) substrate tray 90 by pressing substrate tray 90 with grip sections 64a and 84b, or can hold substrate tray 90 by vacuum adsorption or electrostatic adsorption. Alternatively, a plurality of holding methods such as mechanical holding and holding by adsorption can be used together.

In this case, when taper members 94 to 96 arranged at substrate tray 90b are respectively inserted into recessed sections 66a, 86b and 87b of grip sections 84a and 84b, taper members 94 to 96 are respectively guided by the taper surfaces of recessed sections 86a, 86b and 87b, and therefore, even if the positions of taper members 94 to 96 have minor deviation from the positions of recessed sections 86a, 86b and 87b, it is possible to make taper members 94 to 96 reliably insert into corresponding recessed sections 86a, 86b and 87b.

Afterwards, by synchronous drive of grip sections 84a and 84b, substrate tray 90b moves in the −X direction. On this movement, guide members 77 pass inside notches 92a (see FIG. 6) formed at connecting section 92 of substrate tray 90b. Further, on the lower surface of grip section 84b, a plurality of notches, not illustrated, having a triangular shape in a side view when viewed from the X-axis direction and similar to notches 92a are formed, at positions corresponding to notches 92a of connecting section 92, and guide members 77 passes inside the notches. Further, along with substrate tray 90b moving in the −X direction, grip section 74 of substrate carry-out device 70 is driven in the −X direction on stator section 72.

As shown in FIG. 8C, substrate tray 90b is carried by substrate carry-in device 80 to above the substrate exchange position. Further, air cylinders 76 of tray guide devices 73, which have delivered substrate tray 90b to substrate carry-in device 80, are contracted, and accordingly, guide members 77 are lowered. Incidentally, the lowering of guide members 77 can be performed before substrate tray 90b is moved to above the substrate exchange position (in the state shown in FIG. 8B). Further, grip section 74 of substrate carry-out device 70 stops in the vicinity of the −X side end on stator section 72 (the position that is slightly on the +X side than the limit position on the −X side of the movable range of grip section 74 in the X-axis direction).

Then, in a state where substrate tray 90b waits above the substrate exchange position and grip section 74 of substrate carry-out device 70 waits in the vicinity of the −X side end on stator section 72, substrate stage 20 (in FIGS. 8C to 11A, however, only substrate holder 50 is illustrated for the sake of simplification of the drawing) that holds substrate Pa to which the exposure processing has been completed is positioned at the substrate exchange position. In a state where substrate stage 20 is located at the substrate exchange position, support sections 91 of substrate tray 90b that waits above substrate holder 50 and groove sections 51 of substrate holder 50 overlap in the Z-axis direction (vertical direction) (see FIG. 7).

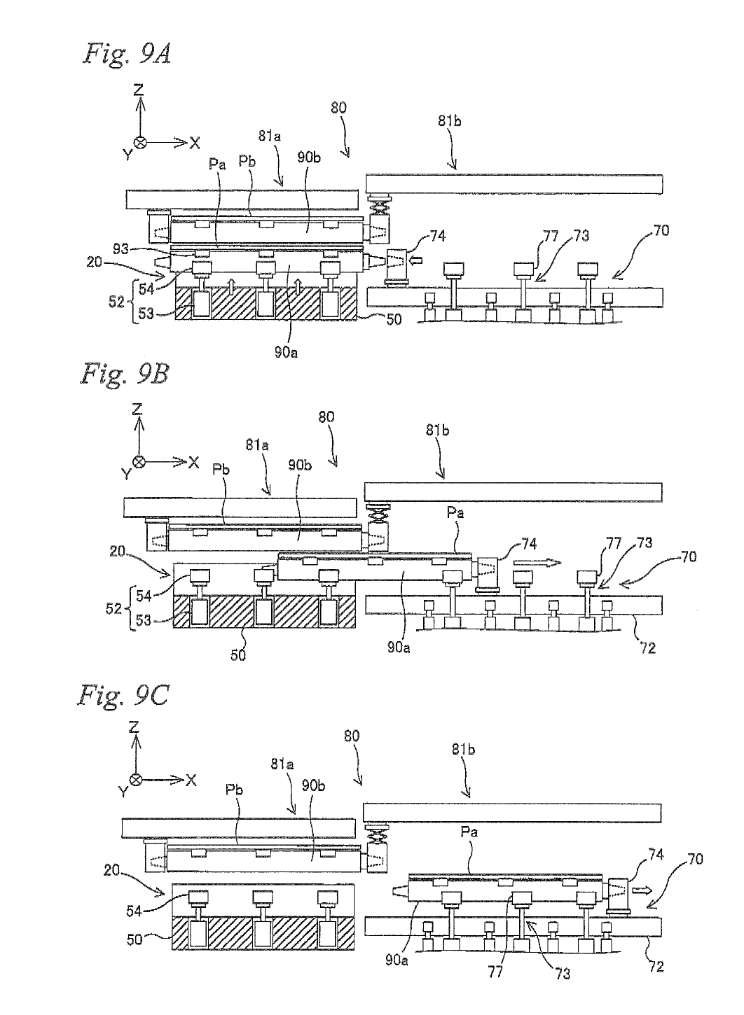

When substrate stage 20 is positioned at the substrate exchange position, as shown in FIG. 9A, the holding by adsorption of substrate Pa by substrate holder 50 is released, and also air cylinders 53 of tray guide devices 52 are expanded and substrate tray 90a moves upward. When substrate tray 90a moves upward, the plurality of pads 93 of substrate tray 90a come in contact with the lower surface of substrate Pa, and presses substrate Pa upward. Accordingly, as shown in FIG. 5C, the lower surface of substrate Pa and the upper surface (substrate holding surface) of substrate holder 50 are separated. In this state where substrate tray 90a is pressed upward, taper member 96 of substrate 90a and recessed section 74a (see FIG. 2) of grip section 74 of substrate carry-out device 70 roughly coincide in the Y-position and the Z-position. And, grip section 74 is driven in the −X direction on stator section 72, and thereby taper member 96 is inserted into recessed section 74a of grip section 74, and grip section 74 holds substrate tray 90a.

Subsequently, as shown in FIG. 93, grip section 74 of substrate carry-out device 70 is driven in the +X direction on stator section 72, and thereby substrate tray 90a moves integrally with grip section 74 in the direction, and substrate Pa is carried out from substrate stage 20. At this point, tray guide devices 52 of substrate stage 20 jet the gas from guide members 54 to substrate tray 90a and levitate substrate tray 90a. In this case, the interval (distance) between tray guide device 52 on the most side that substrate holder 50 has and tray guide device 73 on the most −X side that substrate carry-out device 70 has is set to be shorter than the length in the X-axis direction of substrate tray 90a (or 90b). Consequently, substrate tray 90a moves in the direction, thereby being delivered from tray guide devices 52 within substrate holder 50 to tray guide devices 73 of substrate carry-out device 70. Tray guide devices 73 of substrate carry-out device 70 jet the gas from guide members 77 to substrate tray 90a, similarly to tray guide devices 52 of substrate holder 50, and levitate substrate tray 90a. Then, as shown in FIG. 9C, when substrate tray 90a is completely delivered to tray guide device 73 of substrate carry-out device 70, the plurality of tray guide devices 52 and 73 that substrate holder 50 and substrate carry-out device 70 respectively have stop the jetting of the gas from guide members 54 and 77. Accordingly, substrate tray 90a is mounted on the plurality of guide members 77. In this case, tray guide device 73 is not limited to a levitation type (noncontact type) device that supports substrate tray 90 in a noncontact manner, but can be a contact type device that supports substrate tray 90, for example, using bearings or the like.

Next, as shown in FIG. 10A, expansion/contraction devices 85a of first carrier unit 81a and expansion/contraction devices 85b of second carrier unit 81b synchronously expand, and thereby both grip sections 84a and 84b move in the −Z direction (descends), and substrate tray 90b is delivered to substrate holder 50. On this operation, by support sections 91 (see FIG. 4A) of substrate tray 90b being first inserted into the V grove sections (see FIG. 5B) formed at guide members 54 of tray guide devices 52, substrate tray 90b is supported from below by the plurality of tray guide devices 52. Then, substrate tray 90b further descends by air cylinders 53 of the plurality of tray guide devices 52 being synchronously contracted, and with this operation, substrate Pb is mounted on the upper surface (substrate mounting surface) of substrate holder 50. Further, along with substrate Pb being mounted on substrate holder 50, pads 93 of substrate tray 90b are separated from the lower surface of substrate Pb. After that, substrate holder 50 holds substrate Pb by adsorption using an adsorption device that is not illustrated. Note that, along with air cylinders 53 being contracted, grip section 84a of first carrier unit 81a and grip section 84b of second carrier unit 81b of substrate carry-in device 80 are also lowered. Incidentally, it is also possible to move guide members 54 in the −Z direction by contracting the plurality of air cylinders 53 after substrate 90a removes from substrate holder 50 (see FIG. 9C), and mount substrate tray 90b onto guide members 54. In this case, the substrate carry-in time can be reduced. Further, in the case where substrate tray 90b is delivered to guide members 54 in a state where air cylinders 53 expand, it is also possible that grip of substrate tray 90b by grip sections 84a and 84b is released and expansion/contraction devices 85a and 85b are contracted at the time when substrate tray 90b is mounted on guide members 54. In this case, the strokes of expansion/contraction devices 85a and 85b can be shortened.

When the mounting of substrate Pb onto substrate holder 50 has been completed, as shown in FIG. 10B, grip section 84a of first carrier unit 81a is driven in the −X direction and grip section 84b of second carrier unit 81b is driven in the +X direction, respectively (i.e. directions in which the grip sections move apart from substrate tray 90b). With this movement, taper members 94 to 96 of substrate tray 90b respectively remove from grip sections 84a and 84b. Further, along with this operation, grip section 74 of substrate carry-out device 70 moves in the +X direction. With this movement, taper member 96 of substrate tray 90b removes from grip section 74, and the holding by adsorption of substrate Pa by pads 93 of substrate tray 90a is released. Next, as shown FIG. 10C, expansion/contraction devices 85a of first carrier unit 81a and expansion/contraction devices 85b of second carrier unit 81b are contracted, and thereby each of grip sections 84a and 84b that have moved apart from substrate tray 90b moves in the +Z direction.

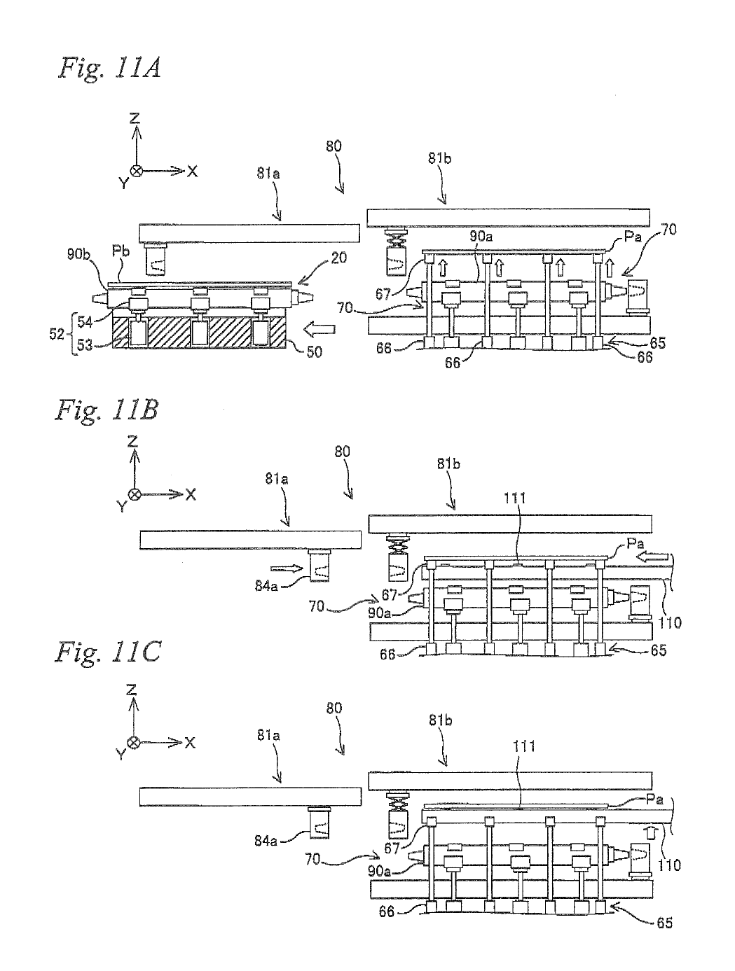

After that, as shown in FIG. 11A, substrate stage 20 moves in the −X direction (a direction in which substrate stage 20 moves apart from the substrate exchange position), and the exposure processing and the like are performed to substrate Pb mounted on substrate holder 50 (the description about the exposure processing operation and the like is omitted). At this point, substrate holder 50 holds substrate tray 90b by adsorption using guide members 54 of tray guide devices 52, and restrains the shift of substrate tray 90b at the time acceleration and deceleration of substrate stage 20. Meanwhile, in substrate carry-out device 70, the plurality of air cylinders 66 that configure lift device 55 are each expanded, and accordingly, substrate Pa moves in the +Z direction and is separated from substrate tray 90a. Incidentally, it is also possible that, for example, a vacuum adsorption device is arranged at the plurality of pad members 67 of lift device 65 and the vacuum adsorption device holds substrate Pa by adsorption to prevent substrate Pa from shifting from pad members 67.

Subsequently, as shown in FIG. 11B, a carry-out robot arm 110 of a substrate carrier robot that carries out substrate Pa (or Pb) to a coater/developer device, not illustrated, which is arranged outside liquid crystal exposure apparatus 10 (see FIG. 2), is inserted into a space formed between the lower surface of substrate Pa and substrate tray 90a. Although not illustrated, carry-out robot arm 110 is made up of a member having a comb shape in a planar view, and has a plurality of pad members 111 that hold substrate Pa (or Pb) by adsorption on their upper surfaces. Further, grip section 84a of first carrier unit 81a of substrate carry-in device 80 is driven in the +X direction. However, since there is a possibility that vibration is generated when grip section 84a is moved, the movement of grip section 84a is preferably performed, for example, when a step operation of substrate stage 20 (see FIG. 11A) is performed. Incidentally, it is also possible that substrate stage device PST and a carrier section for a substrate such as first carrier unit 81a are placed so as to be physically separated, and in such a case, grip section 84a can be moved without any relation to an operation on the substrate stage device PST side.

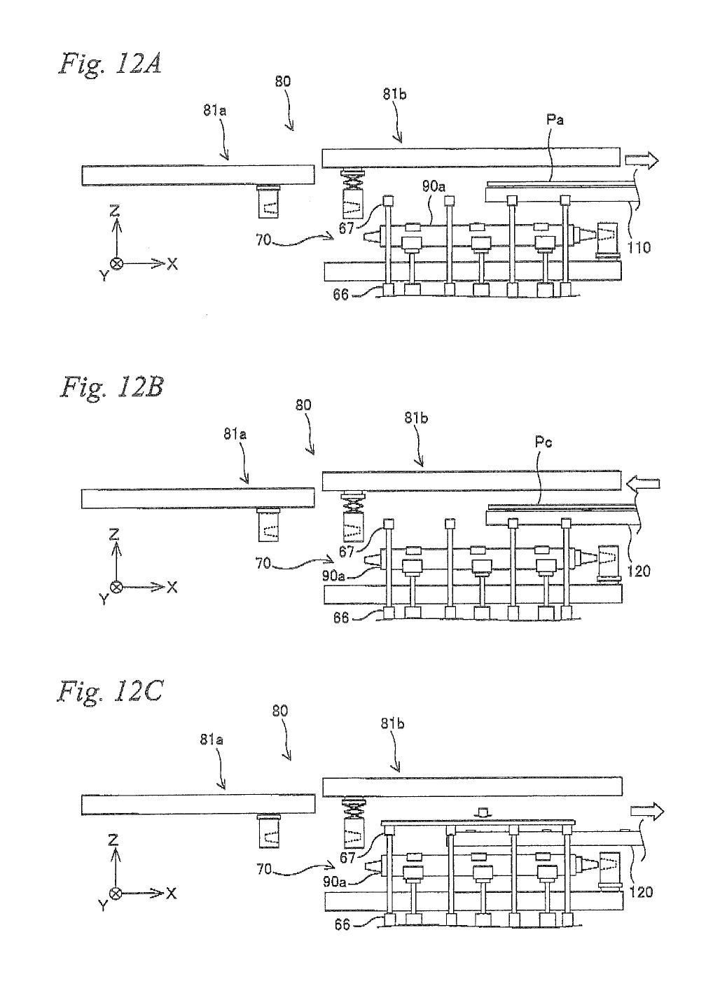

Next, as shown in FIG. 11C, carry-out robot arm 110 is driven upward, and accordingly, the lower surface of substrate Pa moves apart from pad members 67 of lift device 65, and is supported from below by carry-out robot arm 110. After that, as shown in FIG. 12A, carry-out robot arm 110 is driven in the −X direction and substrate Pa is carried to the coater/developer device that is not illustrated.

Afterwards, as shown in FIG. 12B, a carry-in robot arm 120 of the substrate carrier robot carries in a new substrate Pc to above lift device 65. A controller (e.g. a controller of the coater/developer device) that controls the substrate carrier robot moves carry-in robot arm 120 in the −Z direction, as shown in FIG. 12C. Accordingly, substrate Pc is delivered from carry-in robot arm 120 onto the plurality of pad members 67 that lift device 65 has. After that, carry-in robot arm 120 is moved in the +X direction and withdrawn from the inside of the liquid crystal exposure apparatus.

When the main controller receives a signal that carry-in robot arm 120 has been withdrawn from the inside of the liquid crystal exposure apparatus, from another controller that controls the substrate carrier robot, the main controller, in response to the signal, contracts the plurality of air cylinders 66 that lift device 65 has. Accordingly, as shown in FIG. 13A, substrate Pc moves in the −Z direction (descends) and is mounted on substrate tray 90a. After that, as show in FIG. 13B, grip section 84b of second carrier unit 81b of substrate carry-in device 80 is driven in the +X direction. Then, as shown in FIG. 13C, the plurality of air cylinders 76 of tray guide devices 73 are synchronously expanded, and thereby substrate tray 90a that supports substrate Pc moves upward. Further, along with this operation, grip section 84a of first carrier unit 81a is driven in the direction and returns to the state shown in FIG. 8A (though substrate Pb is replaced with substrate Pc). Afterwards, although not illustrated, substrate stage 20 that supports substrate Pb to which the exposure processing has been completed moves to the substrate exchange position, and substrate Pb mounted on substrate tray 90b is carried out from substrate holder 50, and on substrate tray 90b, another substrate is mounted, in replacement of substrate Pb. Further, substrate tray 90a delivers substrate Pc to substrate holder 50, and substrate tray 90c is held by substrate holder 50. In this manner, in liquid crystal exposure apparatus 10 (see FIG. 1) of the present embodiment, two substrate trays 90a and 90b are circulated and used between substrate stage 20 and substrate exchanging device 60.

As described above, liquid crystal exposure apparatus 10 related to the first embodiment can mount substrate P onto substrate holder 50 only by moving substrate tray 90 in the −Z direction (vertical direction) and inserting support sections 91 into the grove sections of substrate holder 50, and therefore, substrate P can be carried into substrate holder 50 at a high speed (in a short time). Further, the carry-out of substrate P after exposure from substrate holder 50 is performed by moving substrate tray 90 in the +X direction (horizontal direction). More specifically, a movement path of substrate P used when substrate P is carried out from substrate holder 50 (carry-out path from substrate stage 20) and a movement path of substrate P used when substrate P is mounted onto substrate holder 50 (carry-in path to substrate stage 20) are different. Consequently, prior to the carry-out of substrate P from substrate holder 50 (or during the carry-out operation), it is possible to make another substrate P positioned (wait) above substrate holder 50. In other words, in substrate exchanging device 60 related to the present embodiment, the carry-out operation to carry substrate P out from substrate holder 50 and the carry-in operation to carry another substrate P into substrate holder 50 can be performed in parallel and the substrate exchange on substrate holder 50 can be speedily performed.

Further, in a conventional substrate exchanging method in which exchange of substrate P on substrate holder 50 is performed, for example, using two robot arms, in order to make one substrate tray 90 that supports another substrate P wait above while a robot arm for substrate carry-out carries the other substrate tray 90 out from substrate holder 50, a space wide enough, for example, for the thickness of the two robot arms and two substrate trays 90 is needed, but in contrast, in substrate exchanging device 60 related to the present embodiment, only substrate tray 90 for substrate carry-in is positioned above substrate holder 50, and therefore substrate exchanging device 60 can suitably be used also in the case where a space above substrate stage 20 that is located at the substrate exchange position is small.

Further, when substrate tray 90 that supports substrate P is pulled out from substrate holder 50, substrate tray 90 needs to be moved in the +Z direction in order to separate substrate P and substrate holder 50, and substrate tray 90 can be moved in the +X direction in a state where the most part of substrate tray 90 remains housed in grove sections 51 of substrate holder 50, because substrate tray 90 is formed into a comb shape in a planar view. In other words, substrate tray 90 does not have to be completely taken out from the inside of groove sections 51 of substrate holder 50 but substrate tray 90 only has to be moved in the +Z direction by a minute distance. Consequently, substrate P can be speedily carried out from substrate holder 50 and thereby the cycle time for substrate exchange can be reduced. Further, since substrate P can be speedily carried out regardless of the thickness (the size in the +Z direction) of substrate tray 90, the thickness of substrate tray 90 can be increased to improve the stiffness.

Further, in recent years, the size of substrate P has tended to be increased, and therefore the movement distance of substrate P (and substrate tray 90) at the time of carry-in of the substrate becomes longer according to the size increase. In response, because substrate carry-in device 80 of the present embodiment grips the +X side end and the −X side end (the front end and the rear end in the movement direction at the time of the carry-in) of substrate tray 90, substrate tray 90 can stably be carried for a long distance, compared with, for example, the case where the substrate tray is carried by a cantilevered robot arm.

Further, in substrate exchanging device 60 of the present embodiment, substrate P before exposure is made to wait above the exposure exchange position in advance, before substrate stage 20 moves to the substrate exchange position, and this carry of substrate P before exposure is performed during the exposure processing of another substrate P, and therefore, substrate P can be carried at a low speed to the waiting position. Consequently, dust generation at substrate carry-in device 80 can be prevented.

Further, substrate carry-out device 70 is arranged outside substrate stage device PST, and therefore, even if dust is generated from the members that configure substrate carry-out device 70, it is possible to restrain the dust (particles) from, for example, reaching onto substrate holder 50 (i.e. onto substrate P before exposure).

Further, because substrate carry-out device 70 has the configuration of carrying substrate tray 90 out from substrate holder 50 by gripping one end (the +X end) of substrate tray 90, the control is easy to make, compared with, for example, the case where a robot arm is inserted into a narrow gap between the lower surface of substrate P and the upper surface of substrate holder 50. Further, because an operation of inserting the robot arm between the gap is unnecessary, substrate tray 90 can be carried out at a high speed (in a short time).

Further, guide members 54 that substrate holder 50 has and guide members 77 that substrate carry-out device 70 has can each support substrate tray 90 in a noncontact manner, and therefore, generation of vibration and dust generation at the time of carrying out substrate tray 90 are prevented.

Further, in substrate exchanging device 60 related to the present embodiment, the respective devices of the plurality of tray guide devices 52 arranged in substrate holder 50, substrate carry-out device 70 (including the plurality of tray guide devices 73), substrate carry-in device 80, and lift device 65 cooperate to perform the exchange of substrate P, and therefore, the operations of the respective devices can be simplified, compared with a conventional substrate exchanging device that performs the exchange of substrate using, for example, two robot arms (a carry-in arm and a carry-out arm). Especially, because substrate carry-out device 70 has the simple configuration of moving substrate tray 90 in the X-axis direction (one axis direction) and substrate carry-in device 80 has the simple configuration of moving substrate tray 90 in the X-axis direction and the Z-axis direction (two axes directions), the cost (manufacturing cost, running cost and the like) can be reduced, compared with a substrate carrier robot equipped with, for example, two robot arms. Further, even if the number of the devices is increased, the workability can be improved and the cycle time of substrate exchange can be reduced because the operations of the respective devices are simple.

### Second Embodiment

Next, a liquid crystal exposure apparatus of a second embodiment is described. Since the liquid crystal exposure apparatus related to the second embodiment is different from the first embodiment described above only in a configuration of a substrate tray and a configuration of a substrate holder, only the configuration of the substrate tray and the configuration of the substrate holder are described below. Incidentally, in the second embodiment and third to sixth embodiments and modified examples, for the sake of simplified description and convenience in illustration, the members having similar configurations and operations to those of the first embodiment described above are denoted with the same reference signs as the reference signs in the first embodiment described above and the description thereof is omitted.

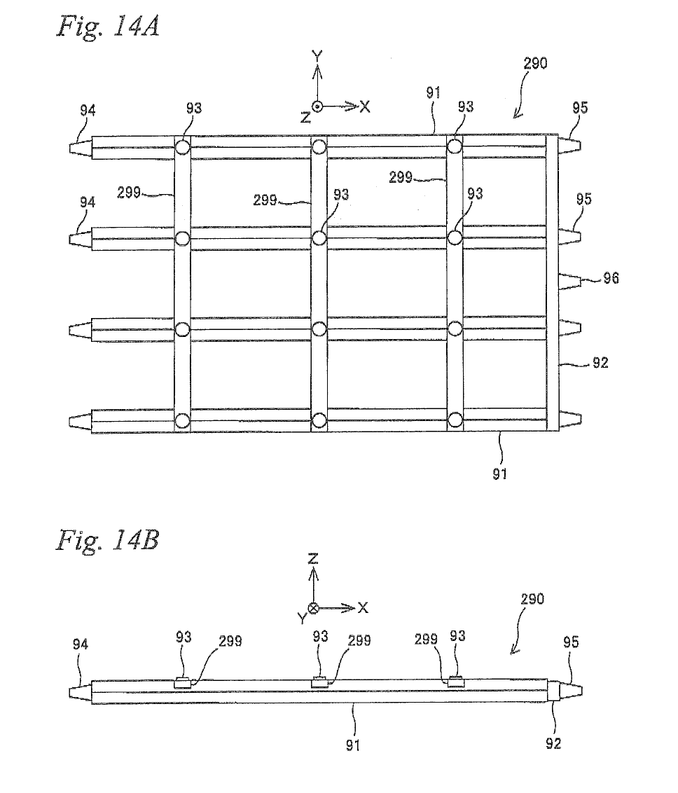

As shown in FIG. 14A, a substrate tray 290 of the second embodiment has, for example, four support sections 91, connecting section 92 that connects the +X side ends of four support sections 91, and a plurality of connection sections 299 that connect the mid portions in the longitudinal direction of four support sections 91. Connecting sections 299 are each made up of a plate-shaped member extending in the Y-axis direction, i.e. in a direction orthogonal to a direction in which support sections 91 extend, and for example, three connecting sections 299 are arranged at a predetermined distance in the X-axis direction. The size in the longitudinal direction of connecting section 299 is substantially the same as a distance between support section 91 located on the most +Y side and support section 91 located on the most −Y side, and the +Y side ends of connecting sections 299 are connected to support section 91 on the most +Y side and the −Y ends are connected to support section 91 on the most side. Further, the mid portions of connecting sections 299 in the longitudinal direction are respectively connected to the second and third support sections 91, viewed from the +Y side. With this arrangement, the substrate tray related to the present second embodiment has a net-like outer shape as a whole, which is different from substrate tray 90 (see FIG. 4A) related to the first embodiment described above with a comb-like outer shape.

In the present second embodiment, as shown in FIG. 14B, at the upper end of each support section 91, a plurality (e.g. three) of recessed sections are formed at a predetermined distance in the X-axis direction, and in the recessed sections, connecting sections 299 are inserted. In this case, the Z-positions of the upper ends of support sections 91 and the Z-positions of the upper surfaces of connecting sections are substantially the same. Fads 93 that come in contact with the lower surface of substrate P are attached to the upper surfaces of connecting sections 299. Consequently, the thickness of substrate tray 290 is substantially the same as that of the substrate tray in the first embodiment described above. Further, the thickness of connecting section 299 is set to, for example, around a quarter of the size in the Z-axis direction (thickness) of support section 91. And, the plurality of connecting sections 299 are formed with the sane materials as those of support sections 91, and on the surfaces of connecting sections 299, for example, the black anodic oxide film is formed similarly to support sections 91.

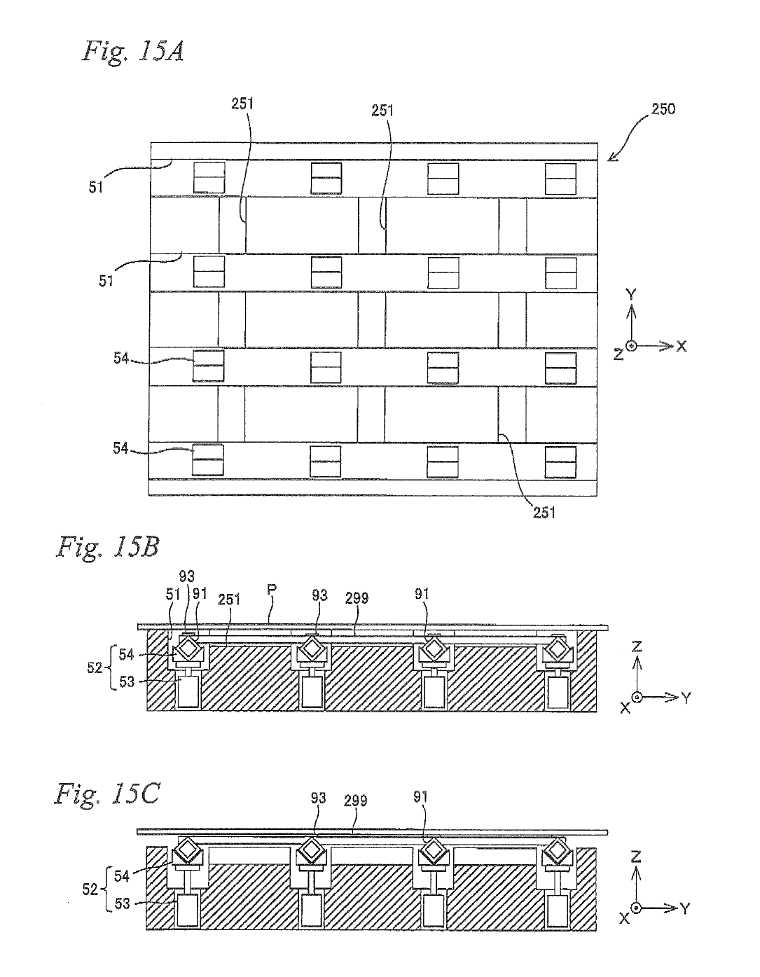

As shown in FIG. 15A, substrate holder 250 has three groove sections 251 extending in the Y-axis direction used to house connecting sections 299, in addition to groove sections 51 extending in the X-axis direction used to house support sections 91 of substrate tray 290. For example, three groove sections 251 are formed at a distance in the X-axis direction that corresponds to a distance between connecting sections 299 of substrate tray 290. The size in a depth direction and the size in a width direction of groove section 251 are slightly larger than the size in a thickness direction and the size in the width direction of a plate-shaped member that configure connecting section 299, respectively, and connecting sections 299 are housed in groove sections 251 in a state where support sections 91 of substrate tray 290 are supported by guide members 54 within groove sections 51. Further, the depth of groove section 251 is set such that the lower surface of connecting section 299 does not come into contact with the inner bottom surface of groove section 251 in a state where substrate tray 290 is located on the most −Z side in the Z-axis direction to separate substrate plate P and pads 93 of substrate tray 290 (see FIG. 15A).

In the present second embodiment, similarly to the first embodiment described above, when substrate P on substrate holder 250 is carried out from substrate stage 20 (see FIG. 2), substrate tray 290 is lifted in the direction by a predetermined distance by tray guide devices 52 in order to separate the lower surface of substrate P and the upper surface of substrate holder 250. On this operation, it is necessary to move substrate tray 290 in the +Z direction such that the lower surfaces of connecting sections 299 are located on the +Z side than the upper surface of substrate holder 250, and connecting sections 299 connect the upper ends of support sections 91 to one another and are thin, and therefore, as shown in FIG. 15C, substrate tray 290 can be pulled out of substrate holder 250 in a state where the lower half of substrate tray 290 is housed in groove sections 51 (substrate tray 290 needs not be completely taken out from the inside of groove sections 51). Consequently, similarly to the first embodiment described above, the carry-out speed of substrate P is improved (the carry-out time is decreased), and the cycle time for substrate exchange can be decreased.

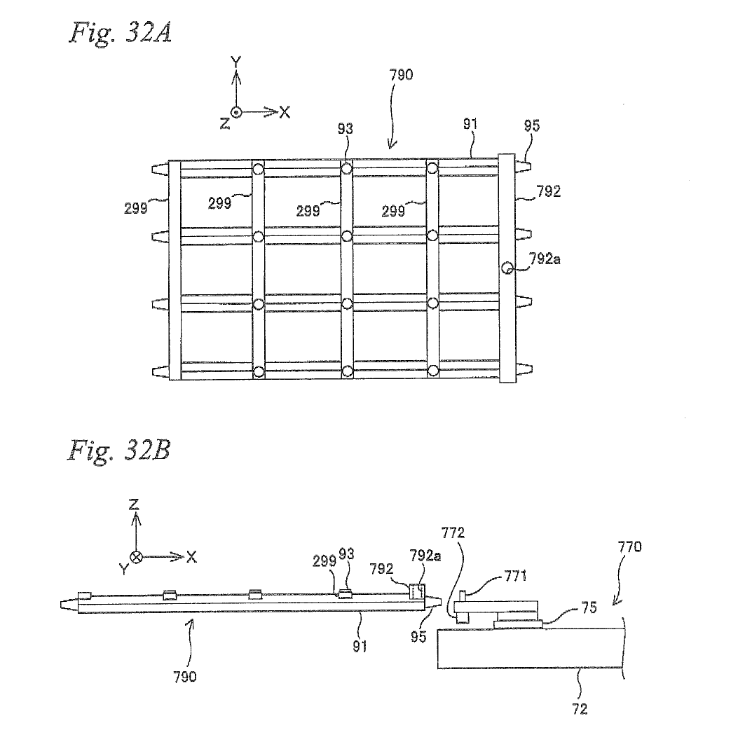

Further, according to substrate tray 290 related to the second embodiment, the plurality of support sections 91 are connected to the plurality of connecting sections 299, and thereby the stiffness of the entire substrate tray 290 (in particular, such as the stiffness in the Y-axis direction, and a twist stiffness) is improved. Consequently, substrate P can be carried at a high speed in a more stable state. Incidentally, while groove sections 251 are formed at substrate holder 250 to house connecting sections 299, the stiffness of substrate holder 250 is not so decreased, even compared with the first embodiment described above, because the thickness of connecting sections 299 themselves are thin and the depth of groove sections 251 are shallow. Incidentally, in the present second embodiment, while the pair of adjacent support sections 91 are connected to each other with the plate-shaped members, this is not intended to be limiting, and for example, the pair of adjacent support sections can be connected to each other with a member having flexibility such as a wire or a rope. Further, the connecting section (stiffening member) to connect the adjacent support sections 91 does not have to be parallel to the Y-axis, and may be bent. Further, connecting sections 299 can each be, for example, a member having a thickness which is around the same as that of support section 91. In this case, the Z-positions of the lower surfaces of connecting sections 299 are made to be the same as those in the second embodiment described above, and the Z-positions of the upper surfaces should be made to protrude on the +Z side beyond the Z-positions of the upper ends of support sections 91. Further, as shown in FIG. 32A, it is also possible that connecting section 299 is arranged so as to connect the −X side ends of the plurality of support sections 91 to one another. In this case, grip section 84a of first carrier unit 81a of substrate carry-in device 80 (see FIG. 2 for each of them) can grip connecting sections 299.

### Third Embodiment

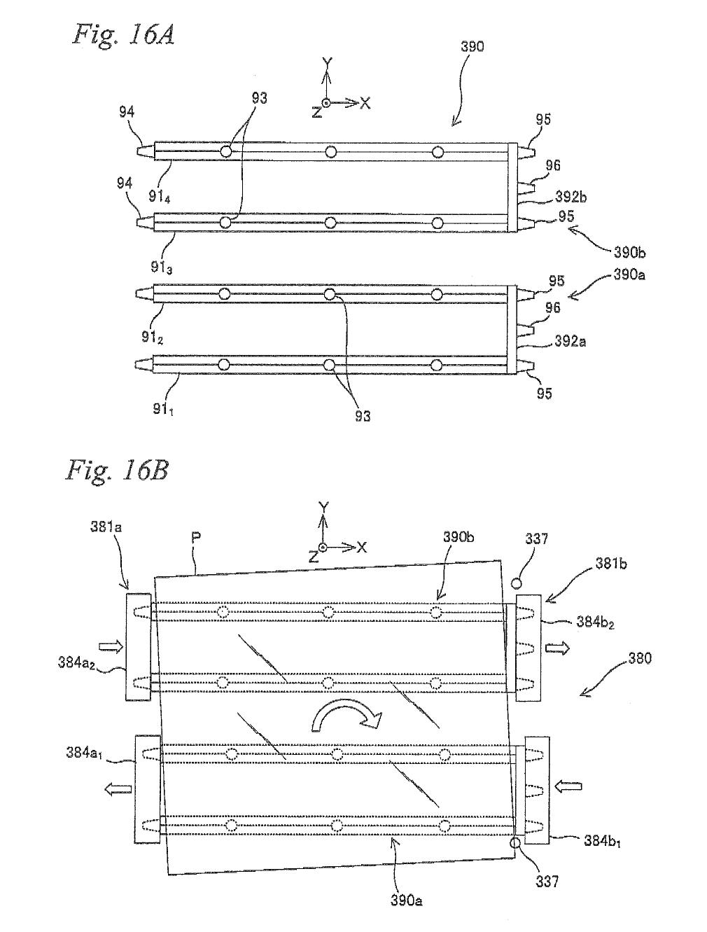

Next, a third embodiment is described with reference to FIGS. 16A and 16B. A liquid crystal exposure apparatus of the third embodiment is different from that of the first embodiment described above in a configuration of a substrate tray 390, a configuration of a substrate carry-in device 380 and a configuration of a substrate carry-out device that is not illustrated. Incidentally, since the other sections are the same as those of the first embodiment described above, the description thereof is omitted.

Substrate tray 390 supports substrate P from below using a plurality, e.g. four, of support sections 91 (which are to be referred to as support sections 91₁ to 91₄ starting from the −Y side) arranged at a predetermined distance in the Y-axis direction (see FIG. 16B). While two support sections 91₁ and 91₂ on the −Y side have the +X side ends that are connected to a connecting section 392a made up of a plate-shaped member parallel to the YZ plane, two support sections 91₃ and 91₄ on the +Y side have the +X side ends that are connected to a connecting section 392b made up of a plate-shaped member parallel to the YZ plane. In other words, two support sections 91₁ and 91₂ on the −Y side and two support sections 91₃ and 91₄ on the +Y side are physically separated. Hereinafter, the description is made, referring to a section composed of two support sections 91₁ and 91₂ and connecting section 392a as a first tray 390a, and a section composed of two support sections 91₃ and 91₄ and connecting section 392b as a second tray 390b, of substrate tray 390. Incidentally, first tray 390a and second tray 390b are substantially the same trays. To the −X side end of each of four support sections 91₁ to 91₄, taper member 94 is attached. On the side surface on the +X side of each of connecting sections 392a and 392b, a pair of taper members 95 and taper member 96 disposed in between the pair of taper members 95 are attached.

FIG. 16B shows a state where substrate tray 390 that supports substrate P from below is carried by substrate carry-in device 380. A first carrier unit 381a of substrate carry-in device 380 has a first grip section 384a₁ that grips the −X side end of first tray 390a and a second grip section 384a₂ that grips the −X side end of second tray 390b. First grip section 384a₁ and second grip section 384a₂ are configured such that position control in the X-axis direction can be performed independently from each other. Further, a second carrier unit 381b of substrate carry-in device 380 has a first grip section 384b₁ that grips the +X side end of first tray 390a and a second grip section 384b₂ that grips the +X side end of second tray 390b. First grip section 384b₁ and second grip section 384b₂ are configured such that position control in the X-axis direction can be performed independently from each other.

Consequently, by making the positions in the X-axis direction (X-positions) of first and second trays 390a and 390b different in a state where substrate P is supported from below using first and second trays 390a and 390b, the position of substrate P in the θz direction can be controlled. In the example shown in FIG. 16B, by synchronously driving each of a pair of first grip sections 384a₁ and 384b₁ that hold first tray 390a in the −X direction and each of a pair of second grip sections 384a₂ and 384b₂ that hold second tray 390b in the +X direction, substrate P rotates in a right-handed direction when viewed from the direction (a clockwise direction in FIG. 16B).

Positional information of substrate P in the θz direction is measured by, for example, a pair of position sensors 337 (e.g. optical sensors that detect the +X side end of substrate P) fixed to barrel surface plate 31 (see FIG. 1). The pair of position sensors 337 are arranged at a predetermined distance in the Y-axis direction, and each detect the position of the +X side end of substrate P in a state (see the drawings such as FIGS. 9A to 9C) where substrate P is made to wait above the substrate exchange position for the carry-in of substrate P to substrate holder 50 (see FIG. 2). The main controller that is not illustrated controls the position of substrate P in the θz direction based on the outputs of the pair of position sensors 337. Incidentally, each of the position sensors is not limited to the one by a noncontact method such as an optical sensor, but can be a sensor by a contact method.

Consequently, for example as shown in FIG. 12C, even if the position of substrate F is deviated (rotated) in the θz direction when robot arm 120 of the substrate carrier robot delivers substrate P to lift device 65, or even if the position of substrate P is deviated in the θz direction while substrate P is carried in using substrate carry-in device 380, the θz position of substrate P can be corrected on substrate tray 390, and therefore, substrate P can reliably be mounted with a predetermined attitude (such that the respective sides of substrate P are parallel to the X-axis and the Y-axis respectively) on substrate holder 50 (see FIG. 2).

Incidentally, although not illustrated in FIG. 16B, the substrate carry-out device has a pair of grip devices (having the same configuration as grip device 71 (see FIG. 2) of the first embodiment) that grip taper member 96 of first tray 390a and taper member 96 of second tray 390b, and when carrying out substrate tray 390 from substrate holder 50 (see FIG. 2), moves substrate tray 390 in the +X direction using the pair of grip devices. Incidentally, if the grip device is configured capable of simultaneously holding first and second trays 390a and 390b, one grip device can be employed (because at the time of carrying out substrate P, position control of substrate P in the θz direction does not have to be performed). Further, at first and second trays 390a and 390b, stiffing members (connecting sections 299) as in substrate tray 290 (see FIG. 14A) of the second embodiment described above can be arranged. In this case, because the X-positions of the stiffing members change in accordance with the X-positions of first and second trays 390a and 390b, the groove sections to house the stiffing members formed at substrate tray 390 should be formed with a width wider than that of the second embodiment described above.

### Fourth Embodiment

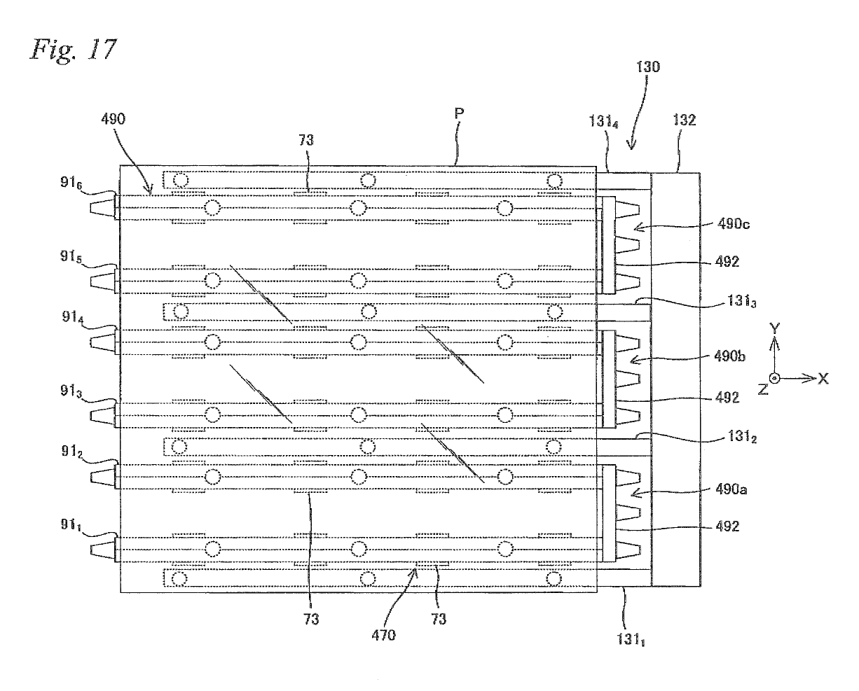

Next, a fourth embodiment is described with reference to FIG. 17. A liquid crystal exposure apparatus related to the fourth embodiment is different from the first embodiment described above in configurations of a substrate tray 490 and a substrate carry-out device 470 and configurations of a substrate carry-in device and a substrate holder that are not illustrated. Incidentally, since the other sections are the same as those of the first embodiment described above, the description thereof is omitted.

Substrate tray 490 supports substrate P from below using a plurality, e.g. six, of support sections 91 (which are to be referred to as support sections 91₁ to 91 starting from the −Y side) arranged at a predetermined distance in the Y-axis direction. Two support sections 91₁ and 91₂ on the −Y side have the +X side ends that are connected by a connecting section 492 made up of a plate-shaped member parallel to the YZ plane. And, similarly, two support sections 91₃ and 91₄ in the center and two support sections 91₅ and 91₆ on the +Y side are each connected by connecting section 492 made up of a plate-shaped member parallel to the YZ plane. Hereinafter, the description is made, referring to a section composed of two support sections 91₁ and 91₂ and connecting section 492 as a first tray 490a, referring to a section composed of two support sections 91₅ and 91₄ and connecting section 492 as a second tray 490b, and referring to a section composed of two support sections 91₅ and 91₆ and connecting section 492 as a third tray 490c, of substrate tray 490.

Further, substrate carry-out device 470 has six rows of tray guide device rows, each of which is composed of a plurality, e.g. four, of tray guide devices 73 disposed at a predetermined distance in the X-axis direction, at a predetermined distance in the Y-axis direction so as to correspond to six support sections 91₁ and 91₆. In a state where substrate tray 490 is supported from below by four tray guide devices 73, first to third trays 490a to 490c are spaced apart at a predetermined distance. Incidentally, although not illustrated in FIG. 17, substrate carry-out device 470 has grip sections that grip first to third trays 490a to 490c respectively. Further, the substrate carry-in device that is not illustrated has a grip section that grips first to third trays 490a to 9900 altogether (or grip sections that individually grip the first to third trays as in the third embodiment described above). Further, the substrate holder that is not illustrated has six groove sections on its upper surface that correspond to six support sections 91₁ and 91₆.

In this case, carry-out robot arm 110 that carries substrate P out from substrate tray 490 to an external device and carry-in robot arm 120 that carries substrate P from the external device into substrate tray 490 (see FIGS. 11B and 12B respectively) each have a member referred to as a hand denoted by a reference sign 130 at its tip. As shown in FIG. 17, a hand 130 has, for example, four support sections 131 (which are to be referred to as support sections 131₁ to 131₄ starting from the −Y side). Four support sections 131₁ to 131₄ each made up of a bar-shaped member extending in the X-axis direction, and are disposed at a distance that is wider than the size in the width direction (the size in the y-axis direction) of each of first to third trays 490a to 490c, in the Y-axis direction. Further, hand 130 has a connecting section 132 that is made up of a member extending in the Y-axis direction and connects the +X side ends of four support sections 131₁ to 131₄ to one another, and has a comb-like outer shape in a planar view as a whole.

In the present fourth embodiment, in a state where substrate tray 490 that supports substrate P after exposure is carried out from the substrate holder (the illustration is omitted) and mounted on the plurality of tray guide devices 73, support section 131₂ of hand 130 is inserted between first tray 490a and second tray 490b and support section 131 of hand 130 is inserted between second tray 490b and third tray 490c. Then, hand 130 moves in the +Z direction, and thereby an area between first tray 490a and second tray 490b and an area between second tray 490b and third tray 494c of substrate P are supported from below by support sections 131₂ and 131₁ respectively. Further, the other two support sections 131₁ and 131₄ of hand 130 support the −Y side end and the +Y side end of substrate P from below, respectively. In this manner, in the fourth embodiment, since substrate P after exposure is directly delivered from substrate tray 490 to the robot arm (not via a lift device 65 (see the drawings such as FIG. 113) as in the first embodiment described above), carry-in of substrate P to substrate tray 490 and carry-out of substrate P from substrate tray 490 (recovery of substrate P) can be speedily performed.

Further, because substrate tray 490 is made up of a plurality of members that are separated in the Y-axis direction, the position of substrate P in the θz direction can be controlled in a state mounted on substrate tray 490, as in the third embodiment described above. Incidentally, in the description above, while the configuration is employed in which substrate tray 490 is composed of three members that are physically separated, if hand 130 of the robot arm can be inserted between adjacent support sections 91 by forming notches at the upper end of connecting section 92 (see FIG. 4C) and so on, for example, at substrate tray 90 (see FIG. 3A) of the first embodiment described above, the substrate tray can be composed of an integral member. Further, it is also possible that the substrate tray is configured of, for example, two members or four or more members, in accordance with the shape of hand 130 (the number of support sections 131) of the robot arm.

### Fifth Embodiment

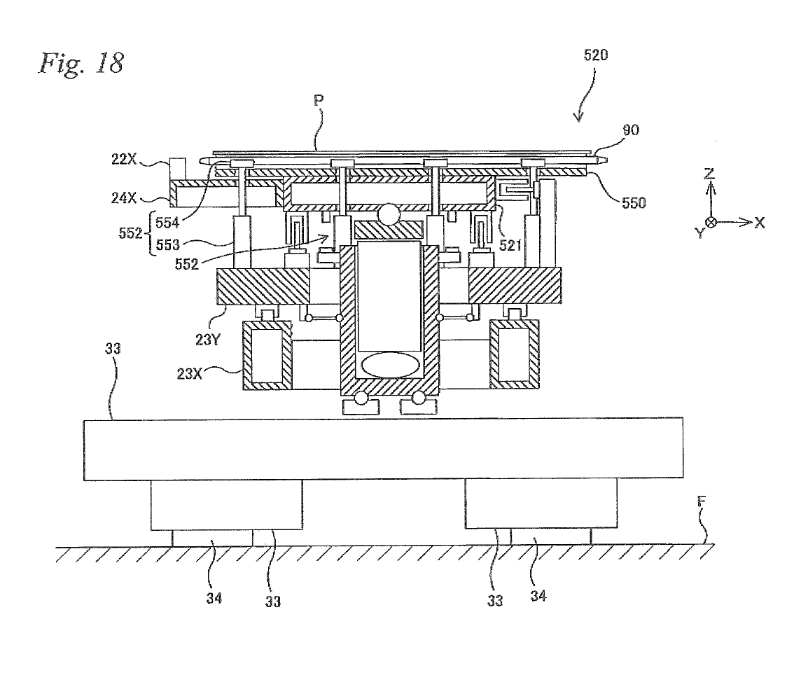

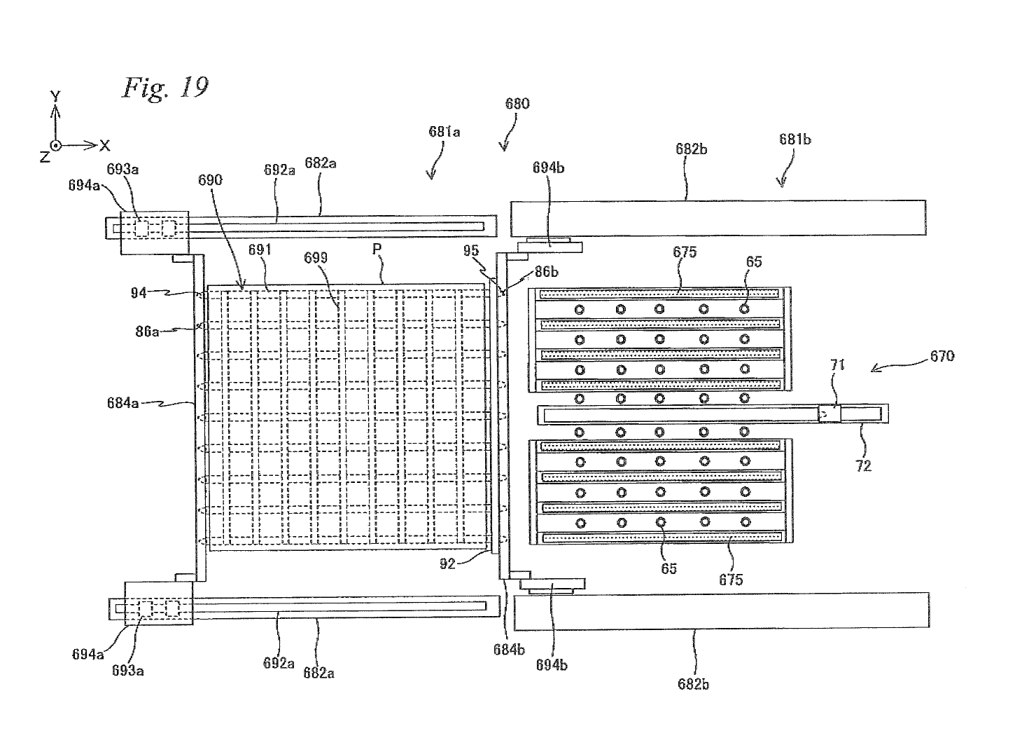

Next, a fifth embodiment is described based on FIG. 1e. A liquid crystal exposure apparatus related to the fifth embodiment is different from the first embodiment described above in a configuration of a substrate stage 520. More specifically, in substrate stage 20 (see FIG. 2) of the first embodiment described above, the plurality of tray guide devices 52 (see FIG. 313) that support substrate tray 90 are arranged at (built in) substrate holder 50, whereas in substrate stage 520 shown in FIG. 19, a plurality of tray guide devices 552 are attached to the upper surface of Y coarse movement stage 23Y, which is a different point. Incidentally, from the viewpoint of preventing intricacy of the drawing, the illustration of the pair of cable guide devices 36 (see FIG. 2) is omitted in FIG. 18.

Tray guide devices 552 each include an air cylinder 553 fixed to Y coarse movement stage 23Y and a guide member 554 attached to the tip of the rod of air cylinder 553. The rods of air cylinders 553 extend parallel to the Z-axis. For example, a total of sixteen tray guide devices 552 are arranged in a placement similar to that of the first embodiment described above (see FIG. 3A). Mid portions in the longitudinal direction of the rods of some of air cylinders 553 are inserted through hole sections formed at a fine movement stage 521 or a mirror base 24X (or a mirror base 24Y that is not illustrated). Further, in substrate holder 550, hole sections that penetrate in the Z-axis direction are formed at positions that correspond to the plurality (e.g. sixteen) of tray guide devices 552, and the rods of sixteen air cylinders 553 are inserted through the hole sections, respectively. Incidentally, guide members 554 are the site as guide members 54 in the first embodiment described above.

Since, in substrate stage 520 related to the present fifth embodiment, air cylinders 553 of tray guide devices 552 are formed outside fine movement stage 521, reduction in thickness and weight of fine movement stage 521 can be attained. Consequently, the voice coil motor used to drive fine movement stage 521, weight cancelling device 40 that cancels the weight of a system including fine movement stage 521, and the like can be reduced in size. Further, because substrate tray 90 is not in contact with fine movement stage 521, even if vibration is generated in substrate tray 90, the vibration is not transmitted to fine movement stage 521. Consequently, the position control of fine movement stage 521 can be performed with high precision. Further, substrate stage 520 of the present embodiment has the configuration in which the center portion of fine movement stage 521 is supported from below by weight cancelling device 40, and therefore, there are no members except for the voice coil motor in an area below the other portion excluding the center portion of fine movement stage 521, which allows the plurality of air cylinders 553 to be placed on Y coarse movement stage 23Y without difficulty.

### Sixth Embodiment

Next, a sixth embodiment is described based on FIGS. 19 to 24. A liquid crystal exposure apparatus related to the sixth embodiment is different from that of the first embodiment described above in configurations of a substrate tray 690, a substrate holder that is not illustrated, a substrate carry-out device 670 and a substrate carry-in device 680. Incidentally, because the other sections are the same as those of the first embodiment described above, the description thereof is omitted.

As shown in FIG. 19, substrate tray 690 of the sixth embodiment has a plurality (e.g. nine) of support sections 691, connecting section 92 that connects the +X side ends of the plurality of support sections 691, and a plurality (e.g. nine) of connecting sections 699 that connect the mid portions in the longitudinal direction of the plurality of support sections 691. Because the functions of substrate tray 690 are the same as those of the second embodiment described above except tat the number of support sections 691 and the number of connecting sections 699 are different, the detailed description thereof is omitted. Further, although not illustrated in the drawings, at the substrate holder, groove sections that correspond to the plurality (e.g. nine) of support sections 691 and the plurality (e.g. nine) of connecting sections 699 described above are formed similarly to the second embodiment described above.

Substrate carry-out device 670 has, for example, eight guide members 675 that correspond to eight support sections 691 (excluding one support section 691 in the center) of nine support sections 691 of substrate tray 690 described above. Since the configuration and functions of substrate carry-out device 670 are roughly the same as those in the first embodiment described above except that eight guide members 675 are each made up of a member extending in the X-axis direction and are mounted on a common base member and synchronously driven, and that the larger number of lift devices 65 are provided, the detailed description thereof is omitted.

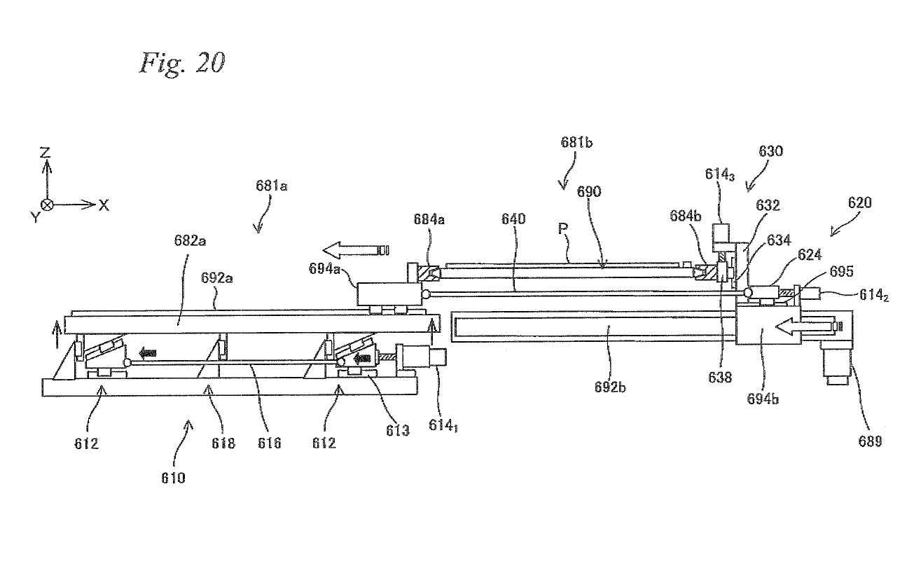

As shown in FIG. 20, substrate carry-in device 690 has a first carrier unit 681a, a Z-axis drive device 610 that drives the first carrier unit in the Z-axis direction, a second carrier unit 6815 and a interlinking bar 640.

As shown in FIG. 19, first carrier unit 681a includes a pair of first guide sections 682a, a pair of X tables 694a that are provided so as to correspond to the pair of first guide sections 682a, respectively, a grip section 684a that grips the −X side end of substrate tray 690, and the like.

First guide sections 682a are each made up of a member extending in the X-axis direction and are mounted on Z-axis drive device 610 that is described later on (see FIG. 20). The pair of first guide sections 682a are placed parallel at a predetermined distance in the Y-axis direction. On the upper surface of each of the pair of first guide sections 682a, an X linear guide member 692a is fixed. X table 694a engages with X linear guide member 692a, via a plurality of X sliders 693a, so as to be slidable with respect to X linear guide member 692a. Grip section 684a is a member that has the similar functions to those of grip section 84a of the first embodiment described above except that the number of recessed sections 86a is different, and grip section 684a is installed between the pair of X tables 694a.

As shown in FIG. 20, Z-axis drive device 610 has a plurality, e.g. two, of cam devices 612 that each include a pair of wedge members overlaid in the vertical direction, a feed screw device 614₁ used to drive cam devices 612, a interlinking bar 616 that interlinks the lower side wedge members of two cam devices 612 with each other, a z-axis guide device 618 and the like, and Z-axis drive device 610 drives first carrier unit 681a described above in the Z-axis direction.

For example, two cam devices 612 are placed at a predetermined distance in the X-axis direction. For example, of the pair of wedge members, which each of two cam devices 612 has, the upper side wedge member is fixed to first guide section 682a and the lower side wedge member is movable in the X-axis direction. The pair of wedge members that constitute each of cam devices 62 are configured so as to smoothly move with respect to each other via a plurality of linear guides 613.

Feed screw device 614₁ drives the lower side wedge member of cam device 612 placed on the +X side with predetermined strokes in the X-axis direction.

Interlinking bar 616 mechanically connects, for example, the lower side wedge members of two cam devices 612 to each other.

Z-axis guide device 618 is placed between two cam devices 612, and supports the mid portion in the longitudinal direction of first guide section 682a from below. Incidentally, any number of cam device 612, feed screw device 614₁ and Z-axis guide device 618 can be employed. Further, the Z-axis drive device used to drive first carrier unit 681a in the Z-axis direction is not limited to Z-axis guide device 618, but for example, a device that directly drives first carrier unit 681a in the Z-axis direction such as an air cylinder can also be used. Further, the Z-axis drive device can be installed at a position above or a position on the side of first carrier unit 81a, and any orientation of the installation can be employed.

Second carrier unit 681b includes a pair of second guide sections 682b, a pair of X tables 694b arranged so as to correspond to the pair of second guide sections 682b, as shown in FIG. 19, and an X-axis drive device 620 attached to X tables 694b, a Z-axis drive device 630 attached to X tables 694b, a grip section 684b that grips the +X side end of substrate tray 690, as shown in FIG. 20, and the like (in order to prevent intricacy of the drawing, X-axis drive device 620 and Z-axis drive device 630 are not illustrated in FIG. 19).

As shown in FIG. 19, the pair of second guide sections 682b are each made up of a member extending in the X-axis direction, and are placed parallel at a predetermined distance in the Y-axis direction. Each of the pair of X tables 694b is driven with predetermined long strokes in the X-axis direction with respect to the corresponding second guide section 682b, by a belt drive device 689 (not illustrated in FIG. 19, see FIG. 20) that includes a belt, a pulley and a rotary motor.

As shown in FIG. 20, X-axis drive device 620 has an X slider 624 mounted on X tables 694b so as to be slidable in the x-axis direction with respect X tables 694b via an X linear guide device 695, and a reed screw device 614₂ that drives X slider 624 in the X-axis direction. Incidentally, X-axis drive device 620 can be attached to Z-axis drive device 630 that is described below.

Z-axis drive device 630 is attached to the upper surfaces (or the inner side surfaces in the Y-axis direction) of X tables 694b. Z-axis drive device 630 has a Z slider 638 that is arranged at a support section 632 fixed to X tables 694b so as to be slidable in the Z-axis direction with respect to support section 632 via a Z linear guide device 634, and a feed screw device 614ₐ that drives Z slider 638 in the Z-axis direction.

Grip section 684b is a member that has functions similar to those of the first embodiment described above, except that the number of recessed sections 86b is different, and grip section 684b is fixed to Z slider 638 and moves integrally with X tables 694b in the Z-axis direction.

Interlinking bar 640 is made up of a bar-shaped member extending in the X-axis direction, and has a hinged joint device, e.g. a ball joint, a hinge device or the like, at both ends, and one end (on the −X side) of the interlinking bar is connected to X tables 694a and the other end (on the +X side) is connected to X slider 624, respectively, via the hinged joint devices. Consequently, when X slider 624 is driven in the X-axis direction by X tables 694b being driven or by feed screw device 614₂, X tables 694b move in the X-axis direction along X linear guide members 692a via interlinking bar 640.

In this case, even if the parallel degrees among first guide sections 682a, second guide sections 682b and X linear guide device 695 are deviated from one another, the action of a pair of the hinged joint devices arranged at both ends of interlinking bar 640 allows the drive force in the X-axis direction from X slider 624 to be transmitted to X tables 694a without excessively restricting each of the guide devices described above, and thereby each of the movable members is smoothly driven in the X-axis direction.

In the description below, the carry-in procedure of substrate P using substrate carry-in device 680 is described with reference to FIGS. 20 to 24. Incidentally, FIGS. 20 to 24 are views used to explain the carry-in procedure of substrate P, and the illustration of the configuration of substrate stage and the like is partially omitted.

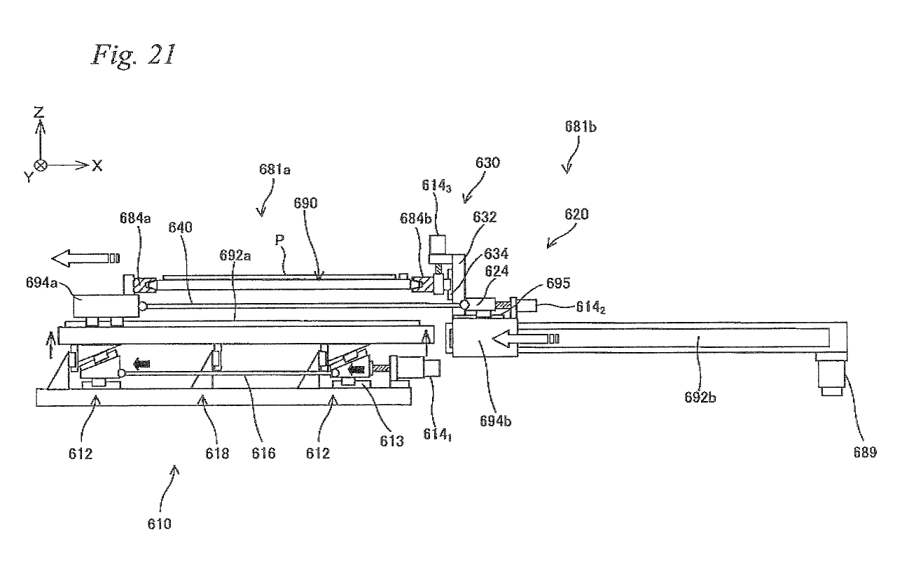

FIG. 20 shows a state where after substrate P is mounted on substrate tray 690, substrate tray 690 is gripped by grip sections 684a and 684b. On this operation, the main controller that is not illustrated adjusts the Z-positions of first guide sections 682a using Z-axis drive device 610 such that substrate P supported by substrate tray 690 is parallel to a horizontal plane (such that grip sections 684a and 684b are the same in the Z-position). Then, by controlling belt drive devices 689, the main controller that is not illustrated drives X tables 694b in the −X direction and integrally moves X tables 694b and X tables 694a interlinked with X tables 694b by interlinking bar 640 in the −X direction. Accordingly, as shown in FIG. 21, substrate tray 690 held by grip sections 684a and 684b moves in the −X direction and substrate P supported by substrate tray 690 moves parallel to the horizontal plane in the −X direction.

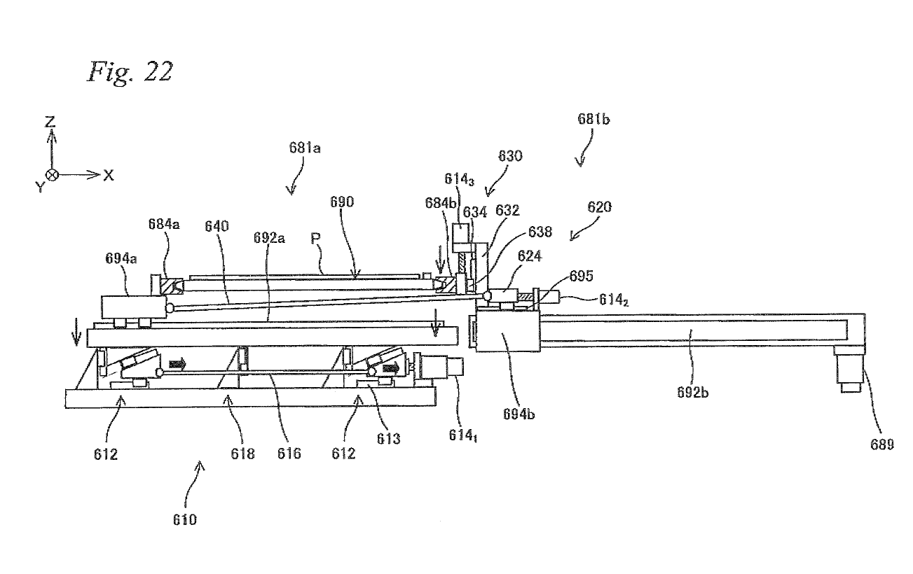

Then, when substrate tray 690 is located in an area above the substrate exchange position, as shown in FIG. 22, the main controller drives each of Z-axis drive device 610 and Z-axis drive device 630 to lower substrate tray 690 (moves the substrate tray in the −Z direction). Accordingly, substrate P mounted on substrate tray 690 is delivered to the substrate holder that is not illustrated. Incidentally, in order to correct an interval error (so-called cosine error) in the X-axis direction between grip sections 684a and 684b caused by tilt of interlinking bar 640 on this operation, X slider 624 can finely be driven to the −X side.

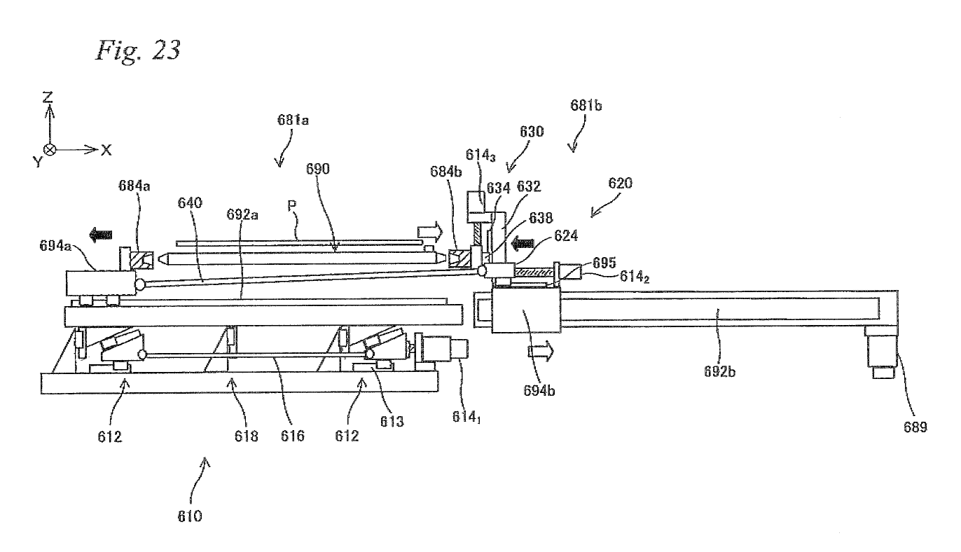

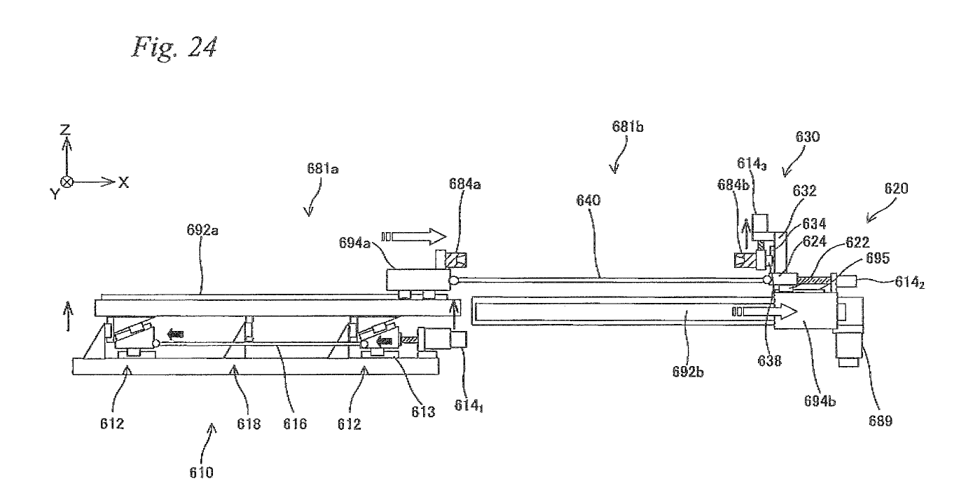

When substrate P is carried from substrate tray 690 and mounted on the substrate holder that is not illustrated, as shown in FIG. 23, the main controller finely drives X tables 694b in the +X direction using belt drive devices 689 and also drives X slider 624 in the −X direction using feed screw device 614₂, thereby moving X tables 694a in the −X direction. Accordingly, grip section 684b moves in the +X direction and also grip section 684a moves in the −X direction, and the engagement of grip sections 684a and 684b with substrate tray 690 is released. After that, as shown in FIG. 24, the main controller drives each of Z-axis drive device 610 and Z-axis drive device 630 to return the 3-positions of grip sections 684a and 684b to the initial positions shown in FIG. 22, and also drives X tables 694b in the +X direction using belt drive devices 689. Accordingly, X tables 694a interlinked with X tables 694b by interlinking bar 640 integrally move in the +X direction.

In the sixth embodiment described above, even in the case where an area above the substrate exchange position of the substrate holder is small (a space is small), substrate tray 650 on which substrate P is mounted can be carried in. Further, because the mid portions in the X-axis direction of first guide sections 682a of first carrier unit 681a are supported by Z-axis guide device 618, substrate carry-in device 680 of a thing type having a high stiffness can be configured. Farther, because K tables 694a and X tables 694b are mechanically interlinked by interlinking bar 640, a drive source used to drive X tables 694a does not have to be arranged at first carrier unit 681a, and the device can be configured being lightweight at a low cost. Further, because there is no drive source for X tables 694a, for example, a movable cable used to supply the electric power is not necessary, and therefore, there is no risk that particles adhere on the substrate holder. Further, because there is no movable cable, the weight of the device can be further decreased.

Incidentally, while belt drive devices 689 are used as the drive device of X tables 694b, this is not intended to be limiting, and for example, drive devices such as ball screw devices or linear motors can be used. Further, while a pair of belt drive devices 689 are arranged so as to respectively correspond to the pair of second guide sections 682b, this is not intended to be limiting, and the pair of X tables 694b can be driven by one motor by transmitting the power from one of the pair of second guide sections 952b to the other. Further, while Z-axis drive device 630 is arranged to raise and lower grip section 84b (drive the grip section in the ±Z direction), this is not intended to be limiting, and it is also possible that second carrier unit 681b as a whole is driven in the Z-axis direction similarly to first carrier unit 681a.

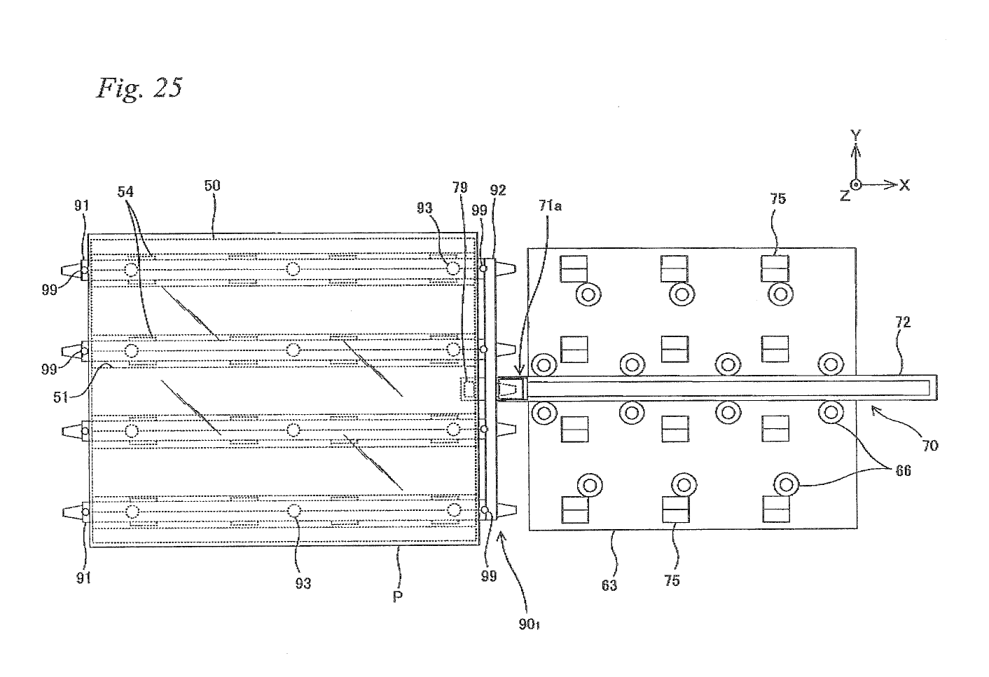

Incidentally, the respective liquid crystal exposure apparatuses (including the substrate trays) related to the first to sixth embodiments described above are merely examples, and the configurations thereof can be appropriately changed. For example, as a substrate tray 90₁ shown in FIG. 25, the substrate tray can have a fall prevention pin 99, used to prevent fall of substrate P, at the +X side end and the −X side end of each of the plurality of support sections 91. With the fall prevention pins, even if substrate P shifts from pads 93, for example, when substrate tray 90₁ accelerates/decelerates (such as the case where substrate tray 90₁ suddenly stops), substrate P and fall prevention pins 99 come in contact with each other, and the fall of substrate P from substrate tray 90₁ is prevented. Consequently, substrate P needs not be held by adsorption on substrate tray 90₁. Incidentally, as far as the fall of substrate P from substrate tray 90₁ can prevented, the shape of the fall prevention member is not limited to the pin shape. Further, fall prevention pin 99 can be arranged at the support sections of the substrate tray that are divided into a plurality of sections like the substrate tray related to the third or fourth embodiment described above (see FIGS. 16A and 17 respectively).

Further, as shown in FIG. 25, a grip device 71a of substrate carry-out device 70 can have a substrate adsorption pad 79 that holds by adsorption the lower surface of substrate P. In such a case, because grip device 71a can directly hold substrate P, substrate P can be reliably guided in the X-axis direction even if defect is generated in adsorption of substrate P by pads 93 of substrate tray 90₁.

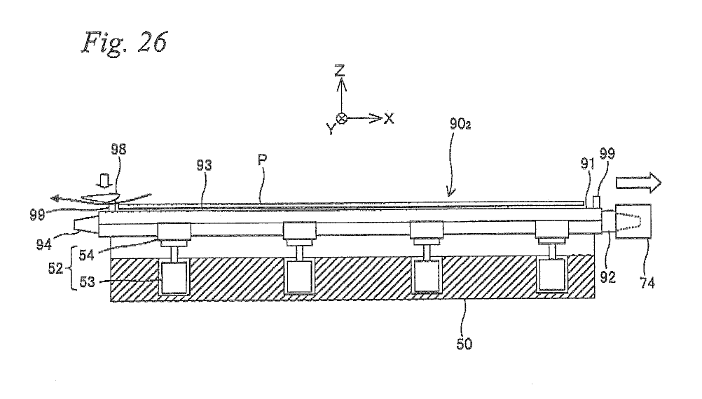

Further, like a substrate tray 90₂ shown in FIG. 26, substrate tray 90 can have lift force generating members 98 that make lift forces in the −Z direction (downward in the vertical direction) act on the −X side ends of support sections 91 when substrate tray 90 moves in the +X direction. Lift force generating member 98 has, for example, a shape like an upside down main plane of an airplane. Lift force generating member 98 is connected to the tip (+Z side end) of fall prevention pin 99. Incidentally, it is also possible that one member having a wing-shaped sectional shape extending in the Y-axis direction of lift force generating member 98 is installed over the plurality of support sections 91, or a plurality of the members each having a wing-shaped sectional shape can be provided so as to correspond to the plurality of support sections 91. Only the +X side end of each of the plurality of support sections 91 of substrate tray 90 is connected to connecting section 92, and the −X side end is a free end, and therefore, for example, there is a possibility that vibration or the like is generated at the −X side end. In contrast, in the case where substrate tray 90₂ moves in the +X direction such as when substrate P is carried out from substrate holder 50 (see FIG. 2), the lift forces downward in the vertical direction act on the −X side ends of support sections 91 owing to the action of lift force generating members 98, and thereby support sections 91 are pressed against guide members 54 (or guide members 77 (see FIG. 6)). Consequently, substrate tray 90₂ can be carried out from substrate holder 50 in a stable state. In the case where a gas is jetted from guide members 54, vibration is prevented from being generated at the −X side end of substrate tray 90₂ by balancing the pressure of the gas and the above-described lift forces.

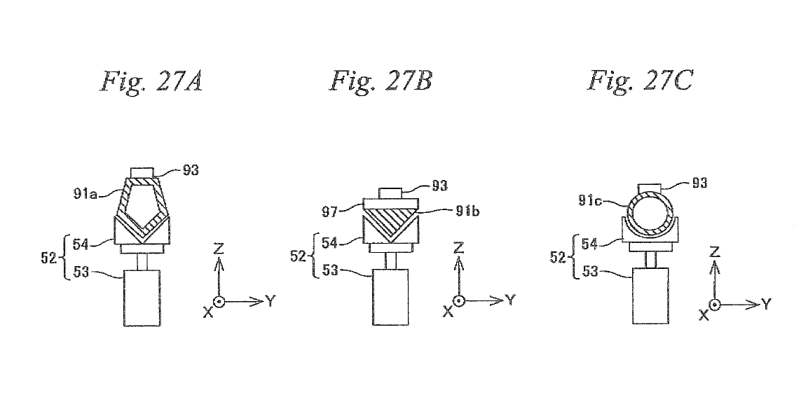

Further, the shape of the cross section that is orthogonal to the longitudinal direction of each support section 91 of substrate tray 90 is not limited in particular as far as substrate tray 90 can reliably be guided in the X-axis direction when substrate P is carried out from substrate holder 50, and can appropriately be changed. The shape can be, for example, an inverted pentagonal shape like a support section 91a shown in FIG. 27A or an inverted triangular shape like a support section 91b shown in FIG. 278. Further, support sections 91 can each be composed of a hollow member as shown in FIG. 27A, or can each be composed of a solid member as shown in FIG. 27B. Incidentally, because support section 91b having an inverted triangular section shown in FIG. 27B has the relatively small size in the Z-axis direction, a spacer 97 used to attach pad 93 is attached to the +Z side surface. Further, as shown in FIG. 27C, a support section 91c can be made up of a hollow member (or can be made up of a solid member) having a circular sectional shape. In this case, guide members 54 (and guide members 77 (see FIG. 6) of substrate carry-out device 70) that guide substrate tray 90 in the X-axis direction are each formed so as to have a U-shaped sectional shape (having a circular arc concave surface) corresponding to the support section.

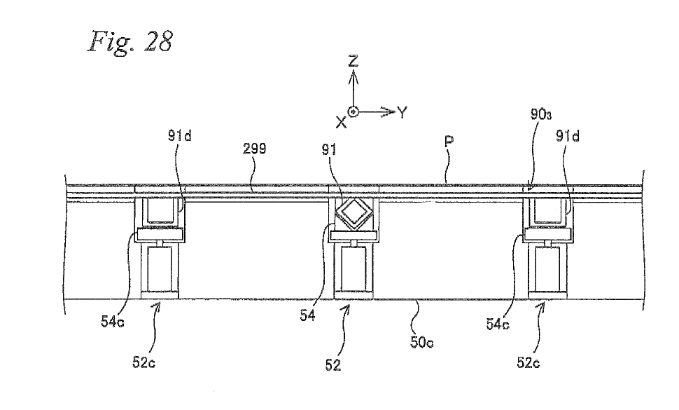

Further, all of guide members 54 of tray guide devices 52 and guide members 77 of substrate carry-out device 70 do not have to be configured so as to restrict relative movement of substrate tray 90 in the Y-axis direction. For example, as shown in FIG. 28, guide devices 52c, other than tray guide devices 52 that configure one tray guide device row (e.g. in the center), out of the tray guide device rows placed at a predetermined distance in the Y-axis direction, can each have a guide member 54c whose upper surface is a flat surface parallel to the horizontal plane. Even in this case as well, guide members 54 having the V groove sections (or the guide members having the U-shaped grooves as shown in FIG. 27C) can surely guide substrate tray 90 linearly in the X-axis direction. Incidentally, it is also possible that guide members 54 of tray guide devices 52 and guide members 77 of substrate carry-out device 70 are used only for support of substrate tray 90, and restriction of the relative movement in the Y-axis direction is performed by, for example, connection of grip sections 84a and 84b with taper members 94, 95 and 96, and the like. Note that support sections 91d of a substrate tray 90₃ corresponding to tray guide devices 52c are each formed to have a rectangular sectional shape. In this ease, because the upper surface of substrate tray 90₃ is parallel to the horizontal plane, the substrate tray needs not have the pad members that come in contact with the lower surface of substrate P (substrate P is directly mounted on support sections 91d). Further, tray guide devices 52 and 52c of a substrate holder 50e are shown in FIG. 28, the tray guide devices that substrate carry-out device 70 (see FIG. 2) has are configured similarly.

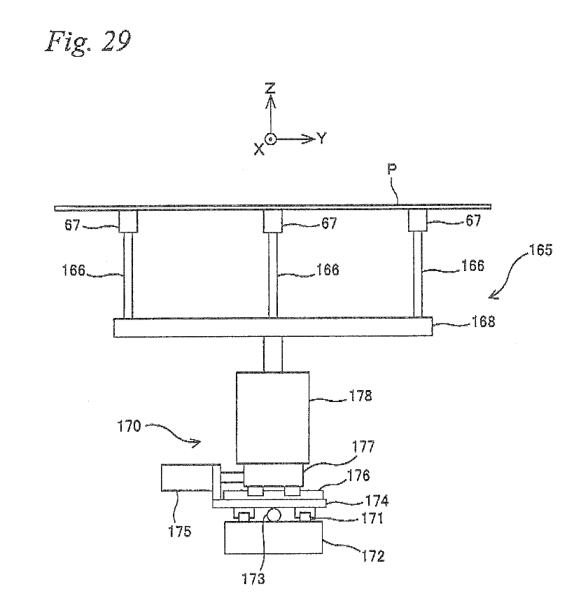

Further, the plurality of air cylinders 66 of lift device 65 (see FIG. 2) used to move substrate P apart from substrate tray 90 can be configured movable in each direction of, for example, the X-axis direction, the Y-axis direction and the θz direction. With such a configuration, the X-position, the Y-position and the θz position of substrate P mounted on lift device 65 can be controlled, and therefore a positional deviation of substrate P occurring when carry-in robot arm 120 delivers substrate P onto lift device 65 can be corrected. As a configuration that drives the plurality of air cylinders 66, for example, a configuration can be employed in which the plurality of air cylinders 66 are fixed on a common base member (a member different from base 63 (see FIG. 2) of the frame) and the base member is driven. Further, it is also possible that the lift device has a configuration in which a plurality of lift pins 166 (bar-shaped members that do not expand/contract), which have pad members 67 at one ends, have the other ends connected onto a common base member 168, and base member 168 is driven in the X-axis direction, the Y-axis direction and the θz direction. A drive device 170 that drives base member 168 has, for example, an X stage 174 that is mounted on an X base 172 having an X guide member 171 extending in the X-axis direction and is driven by an air cylinder 173 with fine strokes in the X-axis direction along X guide member 171, and a rotary actuator 177 that is mounted on X stage 174 and is driven by an air cylinder 175 with fine strokes in the Y-axis direction along a Y guide member 176 that X stage 174 has, and a Z air cylinder 178 that is mounted on rotary actuator 177 and is finely driven by rotary actuator 177 in the θz direction, and base member 168 is connected to a rod tip of Z air cylinder 178. Accordingly, the position in the X-axis direction, the Y-axis direction, the Z-axis direction and the θz direction of substrate P supported from below by the plurality of lift pins 166 can be controlled. Incidentally, while the case has been described where the air cylinders are used as actuators that control the position of substrate P in the first to sixth embodiments described above and the modified example shown in FIG. 29, this is not intended to be limiting, and the position control of substrate P can be performed by, for example, a feed screw device, a linear motor device or the like.

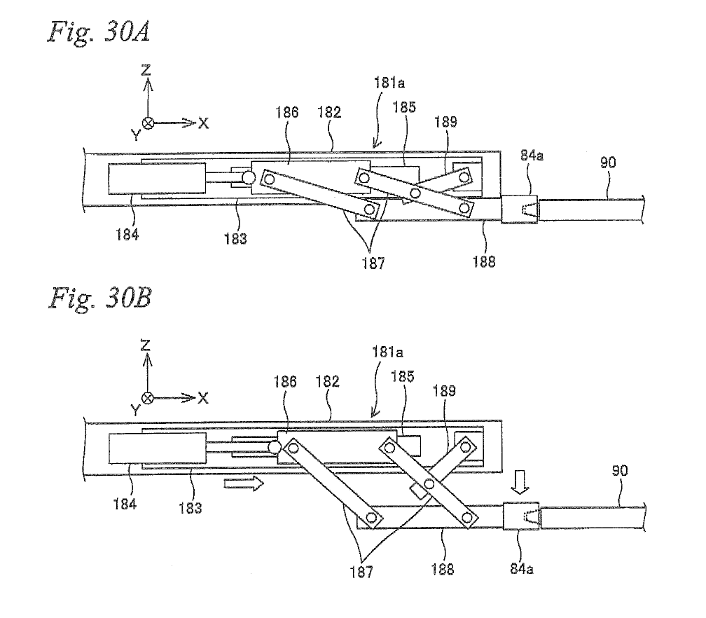

Further, while grip sections 84a and 84b of substrate carry-in device 80 are vertically moved by expansion/contraction devices 85a and 85b including the pantograph mechanisms in the first embodiment described above, grip section 84a can be vertically moved using a link device that performs the Scott Russell approximate parallel motion as shown in FIG. 30A. Incidentally, while in FIGS. 30A and 30B, only a first carrier unit 181a that grips the −X side end of substrate tray 90 is shown and the illustration of a second carrier unit 181b is omitted, first and second carrier units 181a and IBM can have the same configuration. To be more specific, first carrier unit 181a has a mover section 183 that is driven by, for example, a linear motor, with predetermined strokes in the X-axis direction with respect to a stator section 182, an X air cylinder 184 fixed to mover section 183, an X slider 186 that is driven, by X air cylinder 184, with predetermined strokes in the X-axis direction along an X linear guide 185 fixed to mover section 183, a pair of link members 187 one ends of which are connected to X slider 186, a Z slider 188 to which the other ends of the pair of link members 187 are connected and which vertically moves in conjunction with movement of X slider 186 in the X-axis direction (see FIG. 30B), grip section 84a (which has the same configuration as that of grip section 84a of the first to sixth embodiments described above) connected to Z slider 188, and an auxiliary link member 189 that sets an operation of one of the pair of link members 187 such that Z slider 188 vertically moves. A substrate carry-in device of a modified example shown in FIGS. 30A and 30B can also vertically move substrate tray 90, with a compact configuration whose size in the Z-axis direction is small, similarly to the first to sixth embodiments described above.

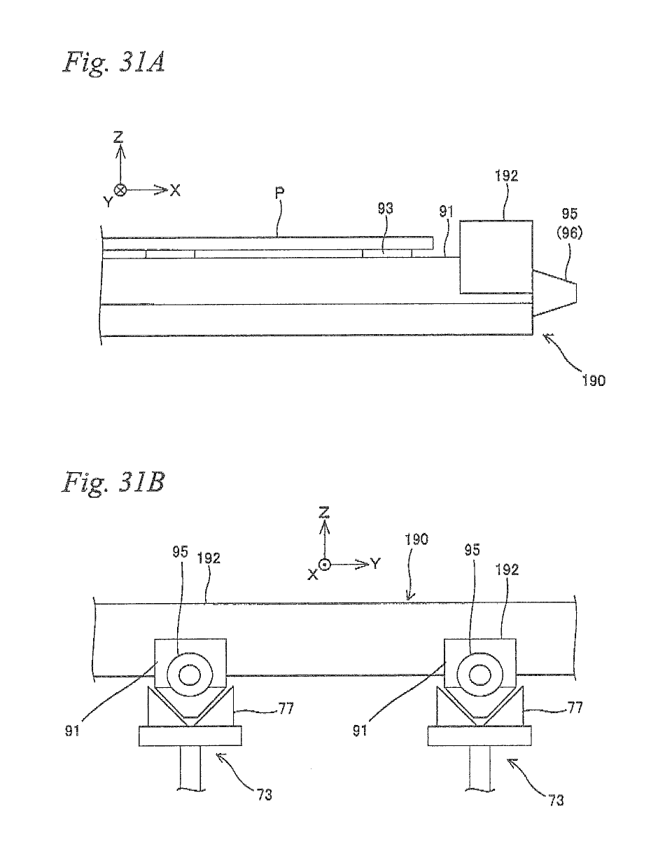

Further, as shown in FIGS. 31A and 31B, in a substrate tray 190, the upper ends of the +X side ends of the plurality of support sections 91 can be connected to one another by a connecting section 192. In this case, when substrate supported by substrate tray 190 is carried out from substrate holder 50 (see FIG. 2), guide members 77 of the plurality of tray guide devices 73 (see FIG. 2) and connecting section 192 do not interfere with each other. Consequently, notches 92a (see FIG. 4C) used to make guide members 77 pass do not have to be formed at connecting section 192, unlike substrate tray 90 related to the first embodiment described above, and the stiffness of substrate tray 190 is improved. Incidentally, while in substrate tray 190 shown in FIG. 31B, the cross sections, which are orthogonal to the longitudinal direction, of the plurality of support sections 91 are each formed to have a roughly inversed pentagonal shape, the sectional shape of each of the support sections can be a rhombic shape as shown in FIG. 5B or another shape as shown in each of FIGS. 27A to 27C as an example (or the other shapes that are not illustrated). Incidentally, taper members 95 and 96 can be attached to connecting section 192 or can be attached to the +X side end surface of support sections 191 as shown FIG. 31B.

Further, while in the first to sixth embodiments described above, grip device 71 (see FIG. 2) of substrate carry-out device 70 has the configuration holding substrate tray 90 by adsorption, this is not intended to be limiting, and for example, the holding by electrostatic adsorption can be employed, or as shown in FIG. 323, for example, it is also possible that a member like a pin is made to mechanically engage with a substrate tray 790 to hold substrate tray 790. In this case, as shown in FIG. 32A, in substrate tray 790, a hole section 792a that penetrates in the Z-axis direction (or a recessed section that is opened in the −Z direction) is formed in the center portion of a connecting section 792 that connect the +X side ends (front ends in the movement direction at the time of carry-out) of the plurality of support sections 91 to one another. Incidentally, the stiffness of substrate tray 790 is improved because the plurality of support sections 91 are connected by the plurality of connecting sections 299, which is similar to the second and sixth embodiments described above. Further, connecting section 792 connects the upper ends of the +X side ends of the plurality of support sections 91 to one another, which is similar to the modified example shown in FIGS. 30A and 303. Further, as shown in FIG. 323, a substrate carry-out device 770 has a pin 771 that is inserted in hole section 792a formed at connecting section 792 of substrate tray 790 and an actuator 772, e.g. an air cylinder of the like, that vertically moves pin 771, on mover section 75 that moves with predetermined strokes in the X-axis direction on stator section 72.

Further, while in the first to sixth embodiments described above (including the modified examples described above), the substrate carry-in device has the configuration in which the grip members that support both ends of the substrate tray are moved in the X-axis direction (one axis direction), the configuration is not limited thereto. More specifically, in the liquid crystal exposure apparatus related to each of the embodiments above, carry of a substrate to the substrate exchange position should be completed until the exposure processing and the like of the other substrate is finished, the carry speed is not required in particular (even if the carry speed is improved, the improved carry speed does not so much contribute to the throughput as a whole). Consequently, the substrate carry-in device can have a configuration equipped with, for example, a robot arm. On the contrary, on carry-out of the substrate from the substrate holder, it is preferable from the viewpoint of throughput improvement that the substrate holder is moved in the X-axis direction (one axis direction) as in the first to sixth embodiments described above. However, the configuration is not limited in particular as far as the substrate tray can be speedily carried out from the substrate holder, and for example, a configuration can also be employed in which a mover (such as a magnet unit) is arranged at the substrate tray and the substrate tray is directly driven by a linear motor.

Further, while in the first to sixth embodiments described above, the carry-in of substrate P to the substrate stage and the carry-out of substrate P from the substrate stage are performed in a state where substrate P is mounted on substrate tray 90 or the like, the carry-in and the carry-out can be performed without using a substrate supporting member like substrate tray 90 as far as substrate P can be lowered and mounted on a substrate holder and substrate P can be moved in a direction parallel to the horizontal plane and carried out from the substrate holder. In other words, the carry-in of substrate P can be performed in a state where the upper surface of substrate P is held in a noncontact manner using, for example, a noncontact holding device (e.g. the Bernoulli chuck or the like). Further, the carry-out of substrate P can be performed by forming a groove section extending in the X-axis direction at a substrate holder similarly to the first to sixth embodiments described above, and the hand (see FIG. 17) of the robot arm for substrate carry is directly inserted into the groove section.

Further, when lowering substrate tray 90 toward substrate holder 50 (see FIG. 10A), substrate carry-in device 80 can drive, first, grip section 84a of first carrier unit 81a that grips the front end in the movement direction at the time of the carry-in of substrate tray 90 in the −Z direction (tilts and lowers substrate tray 90). In other words, because substrate tray 90 that supports substrate P after exposure moves in the +X direction at the time of the carry-out of substrate P, grip section 84a on the −X side can be lowered first. In this case, because grip section 84b on the +X side is lowered later than grip section 84a on the −X side, a state of substrate tray 90 is changed from a tilt state to a horizontal state. Consequently, the gas between the lower surface of substrate P and the upper surface substrate holder 50 can be exhausted out in one time in the carry-out direction of substrate P (in the +X direction), and thereby a so-called air pocket can be prevented from being generated between the lower surface of substrate P and the upper surface of substrate holder 50.

Further, while in the first to sixth embodiments described above, air cylinders 53 of tray guide devices 52 are expanded to lift substrate tray 90 after substrate stage 20 that holds substrate P to which the exposure processing has been completed is moved to the substrate exchange position, air cylinders 53 of tray guide devices 52 can be lifted during the movement of substrate stage 20. In this case, because the movement of substrate stage 20 to the substrate exchange position and the lifting operation of substrate tray 90 by air cylinders 53 of tray guide devices 52 can be performed in parallel, the substrate exchange time can be reduced.

Further, in the first to sixth embodiments described above, before substrate stage 20 that holds substrate P to which the exposure processing has been completed reaches the substrate exchange position, any one of the following operations can be started: (1) release of holding by adsorption of substrate P by substrate holder 50; (2) upward movement of substrate tray 90; (3) holding of substrate P by substrate tray 90; and (4) separation of substrate P from substrate holder 50. In other words, in parallel with an operation of moving substrate stage 20 to the substrate exchange position after the exposure operation of substrate P has been completed, at least a part of the operations (1) to (4) described above can be performed. Accordingly, reduction in time can be attained, by making the operating time of the operations (1) to (4) described above for the substrate carry-out overlap with the time when substrate stage 20 moves from the exposure position to the substrate exchange position, namely, by increasing the parallel operations.

Further, in the first to sixth embodiments described above, in the case where substrate tray 90 that holds substrate P before exposure waits at a position above substrate P, to which the exposure processing has been completed, with a sufficient space in between, the lowering of substrate tray 90 can be started before substrate P is completely taken out of substrate holder 50. Or, by the time before substrate P is completely taken out of substrate holder 50, substrate tray 90 that holds substrate F before exposure can be placed close to substrate F so as to keep the substrate tray from coming in contact with substrate P.

Further, the removal of grip sections 84a and 84b from substrate tray 90 that holds substrate P before exposure can be started at any time when or after the substrate tray 90 is mounted onto guide members 54. Further, the movement of substrate stage 20 apart from the substrate exchange position can be started at the point when the contact with grip section 84a can be avoided after the removal of grip sections 84a and 84b from substrate tray 90 is started. Accordingly, it becomes possible that at least a part of the forgoing operations performed on or after the mounting of substrate tray 90 onto guide members 54 is performed in parallel with the movement of substrate stage 20 for the exposure operation of a next substrate P. In other words, the time for the operations performed on or after the mounting of substrate tray 90 onto guide members 54, of the carry-in operations of substrate P, and the time for the movement of substrate tray 20 for the exposure operation of the next substrate P are made to be overlap with each other, namely, the parallel operations are increased, and thereby reduction in time can be attained.

Further, of supporting sections 91 of substrate tray 90, support section 91 to which taper member 96 is connected (i.e. support section 91 connected to grip section 74 of substrate carry-out device 70 via the taper member) can be longer toward the +X direction compared with the other support sections 91. In this case, because the longer support section 91 is connected to grip section 74 before substrate stage 20 is placed at the substrate exchange position (i.e. during the movement in the +X direction), the movement of substrate stage 20 to the substrate exchange position and the carry-out of substrate tray 90 by substrate carry-out device 70 can be performed in parallel, and thereby the substrate exchange time can be reduced.

Further, while in the third embodiment described above, the positioning of substrate P in the θz direction is performed by driving first and second trays 390a and 390b, the positioning of substrate P is not limited to this method. As the positioning of substrate P, for example, it is also possible to perform the positioning by measuring a positional deviation amount θz1 of substrate P with, for example, a plurality (e.g. two) of optical sensors fixed to barrel surface plate 31 after substrate tray 90 that supports substrate P is carried in to the upper surface of substrate holder 50 by substrate carry-in device 80, and in accordance with the positional deviation amount θz1, moving (rotating) substrate holder 50 in the same direction by the same positional deviation amount θz1, and after substrate P is mounted on substrate holder 50, moving (rotating) substrate holder 50 in a direction opposite to the direction of the positional deviation amount θz1. Incidentally, this method can be performed in all of the first to sixth embodiments described above. Further, the positioning is performed not only for the deviation in the θz direction, but the similar correction can also be performed for the deviation in the X-axis direction and the Y-axis direction. In this case, however, three optical sensors are required. Further, the first movement (the movement in the same direction as the deviation amount) of substrate holder 50 after reading the position of substrate P needs not be performed in a state where substrate P is stopped in an area above substrate holder 50, but can be performed while substrate P is being lowered to be mounted on substrate holder 50.

Further, while in the first to sixth embodiments described above, substrate carry-in device 80 lowers substrate tray 90 and substrate P is delivered to substrate holder 50 (see FIG. 10A), it is also possible that guide members 54 of substrate holder 50 are positioned at the movement upper limit position and substrate tray 90 is delivered to guide members 54. In this case, guide members 54 that support substrate tray 90 from below are driven in the −Z direction, and thereby substrate P is mounted on substrate holder 50. Consequently, the movement strokes in the Z-axis direction of grip sections 84a and 84b of substrate carry-in device 80 can be shortened, which allows the size of expansion/contraction devices 85a and 85b to be reduced (the movement strokes in the Z-axis direction of guide members 54 can be the same). Further, in the case where guide members 54 are lowered and substrate P is mounted on substrate holder 50 as described above, guide members 54, for example, in the center portion, of the plurality of guide members 54, can be lowered earlier, and then the other guide members 54 can be lowered with this operation, the center portion of substrate P comes in contact with the upper surface of substrate holder 50 earlier than the ends of substrate P, which can prevent the so-called air pocket from being generated between substrate P and substrate holder 50. Incidentally, it is also possible to control the positions of the plurality of guide members 54 such that one end of substrate P is made to come in contact with the upper surface of substrate holder 50 earlier and then substrate P sequentially comes in contact with the upper surface of substrate holder 50 toward the other end side of substrate P.

Further, it is also possible that each of the pair of grip sections 84a and 84b of substrate carry-in device 80 is configured rotatable in the θy direction, and during the carry of the substrate tray, the bending of the center portion of substrate tray 90 caused by the self weight is restrained using the pair of grip sections 84a and 84b.

Further, while substrate P carried in from the external device (e.g. the coater/developer device) is mounted on lift device 65 and is then delivered onto substrate tray 90 by the plurality of air cylinders 66 that configure lift device 65 being contracted (see FIGS. 12C and 13A), this is not intended to be limiting, and substrate P can be mounted onto substrate tray 90 by raising substrate tray 90 (substrate tray 90 operates so as to skim substrate P).

Further, while in the first to sixth embodiments described above, substrate P is moved in the vertical direction to be carried in to the substrate holder and substrate P is moved in the horizontal direction to be carried out from the substrate holder, the carry-in and the carry-out method is not limited thereto if the movement path of the carry-in and the movement path of the carry-out of substrate P are different from each other, and for example, substrate P can be moved in the vertical direction to be carried out from the substrate holder and substrate P can be moved in the horizontal direction to carried in to the substrate holder. In other words, it is also possible that substrate tray 90 supported by the plurality of tray guide devices 73 (see FIG. 2) is moved in the −X direction and support sections 91 of substrate tray 90 are inserted from the side into groove sections 51 (see FIG. 4A) of substrate holder 50. Further, while in the first to sixth embodiments above, the carry-out/carry-in of substrate P is performed by circulating two substrate trays 90 between substrate stage 20 and substrate exchanging device 60 (see FIG. 2 for both of them), this is not intended to be limiting, and the carry-out/carry-in of substrate P can be performed using only one substrate tray 90. Further, at the time of carry-out and carry-in of substrate P from/to substrate holder 50, substrate tray 90 can be slid in the X-axis direction using guide members 54 and 77. In this case, it is preferable that two substrate trays 90 are prepared and one substrate tray 90 is withdrawn from guide members 77 after the carry-out of substrate P from substrate holder 50, and the other substrate tray 90 that holds a new substrate P is mounted on guide members 77, and the new substrate P is carried to substrate holder 50.

Further, while the ends of support sections 91, which are bar-shaped members to support substrate P from below, of the substrate tray are connected by connecting section 92, this is not intended to be limiting, and the substrate tray needs not have connecting section 92 (i.e. substrate P can be supported from below by only the plurality of bar-shaped members).

The vacuum adsorption of the substrate by the substrate tray described earlier can be applied not only to the substrate carrier device (substrate exchanging device) of each of the embodiments and modified examples described above, but also to various substrate carrier devices (substrate exchanging devices) regardless of their configurations or movement paths, e.g., a conventional substrate carrier device in which movement paths for loading and unloading a substrate are substantially the same, and the like.

Further, in each of the embodiments above, the vacuum adsorption of the substrate by the substrate tray can be performed only on either one of the loading or the unloading of a substrate, or does not have to be performed on both of the loading and the unloading of a substrate (i.e. the vacuum adsorption of the substrate by the substrate tray is not essential). For example, whether or not the vacuum adsorption of the substrate by the substrate tray is necessary can be determined depending on the movement speed (acceleration) of a substrate and/or a displacement amount of a substrate with respect to the substrate tray or a permissible value thereof, and the like. Especially, the latter one corresponds to pre-alignment accuracy of the substrate on the loading and corresponds to a permissible value used to prevent fall or collision/contact with the other members owing to the displacement of the substrate with respect to the substrate tray on the unloading.

In each of the embodiments above, the holding member used to restrain/prevent relative displacement (movement) between a substrate and the substrate tray on the movement of the substrate tray is not limited to the vacuum adsorption, but instead of or in combination with the vacuum adsorption, another method, e.g., a configuration in which a substrate is sandwiched by a plurality of fixing sections (pins), or at least one fixing section is made to be movable and the side surface of a substrate is pressed against the other fixing sections using the movable fixing section, or a clamp or the like can also be used.

In each of the embodiments above, at least a part of the substrate carry-in device and/or the substrate carry-out device (a port section) does not necessarily have to be arranged within the exposure apparatus, but can be arranged at the coater/developer device or an interface section between the exposure apparatus and the coater/developer device.

Note that each of embodiments above is especially effective in the case where the substrate whose outer diameter is not less than 500 mm serves as a carry subject (or an exposure subject).

Further, the illumination light can be ultraviolet light, such as ArF excimer laser light (with a wavelength of 193 nm) and KrF excimer laser light (with a wavelength of 248 nm) or vacuum ultraviolet light such as F₂ laser light (with a wavelength of 157 nm). Further, as the illumination light, a harmonic wave, which is obtained by amplifying a single-wavelength laser light in the infrared or visible range emitted by a DFB semiconductor laser or fiber laser with a fiber amplifier doped with, for example, erbium (or both erbium and ytteribium), and by converting the wavelength into ultraviolet light using a nonlinear optical crystal, can also be used. Further, solid state laser (with a wavelength of 355 nm, 266 nm) or the like can also be used.

Further, while, in each of the embodiments above, the case has been described where projection optical system PL is the projection optical system by a multi-lens method that is equipped with a plurality of optical systems, the number of the projection optical systems is not limited thereto, but there should be one or more projection optical systems.

Further, the projection optical system is not limited to the projection optical system by a multi-lens method, but can be a projection optical system using, for example, a large mirror of the Offner type, or the like. Further, while the case has been described where the projection optical system whose projection magnification is equal magnification is used as projection optical system PL in each of the embodiments above, this is not intended to be limiting, and the projection optical system can be either of a reduction system or a magnifying system.

Further, in each of the embodiments above, while the case has been described where the exposure apparatus is a scanning stepper, this is not intended to be limiting, and each of the embodiments above can also be applied to a static type exposure apparatus such as a stepper. Further, each of the embodiments above can also be applied to a projection exposure apparatus by a step-and-stitch method that synthesizes a shot area and a shot area. Further, each of the embodiments above can also be applied to an exposure apparatus by a proximity method that does not use any projection optical systems.

Further, the application of the exposure apparatus is not limited to the exposure apparatus for liquid crystal display elements in which a liquid crystal display element pattern is transferred onto a rectangular glass plate, but each of the embodiments above can also be widely applied, for example, to an exposure apparatus for manufacturing semiconductors, and an exposure apparatus for producing thin-film magnetic heads, micromachines, DNA chips, and the like. Further, each of the embodiments above can be applied not only to an exposure apparatus for producing microdevices such as semiconductor devices, but can also be applied to an exposure apparatus in which a circuit pattern is transferred onto a glass substrate, a silicon wafer or the like to produce a mask or a reticle used in a light exposure apparatus, an EUV exposure apparatus, an X-ray exposure apparatus, an electron-beam exposure apparatus, and the like. Incidentally, an object that is subject to exposure is not limited to a glass plate, but for example, can be another object such as a wafer, a ceramic substrate, or a mask blank.

Incidentally, the substrate carrier system related to each of the embodiments above can be applied not only to the exposure apparatus but also to, for example, an element manufacturing apparatus equipped with a functional liquid deposition device by an ink-jet method, or to an inspection device that inspects an exposure subject (e.g. a substrate or the like) to which the exposure processing has been performed by the exposure apparatus.

Electron devices such as liquid crystal display elements (or semiconductor devices) are manufactured through the following steps: a step where the function/performance design of a device is performed; a step where a mask (or a reticle) based on the design step is manufactured; a step where a glass substrate (or a wafer) is manufactured; a lithography step where a pattern of the mask (reticle) is transferred onto the glass substrate with the exposure apparatus of each of the embodiments above and the exposure method thereof; a development step where the exposed glass substrate is developed; an etching step where an exposed member of an area other than an area where resist remains is removed by etching; a resist removing step where the resist that is no longer necessary when the etching is completed is removed; a device assembly step; an inspection step; and the like. In this case, in the lithography step, the exposure method described earlier is executed using the exposure apparatus in each of the embodiments above and the device patterns are formed on the glass substrate, and therefore, and therefore, the devices with a high integration degree can be manufactured with high productivity.

Incidentally, the disclosures of all publications, the PCT International Publications, the U.S. patent application Publications and the U.S. patents related to exposure apparatuses and the like that are cited in the description so far are each incorporated herein by reference.

While the above-described embodiments of the present invention are the presently preferred embodiments thereof, those skilled in the art of lithography systems will readily recognize that numerous additions, modifications, and substitutions may be made to the above-described embodiments without departing from the spirit and scope thereof. It is intended that all such modifications, additions, and substitutions fall within the scope of the present invention, which is best defined by the claims appended below.

What is claimed is:

1. A substrate carrier device, comprising:
a carry-in device that carries in a substrate to a predetermined substrate holding device by carrying the substrate in a first path; and
a carry-out device that carries out the substrate held by the substrate holding device, from the substrate holding device, by carrying the substrate in a second path that is different from the first path.

2. The substrate carrier device according to claim 1, wherein
the carry-in device carries in the substrate to the substrate holding device by lowering the substrate from above the substrate holding device, and
the carry-out device carries out the substrate from the substrate holding device by relatively moving the substrate to one side in one axis direction parallel to a horizontal plane, with respect to the substrate holding device.

3. The substrate carrier device according to claim 1, wherein
the substrate is carried by the carry-in device and the carry-out device in a state mounted on a predetermined substrate supporting member.

4. The substrate carrier device according to claim 3, wherein
at least one of the carry-in device and the carry-out device includes a first holding member that holds one end side in the one axis direction of the substrate supporting member and a second holding member that holds the other end side of the substrate supporting member, and
the first holding member and the second holding member are interlinked with each other and are driven by a common actuator.

5. The substrate carrier device according to claim 3, wherein
after the substrate is carried out, together with the substrate supporting member, from the substrate holding device by the carry-out device, another substrate is mounted on the substrate supporting member, and
the carry-in device carries the substrate supporting member on which the another substrate is mounted to the substrate holding device.

6. The substrate carrier device according to claim 3, further comprising:
the substrate holding device, wherein
the substrate holding device includes a holding member that has a holding surface parallel to the horizontal plane, and a substrate is mounted on the holding surface.

7. The substrate carrier device according to claim 6, wherein
the carry-in device carries the substrate from the substrate supporting member and mounts the substrate onto the substrate holding device by inserting the substrate supporting member into a groove section formed at the holding surface of the substrate holding device.

8. The substrate carrier device according to claim 6, wherein
the substrate supporting member has a support section, which is made up of a plurality of bar-shaped members extending in a first direction parallel to the horizontal plane and arranged at a predetermined distance in a second direction orthogonal to the first direction within the horizontal plane and which supports the substrate from below, and the support section is housed in the groove section formed at the holding surface.

9. The substrate carrier device according to claim 8, wherein
the substrate supporting member further has a connecting section that connects one ends in a longitudinal direction of the plurality of bar-shaped members to one another.

10. The substrate carrier device according to claim 8, wherein
the carry-in device delivers the substrate from the substrate supporting member onto the substrate holding device in conjunction with an operation of inserting the substrate supporting member into the groove section.

11. The substrate carrier device according to claim 10, wherein
the substrate supporting member is separated from a lower surface of the substrate in a state where the substrate is mounted on the holding surface of the substrate holding device.

12. The substrate carrier device according to claim 8, wherein
the support section includes a first support section that supports an area on one side of the substrate in the second direction and a second support section that supports an area on the other side of the substrate in the second direction, and
at least one of the carry-in device and the carry-out device controls a position of the substrate around an axis perpendicular to the horizontal plane by controlling positions of the first and the second support sections in the first direction.

13. The substrate carrier device according to claim 8, wherein
the substrate supporting member further has a fall prevention member that prevents fall of the substrate supported by the support section.

14. The substrate carrier device according to claim 13, wherein
the fall prevention member is made up of a plurality of protruding members that protrude upward from the bar-shaped members.

15. The substrate carrier device according to claim 8, wherein
the support section has an adsorption section that holds the substrate by adsorption.

16. The substrate carrier device according to claim 8, wherein
a surface treatment to restrain reflection of a light is applied to at least the support section.

17. The substrate carrier device according to claim 8, wherein
a surface treatment to restrain generation of outgassing to at least the support section.

18. The substrate carrier device according to claim 8, wherein
the substrate supporting member further has a stiffening member that is installed between upper ends of mid portions, in the longitudinal direction, of the bar-shaped members adjacent to each other.

19. The substrate carrier device according to claim 18, wherein
the stiffening member is housed in a recessed section formed at the holding surface of the substrate holding device.

20. The substrate carrier device according to claim 8, wherein
the substrate supporting member further has an air force member that makes a downward lift force in a vertical direction act on the support section when moving parallel to the horizontal plane.

21. The substrate carrier device according to claim 8, wherein
in the substrate supporting member, a substrate delivery member that delivers the substrate from an external device onto the support section is capable of inserting between the bar-shaped members adjacent to each other.

22. The substrate carrier device according to claim 8, wherein
the carry-oat device carries the substrate out from the substrate holding device by relatively moving the substrate supporting member with respect to the substrate holding device in a state where at least a part of the substrate supporting member is housed in the groove section.

23. The substrate carrier device according to claim 22, wherein
the substrate holding device has a lift device that moves the substrate apart from the holding surface by supporting from below the substrate supporting member housed in the groove section and moving the substrate supporting member upward, and
the carry-out device relatively moves the substrate supporting member supported by the lift device with respect to the substrate holding device.

24. The substrate carrier device according to claim 23, wherein
the lift device has a guide section that guides the substrate supporting member into the second path.

25. The substrate carrier device according to claim 23, wherein
the lift device is arranged at the holding member.

26. The substrate carrier device according to claim 23, wherein
the substrate holding device has a stage device that is placed below the holding member and guides the holding member with predetermined strokes in at least a direction parallel to the horizontal plane, and
the lift device is arranged at the stage device.

27. The substrate carrier device according to claim 26, wherein
a through-hole that penetrates in the vertical direction is formed at the holding member, and
a part of the lift device is inserted through the through-hole.

28. The substrate carrier device according to claim 6, wherein
a plurality of the substrate supporting members are provided, and
when the carry-out device carries out the substrate subject to carry-out, together with one of the substrate supporting members, from the substrate holding device, the carry-in device positions another one of the substrate supporting members that supports the substrate subject to carry-in, above the substrate holding device.

29. An exposure apparatus, comprising:
the substrate carrier device according to claim 6; and
a pattern forming device that forms a predetermined pattern on the substrate mounted on the substrate holding device by exposing the substrate using an energy beam.

30. An exposure apparatus, comprising:
a substrate holding device that includes a holding member having a holding surface parallel to a horizontal plane, on the holding surface a substrate being mounted;
a carry-in device that carries in the substrate to the substrate holding device by carrying the substrate in a first path;
a carry-out device that carries out the substrate held by the substrate holding device, from the substrate holding device, by carrying the substrate in a second path that is different from the first path; and
an exposure system that exposes the substrate held on the substrate holding device with an energy beam.

31. The exposure apparatus according to claim 30, wherein
the carry-in device carries in the substrate to the substrate holding device by lowering the substrate from above the substrate holding device, and
the carry-out device carries out the substrate from the substrate holding device by relatively moving the substrate to one side in one axis direction parallel to a horizontal plane with respect to the substrate holding device.

32. The exposure apparatus according to claim 30, wherein
the substrate is carried by the carry-in device and the carry-out device in a state mounted on a predetermined substrate supporting member.

33. The exposure apparatus according to claim 32, wherein
after the substrate is carried out, together with the substrate supporting member, from the substrate holding device by the carry-out device, another substrate is mounted on the substrate supporting member, and
the carry-in device carries the substrate supporting member, on which the another substrate is mounted, to the substrate holding device.

34. The exposure apparatus according to claim 32, wherein
the carry-in device carries the substrate from the substrate supporting member and mounts the substrate on the substrate holding device by inserting the substrate supporting member into a groove section formed at the holding surface of the substrate holding device.

35. The exposure apparatus according to claim 30, wherein
the substrate is used in a flat-panel display device.

36. The exposure apparatus according to claim 30, wherein
the substrate has a side at least a length of which is not less than 500 mat.

37. A device manufacturing method, comprising:
exposing the substrate using the exposure apparatus according to claim 30; and
developing the substrate that has been exposed.

38. A substrate carrying method, comprising:
carrying in a substrate to a predetermined substrate holding device by carrying the substrate in a first path; and
carrying out the substrate from the substrate holding device by carrying the substrate in a second path that is different from the first path.

39. The substrate carrying method according to claim 38, wherein
in the carrying in the substrate, the substrate is carried onto the substrate holding device by carrying the substrate downward, and
in the carrying out the substrate, the substrate is carried out from the substrate holding device by moving the substrate in one axis direction parallel to a horizontal plane.

40. The substrate carrying method according to claim 39, further comprising:
mounting the substrate onto a predetermined substrate supporting member, wherein
in the carrying in the substrate, the substrate is carried from the substrate supporting member and is mounted onto the substrate holding device by inserting the substrate supporting member into a groove section formed at a substrate holding surface of the substrate holding device.

41. The substrate carrying method according to claim 40, wherein
in the carrying out the substrate, the substrate is carried out from the substrate holding device by moving the substrate supporting member in a state where at least a part of the substrate supporting member is housed in the groove section.

42. The substrate carrying method according to claim 40, further comprising:
mounting another substrate onto the substrate supporting member after the substrate is carried out, together with the substrate supporting member, from the substrate holding device, wherein
in the carrying in the substrate, the substrate supporting member on which the another substrate is mounted is carried to the substrate holding device.

43. The substrate carrying method according to claim 40, wherein
the carrying out the substrate and the carrying in the substrate are partially performed in parallel using a plurality of the substrate supporting members.

44. The substrate carrying method according to claim 43, wherein
when one of the substrate supporting members that supports the substrate subject to carry-out is carried out from the substrate holding device, another one of the substrate supporting members that supports the substrate subject to carry-in is made to wait above the substrate holding device.

45. A substrate supporting member, comprising:
a support section that is made up of a plurality of bar-shaped members extending in a first direction parallel to a horizontal plane and arranged at a predetermined distance in a second direction orthogonal to the first direction within the horizontal plane, and supports a substrate from below; and
an engagement section that is connected to the support section and is capable of engaging with a predetermined carrier device, wherein
the substrate supporting member is carried, together with the substrate, by the carrier device to a substrate holding device that has a substrate mounting surface parallel to the horizontal plane, at least a part of the support section is housed in a groove section formed at the substrate mounting surface, and the substrate supporting member removes from the inside of the groove section, together with the substrate, by relatively moving to one side in the first direction with respect to the substrate holding device.

46. The substrate supporting member according to claim 45, further comprising:
a connecting section that connects ends on the one side, in the first direction, of the plurality of bar-shaped members to one another.

47. The substrate supporting member according to claim 45, wherein
the substrate supporting member delivers the substrate to the substrate holding device in conjunction with an operation of being inserted into the groove section of the substrate holding device.

48. The substrate supporting member according to claim 45, wherein
the substrate supporting member is separated from a lower surface of the substrate in a state inserted in the groove section of the substrate holing device.

49. The substrate supporting member according to claim 45, further comprising:
a fall prevention section that prevents fall of the substrate supported by the support section.

50. The substrate supporting member according to claim 49, wherein
the fall prevention section is made up of a plurality of protruding members that protrude upward from the bar-shaped members.

51. The substrate supporting member according to claim 45, wherein
the support section has an adsorption section that holds the substrate by adsorption.

52. The substrate supporting member according to claim 45, wherein
a surface treatment to restrain reflection of a light is applied to at least the support section.

53. The substrate supporting member according to claim 45, wherein
a surface treatment to restrain generation of outgassing to at least the support section.

54. The substrate supporting member according to claim 45, further comprising:
a stiffening member that is installed between upper ends of mid portions, in the longitudinal direction, of the bar-shaped members adjacent to each other.

55. The substrate supporting member according to claim 54, wherein
the stiffening member is housed in a recessed section formed at the substrate holding surface of the substrate holding device.

56. The substrate supporting member according to claim 45, further comprising:
an air force member that makes a downward lift force in a vertical direction act on the support section when the substrate supporting member moves parallel to the horizontal plane.

57. The substrate supporting member according to claim 45, wherein
a substrate delivery member that delivers the substrate from an external device onto the support section is capable of inserting between the bar-shaped members adjacent to each other.

58. The substrate supporting member according to claim 45, wherein
the substrate supporting member is carried together with the substrate to a predetermined exposure position in a state housed in the groove section of the substrate holding device and an exposure operation is performed on the substrate at the exposure position.

59. A substrate holding device, comprising:
a holding member that has a holding surface parallel to a horizontal plane, on the holding surface a substrate being mounted, wherein
at the holding member, a plurality of groove sections are formed that are capable of housing a part of a substrate supporting member that supports the substrate from below and allow removal of the part of the substrate supporting member by relative movement of the substrate supporting member to one side in a first direction parallel to the horizontal plane.

60. The substrate holding device according to claim 59, wherein
the substrate supporting member has a plurality of bar-shaped members extending in the first direction and arranged at a predetermined distance in a second direction orthogonal to the first direction within the horizontal plane, and supports the substrate from below using the plurality of bar-shaped members, and
the plurality of bar-shaped members are capable of being housed in the plurality of groove sections.

61. The substrate holding device according to claim 60, wherein
a depth of each of the groove sections is set such that the substrate and the plurality of bar-shaped members are separated in a state where the substrate is mounted on the holding surface.

62. The substrate holding device according to claim 60, wherein
the holding member has a guide member that guides the plurality of bar-shaped members in the first direction when the substrate supporting member relatively moves to one side in the first direction.

63. The substrate holding device according to claim 62, wherein
the guide member supports the bar-shaped members from below in a state where the bar-shaped members are housed in the groove sections.

64. The substrate holding device according to claim 63, wherein
the guide member levitates the bar-shaped members via a fine gap.

65. The substrate holding device according to claim 63, wherein
the guide member holds the bar-shaped members by adsorption.

66. The substrate holding device according to claim 62, further comprising:
a lift device that vertically moves the guide member with predetermined strokes in a vertical direction, whereby
the guide member is raised and thereby the substrate is moved apart from the holding surface.

67. The substrate holding device according to claim 66, further comprising:
a stage device that is placed below the holding member and guides the holding member with predetermined strokes in at least direction parallel to the horizontal plane, wherein
the lift device is arranged at the stage device.

68. The substrate holding device according to claim 67, wherein
at the holding member, a through-hole that penetrates in the vertical direction is formed, and
a part of the lift device is inserted through the through-hole.

69. An exposure apparatus, comprising:
the substrate holding device according to claim 59; and
a pattern forming device that forms a predetermined pattern on the substrate mounted on the substrate holding device by exposing the substrate using an energy beam.

70. An exposure apparatus, comprising:
a substrate holding device that includes a holding member having a holding surface parallel to a horizontal plane, on the holding surface a substrate being mounted and at the holding member a plurality of groove sections being formed; and
an exposure system that exposes the substrate held on the substrate holding device with an energy beam, wherein
the groove sections are capable of housing a part of a substrate supporting member that supports the substrate from below and allow removal of the part of the substrate supporting member by relative movement of the substrate supporting member to one side in a first direction parallel to the horizontal plane.

71. The exposure apparatus according to claim 70, wherein
the substrate supporting member has a plurality of bar-shaped members extending in the first direction and arranged at a predetermined distance in a second direction orthogonal to the first direction within the horizontal plane, and supports the substrate from below using the plurality of bar-shaped members, and
the plurality of bar-shaped members are capable of being housed in the plurality of groove sections.

72. The exposure apparatus according to claim 70, wherein
the substrate is used in a flat-panel display device.

73. The exposure apparatus according to claim 70, wherein
the substrate has a side at least a length of which is not less than 500 mm.

74. A device manufacturing method, comprising:
exposing the substrate using the exposure apparatus according to claim 70; and
developing the substrate that has been exposed.

75. An exposure method of exposing a substrate held on a substrate holding device with an energy beam, the method comprising:
carrying in the substrate to the substrate holding device by carrying the substrate in a state mounted on a substrate supporting member; and
carrying out the substrate held on the substrate holding device, from the substrate holding device, by carrying the substrate in a state mounted on a substrate supporting member, wherein
at least during one of the carry-in of the substrate to the substrate holding device and the carry-out of the substrate from the substrate holding device, a shift of a position of the substrate with respect to the substrate supporting member used in the carry of the substrate is restrained or prevented.

76. The exposure method according to claim 75, wherein
the restraint or prevention of the shift of the position of the substrate with respect to the substrate supporting member is performed by vacuum adsorbing the substrate with the substrate supporting member.

77. The exposure method according to claim 75, wherein
the restraint or prevention of the shift of the position of the substrate with respect to the substrate supporting member is performed by sandwiching the substrate from side surface sides thereof with a plurality of fixing sections.

78. The exposure method according to claim 77, wherein
at least one of the plurality of fixing sections is movable, and the substrate is sandwiched by the plurality of fixing sections from the side surface sides by pressing the substrate against the other fixing sections from the side surface side using the movable fixing section.

79. A device manufacturing method, comprising:
exposing the substrate using the exposure method according to claim 75; and
developing the substrate that has been exposed.

80. An exposure apparatus, comprising:
a substrate holding device on which a substrate is mounted;
a carry-in device that carries in the substrate to the substrate holding device by carrying the substrate in a state mounted on a substrate supporting member;
a carry-out device that carries out the substrate held by the substrate holding device, from the substrate holding device, by carrying the substrate in a state mounted on a substrate supporting member; and
an exposure system that exposes the substrate held on the substrate holding device with an energy beam, wherein
at least during one of the carry-in of the substrate to the substrate holding device and the carry-out of the substrate from the substrate holding device, a shift of a position of the substrate with respect to the substrate supporting member used in the carry of the substrate is restrained or prevented.

81. The exposure apparatus according to claim 80, wherein
the restraint or prevention of the shift of the position of the substrate with respect to the substrate supporting member is performed by vacuum adsorbing the substrate with the substrate supporting member.

82. The exposure apparatus according to claim 80, wherein
the restraint or prevention of the shift of the position of the substrate with respect to the substrate supporting member is performed by sandwiching the substrate from side surface sides thereof with a plurality of fixing sections.

83. The exposure apparatus according to claim 82, wherein
at least one of the plurality of fixing sections is movable.

84. A device manufacturing method, comprising;
exposing the substrate using the exposure apparatus according to claim 80; and
developing the substrate that has been exposed.
